(19) United States
(12) Patent Application Publication
(10) Pub. No.: US 2024/0419071 A1
(43) Pub. Date: Dec. 19, 2024

(54) ACTINIC RAY-SENSITIVE OR RADIATION-SENSITIVE RESIN COMPOSITION, ACTINIC RAY-SENSITIVE OR RADIATION-SENSITIVE FILM, PATTERN FORMING METHOD, METHOD FOR PRODUCING ELECTRONIC DEVICE, COMPOUND, AND RESIN

(71) Applicant: FUJIFILM Corporation, Tokyo (JP)

(72) Inventors: Tsutomu YOSHIMURA, Haibara-gun (JP); Naoya Hatakeyama, Haibara-gun (JP); Akiyoshi Goto, Haibara-gun (JP)

(73) Assignee: FUJIFILM Corporation, Tokyo (JP)

(21) Appl. No.: 18/808,397

(22) Filed: Aug. 19, 2024

Related U.S. Application Data
(63) Continuation of application No. PCT/JP2023/000984, filed on Jan. 16, 2023.

(30) Foreign Application Priority Data
Feb. 21, 2022 (JP) 2022-025148

(51) Int. Cl. G03F 7/038; G03F 7/004; G03F 7/039

(52) U.S. Cl. CPC G03F 7/038; G03F 7/0045; G03F 7/0048; G03F 7/039

(57) ABSTRACT

According to an actinic ray-sensitive or radiation-sensitive resin composition including a resin (A) including a repeating unit (a1) having a partial structure in which a phenolic hydroxy group is protected with a structure represented by a formula (1) below, a pattern in which generation of defects is suppressed can be formed:

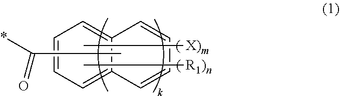

wherein X represents a halogen atom or an electron-withdrawing group, R₁ represents a hydroxy group or an organic group, k represents an integer of 0 to 3, n represents an integer of 0 to (4+2k), m represents an integer of 1 to (5+2k), satisfying a relationship of 1≤(n+m)≤(5+2k), and a plurality of R₁'s and X's may be the same or different according to an integer of n and m respectively, and * represents a bonding site to an oxygen atom of the phenolic hydroxy group.

### CROSS REFERENCE TO RELATED APPLICATION

This is a continuation of International Application No. PCT/JP2023/000984 filed on Jan. 16, 2023, and claims priority from Japanese Patent Application No. 2022-o25148 filed on Feb. 21, 2022, the entire disclosures of which are incorporated herein by reference.

### BACKGROUND OF THE INVENTION

### 1. Field of the Invention

The present invention relates to an actinic ray-sensitive or radiation-sensitive resin composition, an actinic ray-sensitive or radiation-sensitive film, a pattern forming method, a method for producing an electronic device, a compound, and a resin.

### 2. Description of the Related Art

In processes for producing semiconductor devices such as ICs (Integrated Circuits) or LSIs, microfabrication by lithography using photoresist compositions has been performed. In recent years, with an increase in the degree of integration of integrated circuits, formation of ultrafine patterns in the submicron range or the quarter micron range has come to be in demand. With this, there is a trend for exposure wavelengths toward shorter wavelengths from the g-line to the i-line further to the KrF excimer laser beam; currently, exposure apparatuses using, as light sources, the ArF excimer laser having a wavelength of 193 nm have been developed. In addition, as a technique of further increasing the resolving power, a technique in which the space between a projection lens and a sample is filled with a liquid having a high refractive index (hereafter, also referred to as “immersion liquid”), what is called, the immersion method has been developed.

Furthermore, at present, in addition to excimer laser beams, lithography using an electron beam (EB: Electron Beam), X-rays, extreme ultraviolet rays (EUV: Extreme Ultraviolet), or the like has also been developed. With this, chemical amplification resist compositions that are effectively sensitive to various radiations and have high sensitivity and high resolution and resins and the like used for the chemical amplification resist compositions have been developed.

For example, WO2020/235608A describes, as a base component included in a resist composition, a resin including a repeating unit derived from p-hydroxystyrene and a repeating unit having an acid-decomposable group.

### SUMMARY OF THE INVENTION

Patterns formed in workpieces desirably have a less number of defects. The term “defects” used herein means unintended recesses, chipping, or disconnection in patterns, patterns that do not have intended sizes, or the like. However, related-art resist compositions using the above-described resin in WO2020/235608A fail to provide sufficient suppression of generation of defects.

Accordingly, an object of the present invention is to provide an actinic ray-sensitive or radiation-sensitive resin composition that enables formation of a pattern in which generation of defects is suppressed, an actinic ray-sensitive or radiation-sensitive resin film formed from the actinic ray-sensitive or radiation-sensitive resin composition, a pattern forming method and a method for producing an electronic device that use the actinic ray-sensitive or radiation-sensitive resin composition, and a compound and a resin that can be suitably used in the actinic ray-sensitive or radiation-sensitive resin composition.

The inventors of the present invention have found that the following features can address the above-described object.

[1]

An actinic ray-sensitive or radiation-sensitive resin composition containing a resin (A) including a repeating unit (a1) having a partial structure in which a phenolic hydroxy group is protected with a structure represented by a formula (1) below:

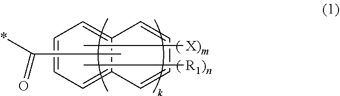

wherein, in the formula (1), X represents a halogen atom or an electron-withdrawing group, R₁ represents a hydroxy group or an organic group, k represents an integer of 0 to 3, n represents an integer of 0 to (4+2k), m represents an integer of 1 to (5+2k), wherein a relationship of 1≤(n+m)≤(5+2k) is satisfied, when n represents an integer of 2 or more, a plurality of R₁'s may be the same or different, when m represents an integer of 2 or more, a plurality of X's may be the same or different, and * represents a bonding site to an oxygen atom of the phenolic hydroxy group.
   [2]

The actinic ray-sensitive or radiation-sensitive resin composition according to [1], wherein the repeating unit (a1) is a repeating unit derived from a monomer represented by a formula (2) or (3) below:

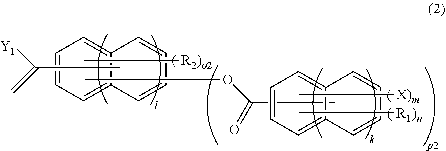

wherein, in the formula (2), Y₁ represents a hydrogen atom, a hydroxy group, a halogen atom, an alkyl group, or a halogenated alkyl group, X represents a halogen atom or an electron-withdrawing group, R₁ represents a hydroxy group or an organic group, R₂ represents a hydroxy group, a halogen atom, or an organic group, k represents an integer of 0 to 3, n represents an integer of 0 to (4+2k), m represents an integer of 1 to (5+2k), wherein a relationship of 1≤(n+m)≤(5+2k) is satisfied, when n represents an integer of 2 or more, a plurality of R₁'s may be the same or different, when m represents an integer of 2 or more, a plurality of X's may be the same or different, I represents an integer of 0 to 2, 02 represents an integer of 0 to (4+2l), p2 represents an integer of 1 to (5+2l), wherein a relationship of 1≤(o2+p2)≤(5+2l) is satisfied, when o2 represents an integer of 2 or more, a plurality of R₂'s may be the same or different, and when p2 represents an integer of 2 or more, a plurality of X's, R₁'s, k's, m's, and n's may be the same or different, and

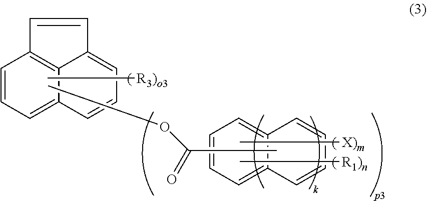

in the formula (3), X represents a halogen atom or an electron-withdrawing group, R₁ represents a hydroxy group or an organic group, R₃ represents a hydroxy group, a halogen atom, or an organic group, k represents an integer of 0 to 3, n represents an integer of 0 to (4+2k), m represents an integer of 1 to (5+2k), wherein a relationship of 1≤(n+m)≤(5+2k) is satisfied, when n represents an integer of 2 or more, a plurality of R₁'s may be the same or different, when m represents an integer of 2 or more, a plurality of X's may be the same or different, o3 represents an integer of 0 to 5, p3 represents an integer of 1 to 6, wherein a relationship of 1≤(o3+p3)≤6 is satisfied, when o3 represents an integer of 2 or more, a plurality of R₃'s may be the same or different, and when p3 represents an integer of 2 or more, a plurality of X's, R₁'s, k's, m's, and n's may be the same or different.
   [3]

The actinic ray-sensitive or radiation-sensitive resin composition according to [1] or [2], wherein X in the formula (1), (2), or (3) represents a halogen atom, a halogenated alkyl group, a nitro group, a cyano group, or a —C(═O)OR group where R represents a hydrocarbon group.

[4]

The actinic ray-sensitive or radiation-sensitive resin composition according to any one of [1] to [3], further containing a photoacid generator and a solvent. [5]

The actinic ray-sensitive or radiation-sensitive resin composition according to any one of [1] to [4], wherein the resin (A) further has a repeating unit (a2) having an acid-decomposable group.

[6]

The actinic ray-sensitive or radiation-sensitive resin composition according to [5], wherein the repeating unit (a2) is a repeating unit derived from a monomer represented by any one of formulas (4) to (6) below:

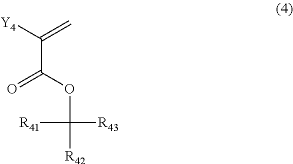

wherein, in the formula (4), Y₄ represents a hydrogen atom, a fluorine atom, or an alkyl group, R₄₁, R₄₂, and R₄₃ each independently represent an organic group, and two among R₄₁, R₄₂, and R₄₃ may be bonded together to form a ring,

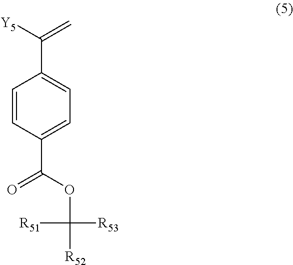

wherein, in the formula (5), Y₅ represents a hydrogen atom, a fluorine atom, or an alkyl group, R₅₁, R₅₂, and R₅₃ each independently represent an organic group, and two among R₅₁, R₅₂, and R₅₃ may be bonded together to form a ring, and

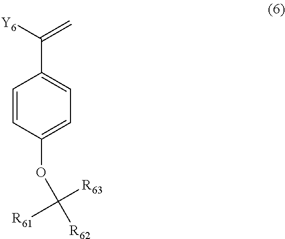

wherein, in the formula (6), Y₆ represents a hydrogen atom, a fluorine atom, or an alkyl group, R₆₁, R₆₂, and R₆₃ each independently represent an organic group, and two among R₆₁, R₆₂, and R₆₃ may be bonded together to form a ring.
   [7]

An actinic ray-sensitive or radiation-sensitive film formed from the actinic ray-sensitive or radiation-sensitive resin composition according to any one of [1] to [6].

[8]

A pattern forming method including:
using the actinic ray-sensitive or radiation-sensitive resin composition according to any one of [1] to [6] to form an actinic ray-sensitive or radiation-sensitive film on a substrate;
exposing the actinic ray-sensitive or radiation-sensitive film; and
using a developer to develop the exposed actinic ray-sensitive or radiation-sensitive film to form a pattern.
   [9]

A method for producing an electronic device, the method including the pattern forming method according to [8].

A compound represented by a formula (2) or (3) below:

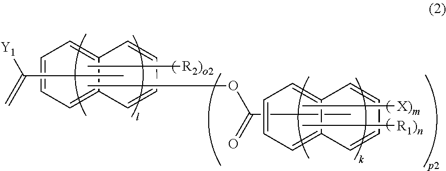

wherein, in the formula (2), Y₁ represents a hydrogen atom, a hydroxy group, a halogen atom, an alkyl group, or a halogenated alkyl group, X represents a halogen atom or an electron-withdrawing group, R₁ represents a hydroxy group or an organic group, R₂ represents a hydroxy group, a halogen atom, or an organic group, k represents an integer of 0 to 3, n represents an integer of 0 to (4+2k), m represents an integer of 1 to (5+2k), wherein a relationship of 1≤(n+m)≤(5+2k) is satisfied, when n represents an integer of 2 or more, a plurality of R₁'s may be the same or different, when m represents an integer of 2 or more, a plurality of X's may be the same or different, 1 represents an integer of 0 to 2, 02 represents an integer of 0 to (4+2l), p2 represents an integer of 1 to (5+2l), wherein a relationship of 1≤(o2+p2)≤(5+2l) is satisfied, when o2 represents an integer of 2 or more, a plurality of R₂'s may be the same or different, and when p2 represents an integer of 2 or more, a plurality of X's, R₁'s, k's, m's, and n's may be the same or different, and

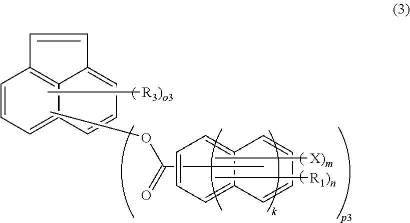

wherein in the formula (3), X represents a halogen atom or an electron-withdrawing group, R₁ represents a hydroxy group or an organic group, R₃ represents a hydroxy group, a halogen atom, or an organic group, k represents an integer of 0 to 3, n represents an integer of 0 to (4+2k), m represents an integer of 1 to (5+2k), wherein a relationship of 1≤(n+m)≤(5+2k) is satisfied, when n represents an integer of 2 or more, a plurality of R₁'s may be the same or different, when m represents an integer of 2 or more, a plurality of X's may be the same or different, o3 represents an integer of 0 to 5, p3 represents an integer of 1 to 6, wherein a relationship of 1≤(o3+p3)≤6 is satisfied, when o3 represents an integer of 2 or more, a plurality of R₃'s may be the same or different, and when p3 represents an integer of 2 or more, a plurality of X's, R₁'s, k's, m's, and n's may be the same or different.

The compound according to [10], wherein, in the formula (2) or (3), X represents a halogen atom, a halogenated alkyl group, a nitro group, a cyano group, or a —C(═O)OR group where R represents a hydrocarbon group.

A resin containing a repeating unit derived from a monomer represented by a formula (2) or (3) below:

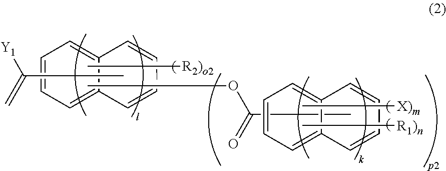

wherein, in the formula (2), Y₁ represents a hydrogen atom, a hydroxy group, a halogen atom, an alkyl group, or a halogenated alkyl group, X represents a halogen atom or an electron-withdrawing group, R₁ represents a hydroxy group or an organic group, R₂ represents a hydroxy group, a halogen atom, or an organic group, k represents an integer of 0 to 3, n represents an integer of 0 to (4+2k), m represents an integer of 1 to (5+2k), wherein a relationship of 1≤(n+m)≤(5+2k) is satisfied, when n represents an integer of 2 or more, a plurality of R₁'s may be the same or different, when m represents an integer of 2 or more, a plurality of X's may be the same or different, 1 represents an integer of 0 to 2, o2 represents an integer of 0 to (4+2l), p2 represents an integer of 1 to (5+2l), wherein a relationship of 1≤(o2+p2)≤(5+2l) is satisfied, when o2 represents an integer of 2 or more, a plurality of R₂'s may be the same or different, and when p2 represents an integer of 2 or more, a plurality of X's, R₁'s, k's, m's, and n's may be the same or different, and

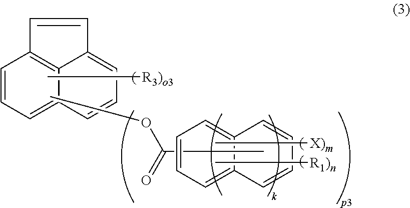

wherein, in the formula (3), X represents a halogen atom or an electron-withdrawing group, R₁ represents a hydroxy group or an organic group, R₃ represents a hydroxy group, a halogen atom, or an organic group, k represents an integer of 0 to 3, n represents an integer of 0 to (4+2k), m represents an integer of 1 to (5+2k), wherein a relationship of 1≤(n+m)≤(5+2k) is satisfied, when n represents an integer of 2 or more, a plurality of R₁'s may be the same or different, when m represents an integer of 2 or more, a plurality of X's may be the same or different, o3 represents an integer of 0 to 5, p3 represents an integer of 1 to 6, wherein a relationship of 1≤(o3+p3)≤6 is satisfied, when o3 represents an integer of 2 or more, a plurality of R₃'s may be the same or different, and when p3 represents an integer of 2 or more, a plurality of X's, R₁'s, k's, m's, and n's may be the same or different.

The present invention can provide an actinic ray-sensitive or radiation-sensitive resin composition that enables formation of a pattern in which generation of defects is suppressed, an actinic ray-sensitive or radiation-sensitive resin film formed from the actinic ray-sensitive or radiation-sensitive resin composition, a pattern forming method and a method for producing an electronic device that use the actinic ray-sensitive or radiation-sensitive resin composition, and a compound and a resin that can be suitably used in the actinic ray-sensitive or radiation-sensitive resin composition.

### DESCRIPTION OF THE PREFERRED EMBODIMENTS

Hereinafter, the present invention will be described in detail.

Features may be described below with reference to representative embodiments according to the present invention; however, the present invention is not limited to the embodiments.

In this Specification, for written forms of groups (atomic groups), written forms without referring to substituted or unsubstituted encompass, in addition to groups not having a substituent, groups including a substituent without departing from the spirit and scope of the present invention. For example, “alkyl group” encompasses not only alkyl groups not having a substituent (unsubstituted alkyl groups), but also alkyl groups having a substituent (substituted alkyl groups). In this Specification, “organic group” refers to a group including at least one carbon atom.

The substituent is preferably a monovalent substituent unless otherwise specified.

In this Specification, in the case of using a phrase “may have a substituent”, the type of the substituent, the position of the substituent, and the number of such substituents are not particularly limited. The number of the substituents may be, for example, one, two, three, or more. Examples of the substituents include monovalent non-metallic atomic groups except for the hydrogen atom and, for example, can be selected from the group consisting of the following Substituents T.

### Substituents T

Substituents T include halogen atoms such as a fluorine atom, a chlorine atom, a bromine atom, and an iodine atom; alkoxy groups such as a methoxy group, an ethoxy group, and a tert-butoxy group; aryloxy groups such as a phenoxy group and a p-tolyloxy group; alkoxycarbonyl groups such as a methoxycarbonyl group, a butoxycarbonyl group, and a phenoxycarbonyl group; acyloxy groups such as an acetoxy group, a propionyloxy group, and a benzoyloxy group; acyl groups such as an acetyl group, a benzoyl group, an isobutyryl group, an acryloyl group, a methacryloyl group, and a methoxalyl group; alkylsulfanyl groups such as a methylsulfanyl group and a tert-butylsulfanyl group; arylsulfanyl groups such as a phenylsulfanyl group and a p-tolylsulfanyl group; alkyl groups; cycloalkyl groups; aryl groups; heteroaryl groups; a hydroxyl group; a carboxyl group; a sulfo group; a cyano group; alkylaminocarbonyl groups; arylaminocarbonyl groups; a sulfonamide group; a silyl group; an amino group; monoalkylamino groups; dialkylamino groups; arylamino groups; a nitro group; a formyl group; and combinations of the foregoing.

In this Specification, “actinic ray” or “radiation” means, for example, the emission line spectrum of a mercury lamp, far-ultraviolet rays represented by excimer lasers, extreme ultraviolet rays (EUV: Extreme Ultraviolet), X-rays, or an electron beam (EB: Electron Beam).

In this Specification, “light” means an actinic ray or a radiation.

In this Specification, “exposure” includes, unless otherwise specified, not only exposure using, for example, the emission line spectrum of a mercury lamp, far-ultraviolet rays represented by excimer lasers, extreme ultraviolet rays, or X-rays, but also patterning using a corpuscular beam such as an electron beam or an ion beam.

In this Specification, “a value ‘to’ another value” is used to mean that it includes the value and the other value as the lower limit value and the upper limit value.

In this Specification, the bonding directions of divalent linking groups are not limited to the written forms unless otherwise specified. For example, in a compound represented by a formula “X—Y—Z” where Y is —COO—, Y may be —CO—O— or may be —O—CO—. The compound may be “X—CO—O—Z” or may be “X—O—CO—Z”.

In this Specification, (meth)acrylate represents acrylate and methacrylate, and (meth)acrylic represents acrylic and methacrylic.

In this Specification, the weight-average molecular weight (Mw), the number-average molecular weight (Mn), and the dispersity (hereafter, also referred to as “molecular weight distribution”) (Mw/Mn) are defined as polystyrene-equivalent values measured using a GPC (Gel Permeation Chromatography) apparatus (HLC-8120GPC manufactured by Tosoh Corporation) by GPC measurement (solvent: tetrahydrofuran, flow rate (sample injection amount): 10 μL, column: TSK gel Multipore HXL-M manufactured by Tosoh Corporation, column temperature: 40° C., flow rate: 1.0 mL/min, detector: differential refractive index detector (Refractive Index Detector))

In this Specification, the acid dissociation constant (pKa) represents pKa in an aqueous solution, specifically, a value determined using the following Software package 1, on the basis of the Hammett's substituent constant and the database of values in publicly known documents, by calculation.

Software package 1: Advanced Chemistry Development (ACD/Labs) Software V8.14 for Solaris (1994-2007 ACD/Labs)

Alternatively, pKa can be determined by the molecular orbital calculation method. Specifically, this method may be a method of, on the basis of a thermodynamic cycle, calculating H′ dissociation free energy in an aqueous solution to achieve the determination. As the calculation method for H dissociation free energy, for example, DFT (density function theory) can be performed for calculation; however, other various methods have been reported in documents and the like and the calculation method is not limited to DFT. Note that there are a plurality of pieces of software for performing DFT, such as Gaussian 16.

In this Specification, as described above, pKa refers to a value determined using Software package 1, on the basis of the Hammett's substituent constant and the database of values in publicly known documents, by calculation; however, when use of this method cannot determine pKa, a value determined on the basis of DFT (density function theory) using Gaussian 16 is employed.

In this Specification, as described above, pKa refers to “pKa in an aqueous solution”; however, when pKa in an aqueous solution cannot be determined, “pKa in a dimethyl sulfoxide (DMSO) solution” is employed.

“Solid content” means components forming the actinic ray-sensitive or radiation-sensitive film and does not include solvents. As long as a component forms the actinic ray-sensitive or radiation-sensitive film, even when the component has the form of liquid, it is regarded as the solid content.

### Actinic Ray-Sensitive or Radiation-Sensitive Resin Composition

Hereinafter, the actinic ray-sensitive or radiation-sensitive resin composition of the present invention will be described.

An actinic ray-sensitive or radiation-sensitive resin composition of the present invention is:
an actinic ray-sensitive or radiation-sensitive resin composition containing a resin (A) including a repeating unit (a1) having a partial structure in which a phenolic hydroxy group is protected with a structure represented by a formula (1) below:

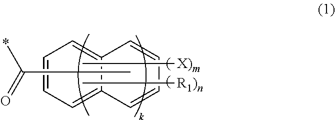

wherein, in the formula (1), X represents a halogen atom or an electron-withdrawing group, R₁ represents a hydroxy group or an organic group, k represents an integer of 0 to 3, n represents an integer of 0 to (4+2k), m represents an integer of 1 to (5+2k), provided that a relationship of 1≤(n+m)≤(5+2k) is satisfied; when n represents an integer of 2 or more, a plurality of R₁'s may be the same or different; when m represents an integer of 2 or more, a plurality of X's may be the same or different; and * represents a bonding site to an oxygen atom of the phenolic hydroxy group.

Such features enable formation of a pattern in which generation of defects is suppressed.

The mechanism by which the present invention can provide the above-described advantages is not necessarily clear, but is inferred by the inventors of the present invention as follows.

The above-described specific structure of the repeating unit (a1) included in the resin (A) used in the actinic ray-sensitive or radiation-sensitive resin composition of the present invention has a carbonyl group to which an electron-withdrawing group is bonded. This group has high interactivity with an acid, can appropriately control the diffusion of an acid generated in the actinic ray-sensitive or radiation-sensitive film, and can suppress generation of defects derived from excessive acid diffusion.

In addition, the specific structure has high alkali decomposability. For this reason, for example, in the formation of a pattern using the resist composition of the present invention, in the case of performing development using an alkali developer, the specific structure is decomposed, so that the resin (A) has increased solubility in the developer. This can also result in suppression of generation of defects caused by an undissolved residue of the resin in the developer, inferentially.

The actinic ray-sensitive or radiation-sensitive resin composition of the present invention (hereafter, also referred to as “composition of the present invention”) is typically a resist composition, and may be a positive resist composition or may be a negative resist composition. The composition of the present invention may be a resist composition for alkali development or may be a resist composition for organic solvent development.

The composition of the present invention may be a chemical amplification resist composition or may be a non-chemical amplification resist composition. The composition of the present invention is typically a chemical amplification resist composition.

### Components of Actinic Ray-Sensitive or Radiation-Sensitive Resin Composition

Hereinafter, components that the actinic ray-sensitive or radiation-sensitive resin composition can include will be described in detail.

### Resin (A)

### Repeating Unit (a1)

The resin (A) contained in the composition of the present invention includes a repeating unit (a1) having a partial structure in which a phenolic hydroxy group is protected with a structure represented by a formula (1) below:

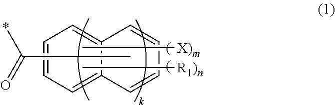

in the formula (1), X represents a halogen atom or an electron-withdrawing group, R₁ represents a hydroxy group or an organic group, k represents an integer of 0 to 3, n represents an integer of 0 to (4+2k), m represents an integer of 1 to (5+2k), provided that a relationship of 1≤(n+m)≤(5+2k) is satisfied; when n represents an integer of 2 or more, a plurality of R₁'s may be the same or different; when m represents an integer of 2 or more, a plurality of X's may be the same or different; and * represents a bonding site to an oxygen atom of the phenolic hydroxy group.

In the formula (1), X represents a halogen atom or an electron-withdrawing group.

The halogen atom represented by X may be a fluorine atom, a chlorine atom, a bromine atom, or an iodine atom.

The electron-withdrawing group represented by X may be, for example, a halogenated alkyl group, a nitro group, a cyano group, or a —C(═O)OR group (where R represents a hydrocarbon group).

The halogenated alkyl group may be, for example, an alkyl group having 1 to 12 carbon atoms and substituted with a halogen atom, preferably a trifluoromethyl group, a pentafluoroethyl group, or a nonafluorobutyl group, and more preferably a trifluoromethyl group.

In the —C(═O)OR group, the hydrocarbon group represented by R may be, for example, an alkyl group, an alkenyl group, an alkynyl group, a cycloalkyl group, or an aryl group, preferably an alkyl group having 1 to 15 carbon atoms, and more preferably a methyl group.

X is preferably a halogen atom, a halogenated alkyl group, a nitro group, a cyano group, or a —C(═O) OR group, more preferably a fluorine atom, a bromine atom, an iodine atom, a trifluoromethyl group, a nitro group, or a —C(═O)OCH₃ group, and still more preferably a fluorine atom or an iodine atom.

In the formula (1), R₁ represents a hydroxy group or an organic group.

The organic group represented by R₁ may be, for example, an alkyl group (linear or branched), an alkoxy group (linear or branched), an alkenyl group (linear or branched), a cycloalkyl group (monocyclic or polycyclic), or an aryl group (monocyclic or polycyclic).

The alkyl group may be, for example, an alkyl group having 1 to 15 carbon atoms such as a methyl group, an ethyl group, an n-propyl group, or a t-butyl group, and is preferably a methyl group.

The alkoxy group may be, for example, an alkoxy group having 1 to 15 carbon atoms such as a methoxy group, an ethoxy group, an n-propyloxy group, or a t-butyloxy group, and is more preferably a methoxy group.

The alkenyl group may be, for example, an alkenyl group having 2 to 15 carbon atoms such as a vinyl group.

The cycloalkyl group may be, for example, a cycloalkyl group having 3 to 20 carbon atoms such as a cyclopentyl group or a cyclohexyl group.

The aryl group is preferably an aryl group having 6 to 15 carbon atoms such as a phenyl group or a naphthyl group, and more preferably a phenyl group.

The organic group represented by R₁ may further have a substituent. In such a case of further having a substituent, the substituent may be, for example, a halogenated alkyl group such as a trifluoromethyl group, a —C(═O) OR group (where R represents a hydrocarbon group), a cyano group, a hydroxy group, a carboxy group, or a —C—OR group (where R represents a hydrocarbon group).

R₁ is preferably a hydroxyl group, an alkyl group, an alkoxy group, or an aryl group, and more preferably a hydroxyl group, a methyl group, a methoxy group, a phenyl group, or a trifluoromethylphenyl group.

In the formula (1), k represents an integer of 0 to 3, preferably 0 or 1, and more preferably 0.

In the formula (1), n represents an integer of 0 to (4+2k), m represents an integer of 1 to (5+2k), provided that a relationship of 1≤(n+m)≤(5+2k) is satisfied.

n is preferably an integer of 0 to 2, and more preferably 0.

m is preferably an integer of 1 to 3, and more preferably 1 or 2.

Repeating Unit Derived from Monomer Represented by Formula (2) or (3)

The repeating unit (a1) is preferably a repeating unit derived from a monomer represented by a formula (2) or (3) below.

Note that the present invention also relates to a compound represented by the following formula (2) or (3), and a resin containing a repeating unit derived from a monomer represented by the following formula (2) or (3).

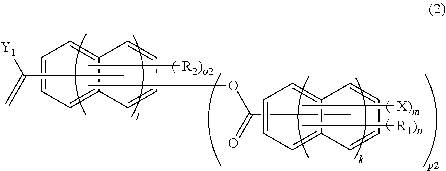

In the formula (2), Y₁ represents a hydrogen atom, a hydroxy group, a halogen atom, an alkyl group, or a halogenated alkyl group, X represents a halogen atom or an electron-withdrawing group, R₁ represents a hydroxy group or an organic group, R₂ represents a hydroxy group, a halogen atom, or an organic group, k represents an integer of 0 to 3, n represents an integer of 0 to (4+2k), m represents an integer of 1 to (5+2k), provided that a relationship of 1≤(n+m)≤(5+2k) is satisfied; when n represents an integer of 2 or more, a plurality of R₁'s may be the same or different; when m represents an integer of 2 or more, a plurality of X's may be the same or different; 1 represents an integer of 0 to 2, 02 represents an integer of 0 to (4+21), p2 represents an integer of 1 to (5+2l), provided that a relationship of 1≤(o2+p2)≤(5+21) is satisfied; when o2 represents an integer of 2 or more, a plurality of R₂'s may be the same or different; and when p2 represents an integer of 2 or more, a plurality of X's, R₁'s, k's, m's, and n's may be the same or different.

In the formula (2), X, R₁, k, n, and m have the same definitions as X, R₁, k, n, and m in the formula (1), and preferred examples thereof are also the same.

In the formula (2), Y₁ represents a hydrogen atom, a hydroxy group, a halogen atom, an alkyl group, or a halogenated alkyl group.

The halogen atom represented by Y₁ may be, for example, a fluorine atom, a chlorine atom, a bromine atom, or an iodine atom.

The alkyl group represented by Y₁ may be, for example, a linear or branched alkyl group having 1 to 12 carbon atoms, is preferably a methyl group or an ethyl group, and more preferably a methyl group.

The halogenated alkyl group represented by Y₁ may be, for example, a group in which the above-described alkyl group is substituted with a halogen atom, such as a trifluoromethyl group.

Y₁ is preferably a hydrogen atom, a fluorine-substituted or unsubstituted alkyl group having 1 to 12 carbon atoms, or a fluorine atom, more preferably a hydrogen atom, a methyl group, a trifluoromethyl group, or a fluorine atom, still more preferably a hydrogen atom or a methyl group, and particularly preferably a hydrogen atom.

In the formula (2), R₂ represents a hydroxy group, a halogen atom, or an organic group.

The halogen atom represented by R₂ may be, for example, a fluorine atom, a chlorine atom, a bromine atom, or an iodine atom.

The organic group represented by R₂ may be, for example, the above-described organic group represented by R₁.

In the formula (2), 1 represents an integer of 0 to 2, and is preferably 0 or 1.

In the formula (2), o2 represents an integer of 0 to (4+2l), p2 represents an integer of 1 to (5+2l), provided that a relationship of 1≤(o2+p2)≤(5+2l) is satisfied.

o2 is preferably 0 or 1, and more preferably 0.

p2 is preferably 1 or 2.

The monomer represented by the above-described formula (2) is preferably a monomer represented by a formula (2-1) or (2-2) below.

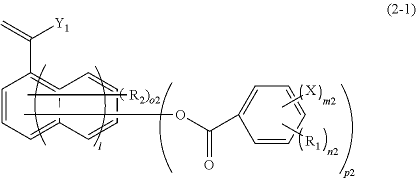

In the formula (2-1), Y₁, X, R₁, R₂, 1, o2, and p2 have the same definitions as Y₁, X, R₁, R₂, 1, o2, and p2 in the formula (2), and preferred examples thereof are also the same.

In the formula (2-1), n2 represents an integer of 0 to 4, m2 represents an integer of 1 to 5, provided that a relationship 1≤(n2+m2)≤5 is satisfied.

n2 is preferably an integer of 0 to 2, and more preferably 0.

m2 is preferably an integer of 1 to 3, and more preferably 1 or 2.

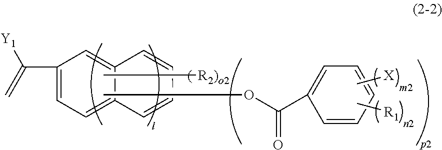

In the formula (2-2), Y₁, X, R₁, R₂, n2, m2, 1, o2, and p2 have the same definitions as Y₁, X, R₁, R₂, n2, m2, 1, o2, and p2 in the formula (2-1), and preferred examples thereof are also the same.

The monomer represented by the above-described formula (2-1) or (2-2) is more preferably a monomer represented by the following formula (2-1A) or (2-2A).

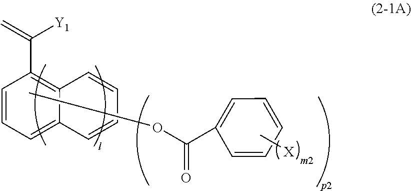

In the formula (2-1A), Y₁, X, m2, 1, and p2 have the same definitions as Y₁, X, m2, 1, and p2 in the formula (2-1), and preferred examples thereof are also the same.

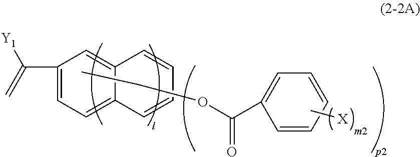

In the formula (2-2A), Y₁, X, m2, 1, and p2 have the same definitions as Y₁, X, m2, 1, and p2 in the formula (2-2), and preferred examples thereof are also the same.

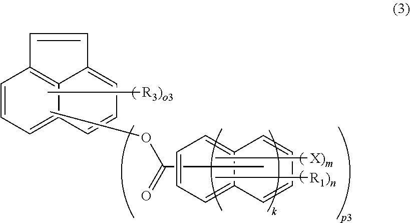

In the formula (3), X represents a halogen atom or an electron-withdrawing group, R₁ represents a hydroxy group or an organic group, R₃ represents a hydroxy group, a halogen atom, or an organic group, k represents an integer of 0 to 3, n represents an integer of 0 to (4+2k), m represents an integer of 1 to (5+2k), provided that a relationship of 1≤(n+m)≤(5+2k) is satisfied; when n represents an integer of 2 or more, a plurality of R₁'s may be the same or different; when m represents an integer of 2 or more, a plurality of X's may be the same or different, o3 represents an integer of 0 to 5, p3 represents an integer of 1 to 6, provided that a relationship of 1≤(o3+p3)≤6 is satisfied; when o3 represents an integer of 2 or more, a plurality of R₃'s may be the same or different; and when p3 represents an integer of 2 or more, a plurality of X's, R₁'s, k's, m's, and n's may be the same or different.

In the formula (3), X, R₁, k, n, and m have the same definitions as X, R₁, k, n, and m in the formula (1), and preferred examples thereof are also the same.

In the formula (3), R₃ represents a hydroxy group, a halogen atom, or an organic group.

The halogen atom represented by R₃ may be, for example, a fluorine atom, a chlorine atom, a bromine atom, or an iodine atom.

The organic group represented by R₃ may be, for example, the above-described organic group represented by R₁.

In the formula (3), o3 represents an integer of 0 to 5, p3 represents an integer of 1 to 6, provided that a relationship of 1≤(o3+p3)≤6 is satisfied.

o3 is preferably 0 or 1, and more preferably 0.

p3 is preferably 1 or 2, and more preferably 1.

The monomer represented by the above-described formula (3) is preferably a monomer represented by the following formula (3-1).

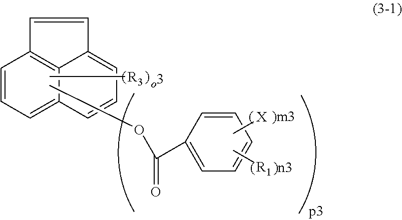

In the formula (3-1), X, R₁, R₃, o3, and p3 have the same definitions as X, R₁, R₃, o3, and p3 in the formula (3), and preferred examples thereof are also the same.

In the formula (3-1), n3 represents an integer of 0 to 4, m3 represents an integer of 1 to 5, provided that a relationship of 1≤(n3+m3)≤5 is satisfied.

n3 is preferably an integer of 0 to 2, and more preferably 0.

m3 is preferably an integer of 1 to 3, and more preferably 1 or 2.

The monomer represented by the above-described formula (3-1) is more preferably a monomer represented by the following formula (3-1A).

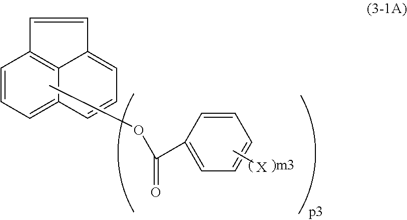

In the formula (3-1A), X, m3, and p3 have the same definitions as X, m3, and p3 in the formula (3-1), and preferred examples thereof are also the same.

The following are non-limiting specific examples of the monomer corresponding to the repeating unit (a1). In the following specific examples, Me represent a methyl group. Specific examples of the monomer represented by the formula (2) or (3) include, in the following specific examples, those corresponding to the monomer represented by the formula (2) or (3).

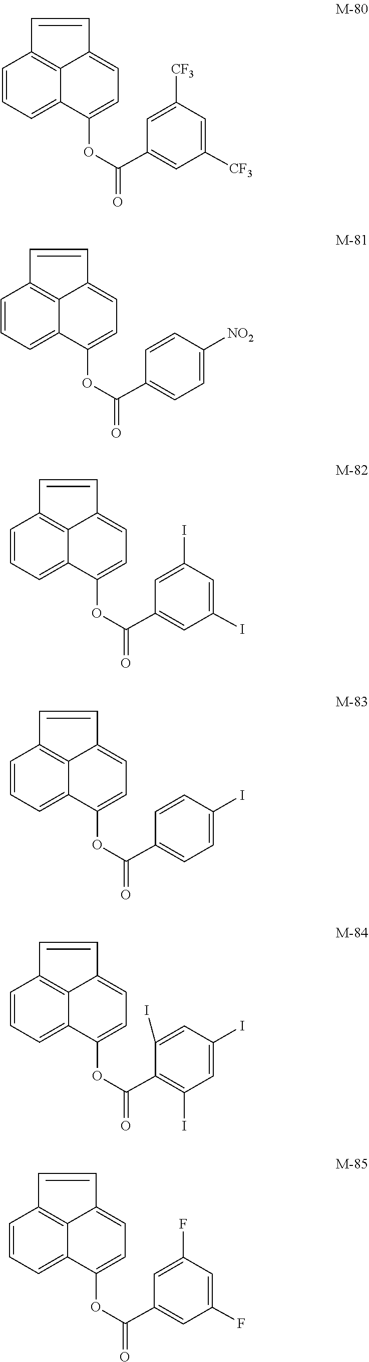

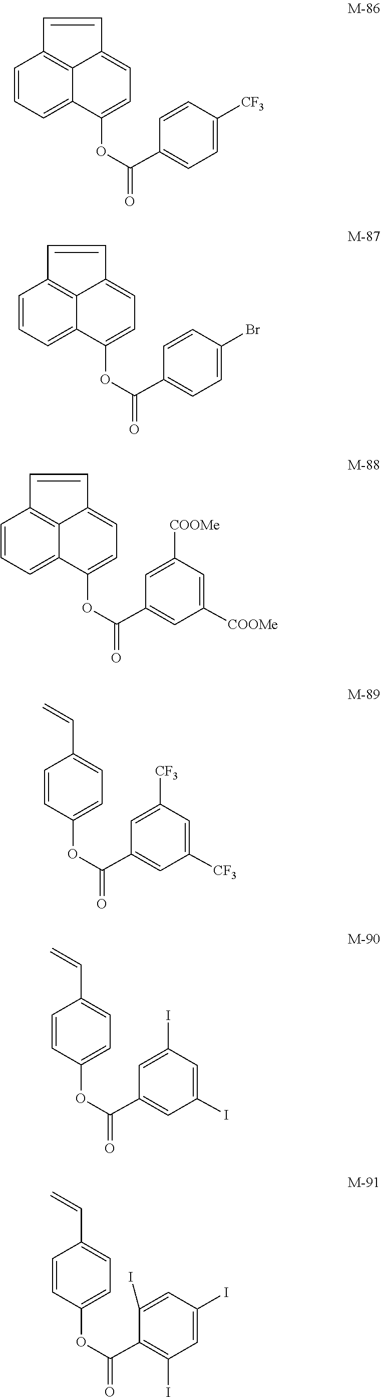

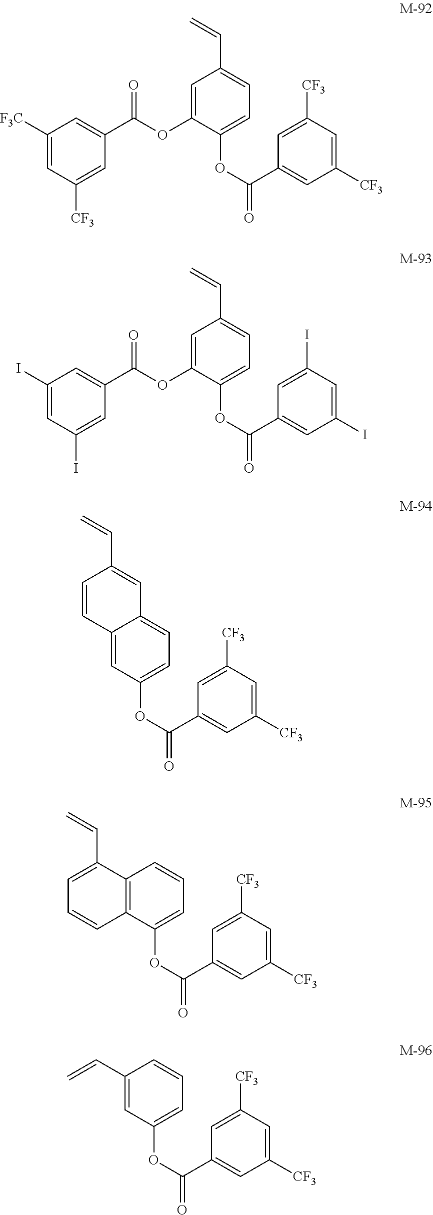

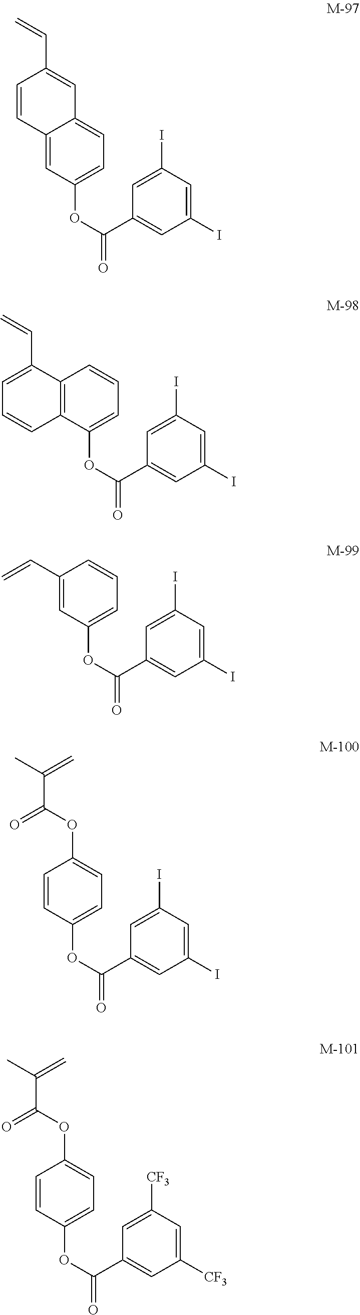

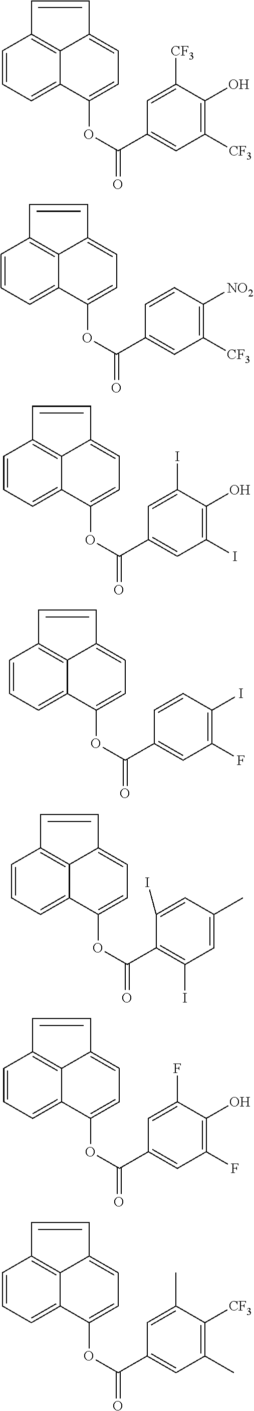

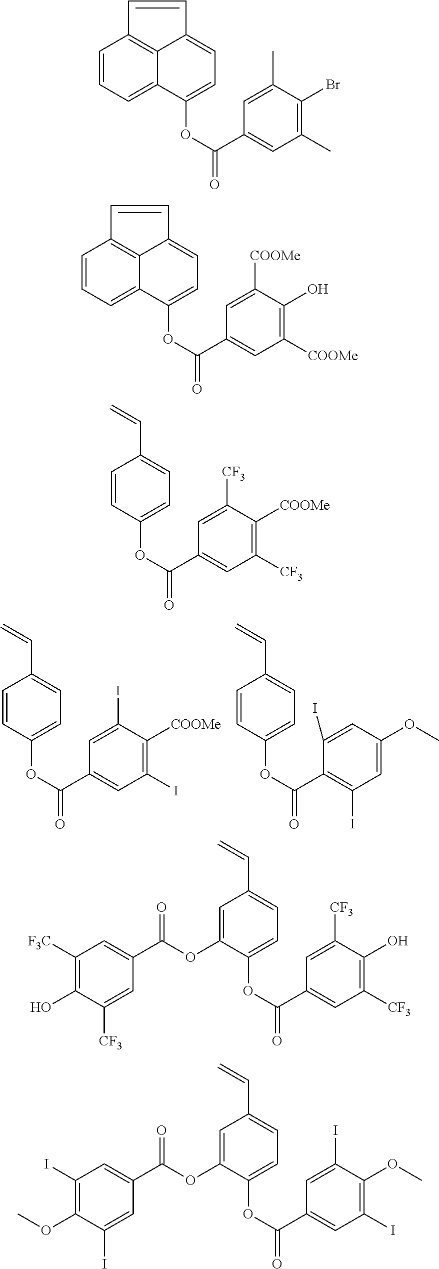

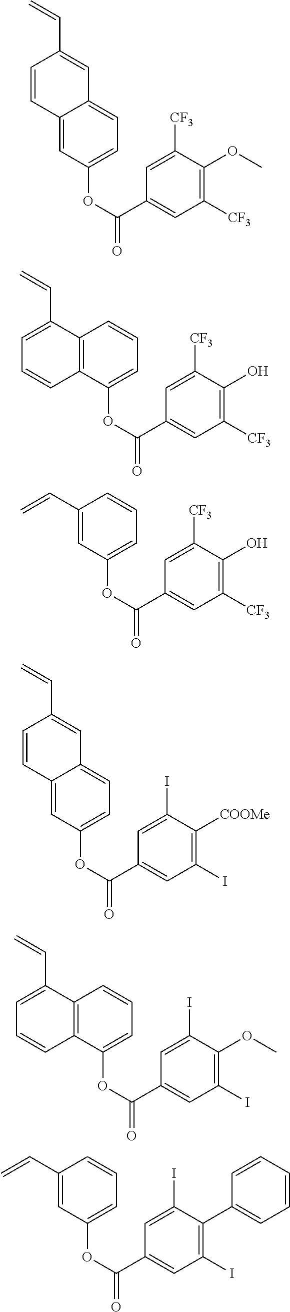

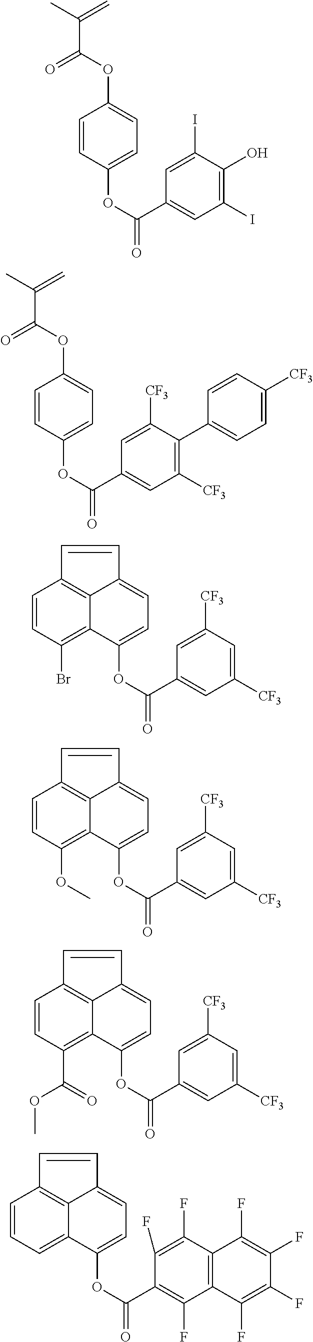

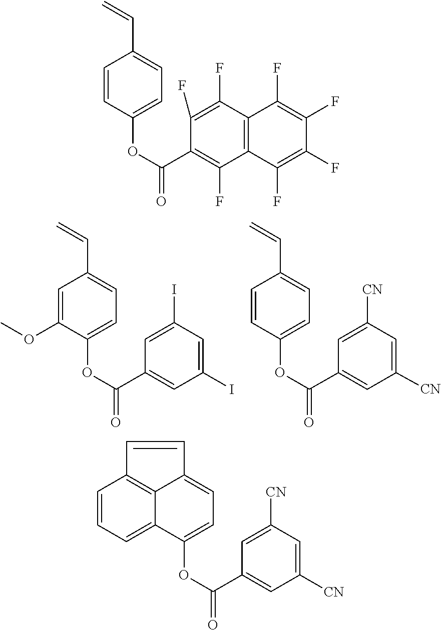

The content of the repeating unit (a1) is, relative to all the repeating units in the resin (A), preferably 2 mol % or more, more preferably 5 mol % or more, and still more preferably 10 mol % or more. The upper limit value relative to all the repeating units in the resin (A) is preferably 80 mol % or less, more preferably 70 mol % or less, and still more preferably 60 mol % or less.

### Repeating Unit (a2)

The resin (A) contained in the composition of the present invention includes a group that is decomposed by the action of an acid to provide increased polarity (hereafter, also referred to as an “acid-decomposable group”), and preferably includes a repeating unit (a2) having an acid-decomposable group.

When the resin (A) has an acid-decomposable group, in a pattern forming method in this Specification, typically, in the case of employing a developer that is an alkali developer, a positive-type pattern is suitably formed or, in the case of employing a developer that is an organic-based developer, a negative-type pattern is suitably formed.

Preferred examples of the repeating unit having an acid-decomposable group include, in addition to a repeating unit having an acid-decomposable group described later, a repeating unit having an acid-decomposable group including an unsaturated bond.

### Repeating Unit Having Acid-Decomposable Group

The acid-decomposable group refers to a group that is decomposed by the action of an acid to generate a polar group. The acid-decomposable group preferably has a structure in which the polar group is protected with a group (leaving group) that leaves by the action of an acid. Thus, the resin (A) has a repeating unit having a group that is decomposed by the action of an acid to generate a polar group. The resin having the repeating unit is subjected to the action of an acid to have increased polarity to have an increased degree of solubility in the alkali developer, but have a decreased degree of solubility in organic solvents.

The polar group is preferably an alkali soluble group; examples include acidic groups such as a carboxyl group, a phenolic hydroxyl group, fluorinated alcohol groups, a sulfonic acid group, a phosphoric acid group, a sulfonamide group, a sulfonylimide group, (alkylsulfonyl) (alkylcarbonyl)methylene groups, (alkylsulfonyl) (alkylcarbonyl)imide groups, bis(alkylcarbonyl)methylene groups, bis(alkylcarbonyl)imide groups, bis(alkylsulfonyl)methylene groups, bis(alkylsulfonyl)imide groups, tris(alkylcarbonyl)methylene groups, and tris(alkylsulfonyl)methylene groups, and an alcoholic hydroxy group.

In particular, the polar group is preferably a carboxyl group, a phenolic hydroxyl group, a fluorinated alcohol group (preferably a hexafluoroisopropanol group), or a sulfonic acid group.

Examples of the group that leaves by the action of an acid include groups represented by formulas (Y1) to (Y4).

—C(Rx₁)(Rx₂)(Rx₃) formula (Y1)

—C(═O)OC(Rx₁)(Rx₂)(Rx₃) formula (Y2)

—C(R₃₆)(R₃₇)(OR₃₈) formula (Y3)

—C(Rn)(H)(Ar) formula (Y4)

In the formula (Y1) and the formula (Y2), Rx₁ to Rx₃ each independently represent an alkyl group (linear or branched), a cycloalkyl group (monocyclic or polycyclic), an alkenyl group (linear or branched), or an aryl group (monocyclic or polycyclic). Note that, when Rx₁ to Rx₃ are all alkyl groups (linear or branched), at least two among Rx₁ to Rx₃ are preferably methyl groups.

In particular, Rx₁ to Rx₃ preferably each independently represent a linear or branched alkyl group, and Rx₁ to Rx₃ more preferably each independently represent a linear alkyl group.

Two among Rx₁ to Rx₃ may be bonded together to form a monocycle or a polycycle.

For Rx₁ to Rx₃, the alkyl group is preferably an alkyl group having 1 to 5 carbon atoms such as a methyl group, an ethyl group, an n-propyl group, an isopropyl group, an n-butyl group, an isobutyl group, or a t-butyl group.

For Rx₁ to Rx₃, the cycloalkyl group is preferably a monocyclic cycloalkyl group such as a cyclopentyl group or a cyclohexyl group, or a polycyclic cycloalkyl group such as a norbornyl group, a tetracyclodecanyl group, a tetracyclododecanyl group, or an adamantyl group.

For Rx₁ to Rx₃, the aryl group is preferably an aryl group having 6 to 10 carbon atoms and may be, for example, a phenyl group, a naphthyl group, or an anthryl group.

For Rx₁ to Rx₃, the alkenyl group is preferably a vinyl group.

The ring formed by bonding together two among Rx₁ to Rx₃ is preferably a cycloalkyl group. The cycloalkyl group formed by bonding together two among Rx₁ to Rx₃ is preferably a monocyclic cycloalkyl group such as a cyclopentyl group or a cyclohexyl group, or a polycyclic cycloalkyl group such as a norbornyl group, a tetracyclodecanyl group, a tetracyclododecanyl group, or an adamantyl group, and more preferably a monocyclic cycloalkyl group having 5 to 6 carbon atoms.

In the cycloalkyl group formed by bonding together two among Rx₁ to Rx₃, one of methylene groups constituting the ring may be replaced by a heteroatom such as an oxygen atom, a group including a heteroatom such as a carbonyl group, or a vinylidene group. In the cycloalkyl group, one or more ethylene groups constituting the cycloalkane ring may be replaced by vinylene groups.

The group represented by the formula (Y1) or the formula (Y2) preferably has a form in which, for example, Rx₁ is a methyl group or an ethyl group, and Rx₂ and Rx₃ are bonded together to form the above-described cycloalkyl group.

When the composition of the present invention is, for example, a resist composition used for EUV exposure, the alkyl groups, cycloalkyl groups, alkenyl groups, and aryl groups represented by Rx₁ to Rx₃ and the ring formed by bonding together two among Rx₁ to Rx₃ also preferably further have, as a substituent, a fluorine atom or an iodine atom.

In the formula (Y3), R₃₆ to R₃₈ each independently represent a hydrogen atom or a monovalent organic group. R₃₇ and R₃₈ may be bonded together to form a ring. The monovalent organic group may be an alkyl group, a cycloalkyl group, an aryl group, an aralkyl group, or an alkenyl group. R₃₆ is also preferably a hydrogen atom.

Note that the alkyl group, the cycloalkyl group, the aryl group, and the aralkyl group may include a heteroatom such as an oxygen atom and/or a group including a heteroatom such as a carbonyl group. For example, in the alkyl group, the cycloalkyl group, the aryl group, and the aralkyl group, one or more methylene groups may be replaced by a heteroatom such as an oxygen atom and/or a group including a heteroatom such as a carbonyl group.

R₃₈ and another substituent of the main chain of the repeating unit may be bonded together to form a ring. The group formed by bonding together R₃₈ and another substituent of the main chain of the repeating unit is preferably an alkylene group such as a methylene group.

When the resist composition is, for example, a resist composition used for EUV exposure, the monovalent organic groups represented by R₃₆ to R₃₈ and the ring formed by bonding together R₃₇ and R₃₈ also preferably further have, as a substituent, a fluorine atom or an iodine atom.

The formula (Y3) is preferably a group represented by the following formula (Y3-1).

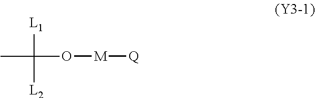

L₁ and L₂ above each independently represent a hydrogen atom, an alkyl group, a cycloalkyl group, an aryl group, or a group that is a combination of the foregoing (for example, a group that is a combination of an alkyl group and an aryl group).

M represents a single bond or a divalent linking group.

Q represents an alkyl group that may include a heteroatom, a cycloalkyl group that may include a heteroatom, an aryl group that may include a heteroatom, an amino group, an ammonium group, a mercapto group, a cyano group, an aldehyde group, or a group that is a combination of the foregoing (for example, a group that is a combination of an alkyl group and a cycloalkyl group).

In the alkyl group and the cycloalkyl group, for example, one of methylene groups may be replaced by a heteroatom such as an oxygen atom or a group including a heteroatom such as a carbonyl group.

Note that one of L₁ and L₂ is preferably a hydrogen atom and the other is preferably an alkyl group, a cycloalkyl group, an aryl group, or a group that is a combination of an alkylene group and an aryl group.

At least two among Q, M, and L₁ may be bonded together to form a ring (preferably a 5-membered or 6-membered ring).

From the viewpoint of forming finer patterns, L₂ is preferably a secondary or tertiary alkyl group, and more preferably a tertiary alkyl group. Examples of the secondary alkyl group include an isopropyl group, a cyclohexyl group, and a norbornyl group; examples of the tertiary alkyl group include a tert-butyl group and an adamantane group. In such examples, Tg (glass transition temperature) and activation energy are increased, so that film hardness is ensured and fogging can be suppressed.

When the composition of the present invention is, for example, a resist composition used for EUV exposure, the alkyl groups, cycloalkyl groups, aryl groups, and groups that are combinations of the foregoing represented by L₁ and L₂ also preferably further have, as a substituent, a fluorine atom or an iodine atom. The alkyl groups, the cycloalkyl groups, the aryl groups, and the aralkyl groups also preferably include, in addition to a fluorine atom and an iodine atom, a heteroatom such as an oxygen atom. Specifically, in the alkyl groups, the cycloalkyl groups, the aryl groups, and the aralkyl groups, for example, one of methylene groups may be replaced by a heteroatom such as an oxygen atom or a group including a heteroatom such as a carbonyl group.

When the composition of the present invention is, for example, a resist composition used for EUV exposure, in the alkyl group that may include a heteroatom, cycloalkyl group that may include a heteroatom, aryl group that may include a heteroatom, amino group, ammonium group, mercapto group, cyano group, aldehyde group, and group that is a combination of the foregoing represented by Q, such a heteroatom is also preferably a heteroatom selected from the group consisting of a fluorine atom, an iodine atom, and an oxygen atom.

In the formula (Y4), Ar represents an aromatic ring group. Rn represents an alkyl group, a cycloalkyl group, or an aryl group. Rn and Ar may be bonded together to form a non-aromatic ring. Ar is preferably an aryl group.

When the composition of the present invention is, for example, a resist composition used for EUV exposure, the aromatic ring group represented by Ar and the alkyl group, cycloalkyl group, and aryl group represented by Rn also preferably have, as a substituent, a fluorine atom or an iodine atom.

From the viewpoint of providing a repeating unit having high acid decomposability, in the leaving group protecting the polar group, when a non-aromatic ring is directly bonded to the polar group (or its residue), in the non-aromatic ring, a ring-member atom adjacent to a ring-member atom directly bonded to the polar group (or its residue) also preferably does not have, as a substituent, a halogen atom such as a fluorine atom.

Alternatively, the group that leaves by the action of an acid may be a 2-cyclopentenyl group having a substituent (such as an alkyl group) such as a 3-methyl-2-cyclopentenyl group, or a cyclohexyl group having a substituent (such as an alkyl group) such as a 1,1,4,4-tetramethylcyclohexyl group.

The repeating unit (a2) having an acid-decomposable group is preferably a repeating unit derived from a monomer represented by any one of the following formulas (4) to (6).

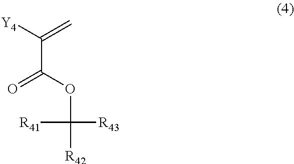

In the formula (4), Y₄ represents a hydrogen atom, a fluorine atom, or an alkyl group. R₄₁, R₄₂, and R₄₃ each independently represent an organic group. Two among R₄₁, R₄₂ and R₄₃ may be bonded together to form a ring.

In the formula (4), Y₄ represents a hydrogen atom, a fluorine atom, or an alkyl group.

The alkyl group represented by Y₄ may be linear or may be branched. The number of carbon atoms of the alkyl group is not particularly limited, but is preferably 1 to 10, and more preferably 1 to 3.

The alkyl group represented by Y₄ may have a substituent, and the substituent may be, for example, a halogen atom (such as a fluorine atom), a hydroxyl group, or a monovalent organic group.

Y₄ is preferably a hydrogen atom or a methyl group.

In the formula (4), R₄₁, R₄₂ and R₄₃ each independently represent an organic group. For R₄₁, R₄₂, and R₄₃, the organic group may be, for example, an alkyl group (linear or branched), a cycloalkyl group (monocyclic or polycyclic), an alkenyl group (linear or branched), an aryl group (monocyclic or polycyclic), or a heteroaryl group (monocyclic or polycyclic).

For R₄₁, R₄₂, and R₄₃, the alkyl group is preferably an alkyl group having 1 to 5 carbon atoms such as a methyl group, an ethyl group, an n-propyl group, an isopropyl group, an n-butyl group, an isobutyl group, or a t-butyl group.

For R₄₁, R₄₂ and R₄₃, the cycloalkyl group is preferably a monocyclic cycloalkyl group such as a cyclopentyl group or a cyclohexyl group, or a polycyclic cycloalkyl group such as a norbornyl group, a tetracyclodecanyl group, a tetracyclododecanyl group, or an adamantyl group.

For R₄₁, R₄₂ and R₄₃, the aryl group is preferably an aryl group having 6 to 10 carbon atoms, and may be, for example, a phenyl group or a naphthyl group.

For R₄₁, R₄₂, and R₄₃, the heteroaryl group is preferably a heteroaryl group having 5 to 10 carbon atoms, and may be, for example, a group in which a single hydrogen atom is removed from a heterocycle such as thiophene, furan, or thiazole.

For R₄₁, R₄₂, and R₄₃, the alkenyl group is preferably a vinyl group.

The ring formed by bonding together two among R₄₁, R₄₂ and R₄₃ is preferably a cycloalkyl group. The cycloalkyl group formed by bonding together two among R₁₁, R₁₂ and R₁₃ is preferably a monocyclic cycloalkyl group such as a cyclopentyl group or a cyclohexyl group, or a polycyclic cycloalkyl group such as a norbornyl group, a tetracyclodecanyl group, a tetracyclododecanyl group, or an adamantyl group, and more preferably a monocyclic cycloalkyl group having 5 to 6 carbon atoms.

In the cycloalkyl group formed by bonding together two among R₄₁, R₄₂, and R₄₃, one of the methylene groups constituting the ring may be replaced by a heteroatom such as an oxygen atom, a group including a heteroatom such as a carbonyl group, or a vinylidene group. In the cycloalkyl group, one or more ethylene groups constituting the cycloalkane ring may be replaced by vinylene groups.

For R₄₁, R₄₂, and R₄₃, the organic group may further have a substituent, and the substituent may be, for example, a halogen atom, a hydroxyl group, or a monovalent organic group. The monovalent organic group may be, for example, an alkyl group (having 1 to 4 carbon atoms), an alkoxy group (having 1 to 4 carbon atoms), an alkylcarbonyl group (having 2 to 5 carbon atoms), a halogenated alkyl group (having 1 to 4 carbon atoms) such as a trifluoromethyl group, a carboxyl group, or an alkoxycarbonyl group (having 2 to 6 carbon atoms). The substituent preferably has 8 or less carbon atoms.

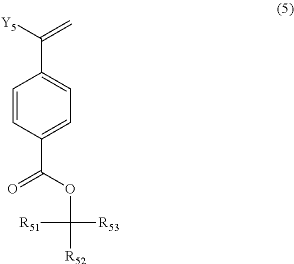

In the formula (5), Y₅ represents a hydrogen atom, a fluorine atom, or an alkyl group. R₅₁, R₅₂, and R₅₃ each independently represent an organic group. Two among R₅₁, R₅₂, and R₅₃ may be bonded together to form a ring.

In the formula (5), Y₅ represents a hydrogen atom, a fluorine atom, or an alkyl group.

The alkyl group represented by Y₅ may be, for example, the alkyl group represented by Y₄, and preferred examples thereof are also the same.

Y₅ is preferably a hydrogen atom or a methyl group.

R₅₁, R₅₂, and R₅₃ in the formula (5) have the same definitions as R₄₁, R₄₂, and R₄₃ in the formula (4), and preferred examples thereof are also the same.

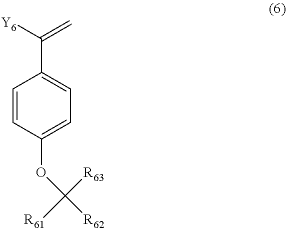

In the formula (6), Y₆ represents a hydrogen atom, a fluorine atom, or an alkyl group. R₆₁, R₆₂, and R₆₃ each independently represent an organic group. Two among R₆₁, R₆₂, and R₆₃ may be bonded together to form a ring.

In the formula (6), Y₆ represents a hydrogen atom, a fluorine atom, or an alkyl group.

The alkyl group represented by Y₆ may be, for example, the alkyl group represented by Y₄, and preferred examples thereof are also the same.

Y₆ is preferably a hydrogen atom or a methyl group.

R₆₁, R₆₂, and R₆₃ in the formula (6) have the same definitions as R₄₁, R₄₂, and R₄₃ in the formula (4), and preferred examples thereof are also the same.

The repeating unit having an acid-decomposable group is also preferably a repeating unit represented by a formula (A).

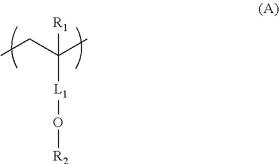

L₁ represents a divalent linking group that may have a fluorine atom or an iodine atom; R₁ represents a hydrogen atom, a fluorine atom, an iodine atom, or an alkyl group that may have a fluorine atom or an iodine atom, or an aryl group that may have a fluorine atom or an iodine atom; R₂ represents a leaving group that leaves by the action of an acid and that may have a fluorine atom or an iodine atom. Note that at least one of L₁, R₁, or R₂ has a fluorine atom or an iodine atom.

Examples of the divalent linking group that is represented by L₁ and may have a fluorine atom or an iodine atom include —CO—, —O—, —S—, —SO—, —SO₂—, hydrocarbon groups that may have a fluorine atom or an iodine atom (for example, alkylene groups, cycloalkylene groups, alkenylene groups, and arylene groups), and linking groups provided by linking together a plurality of the foregoing. In particular, L₁ is preferably —CO—, an arylene group, or an-arylene group-alkylene group having a fluorine atom or an iodine atom-, and more preferably —CO— or an -arylene group-alkylene group having a fluorine atom or an iodine atom-.

The arylene group is preferably a phenylene group.

The alkylene group may be linear or may be branched. The number of carbon atoms of the alkylene group is not particularly limited, but is preferably 1 to 10, and more preferably 1 to 3.

In the alkylene group having a fluorine atom or an iodine atom, the total number of fluorine atoms and iodine atoms is not particularly limited, but is preferably 2 or more, more preferably 2 to 10, and still more preferably 3 to 6.

The alkyl group represented by R₁ may be linear or may be branched. The number of carbon atoms of the alkyl group is not particularly limited, but is preferably 1 to 10, and more preferably 1 to 3.

In the alkyl group represented by R₁ and having a fluorine atom or an iodine atom, the total number of fluorine atoms and iodine atoms is not particularly limited, but is preferably 1 or more, more preferably 1 to 5, and still more preferably 1 to 3.

The alkyl group represented by R₁ may include a heteroatom other than halogen atoms, such as an oxygen atom.

Examples of the leaving group that is represented by R₂ and may have a fluorine atom or an iodine atom include leaving groups that are represented by the above-described formulas (Y1) to (Y4) and that have a fluorine atom or an iodine atom.

The repeating unit having an acid-decomposable group is also preferably a repeating unit represented by a formula (AI).

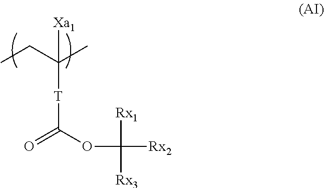

In the formula (AI), Xa₁ represents a hydrogen atom or an alkyl group that may have a substituent. T represents a single bond or a divalent linking group. Rx₁ to Rx₃ each independently represent an alkyl group (linear or branched), a cycloalkyl group (monocyclic or polycyclic), an alkenyl group (linear or branched), or an aryl (monocyclic or polycyclic) group. Note that, when Rx₁ to Rx₃ are all alkyl groups (linear or branched), at least two among Rx₁ to Rx₃ are preferably methyl groups.

Two among Rx₁ to Rx₃ may be bonded together to form a monocycle or polycycle (such as a monocyclic or polycyclic cycloalkyl group).

The alkyl group that is represented by Xa₁ and may have a substituent may be, for example, a methyl group or a group represented by —CH₂—R₁₁. R₁₁ represents a halogen atom (such as a fluorine atom), a hydroxy group, or a monovalent organic group. The monovalent organic group represented by R₁₁ is, for example, an alkyl group that has 5 or less carbon atoms and that may be substituted with a halogen atom, an acyl group that has 5 or less carbon atoms and that may be substituted with a halogen atom, or an alkoxy group that has 5 or less carbon atoms and that may be substituted with a halogen atom, and is preferably an alkyl group having 3 or less carbon atoms, and more preferably a methyl group. Xa₁ is preferably a hydrogen atom, a methyl group, a trifluoromethyl group, or a hydroxymethyl group.

For T, the divalent linking group may be an alkylene group, an aromatic ring group, a —COO-Rt- group, or an —O-Rt- group. In the formulas, Rt represent an alkylene group or a cycloalkylene group.

T is preferably a single bond or a —COO-Rt- group. When T represents a —COO-Rt- group, Rt is preferably an alkylene group having 1 to 5 carbon atoms, and more preferably a —CH₂— group, a —(CH₂)₂— group, or a —(CH₂)₃— group.

For Rx₁ to Rx₃, the alkyl group is preferably an alkyl group having 1 to 4 carbon atoms such as a methyl group, an ethyl group, an n-propyl group, an isopropyl group, an n-butyl group, an isobutyl group, or a t-butyl group.

For Rx₁ to Rx₃, the cycloalkyl group is preferably a monocyclic cycloalkyl group such as a cyclopentyl group or a cyclohexyl group, or a polycyclic cycloalkyl group such as a norbornyl group, a tetracyclodecanyl group, a tetracyclododecanyl group, or an adamantyl group.

For Rx₁ to Rx₃, the aryl group is preferably an aryl group having 6 to 10 carbon atoms and may be, for example, a phenyl group, a naphthyl group, or an anthryl group.

For Rx₁ to Rx₃, the alkenyl group is preferably a vinyl group.

The cycloalkyl group formed by bonding together two among Rx₁ to Rx₃ is preferably a monocyclic cycloalkyl group such as a cyclopentyl group or a cyclohexyl group. Also preferred are polycyclic cycloalkyl groups such as a norbornyl group, a tetracyclodecanyl group, a tetracyclododecanyl group, and an adamantyl group. In particular, preferred is a monocyclic cycloalkyl group having 5 to 6 carbon atoms.

In the cycloalkyl group formed by bonding together two among Rx₁ to Rx₃, for example, one of methylene groups constituting the ring may be replaced by a heteroatom such as an oxygen atom, a group including a heteroatom such as a carbonyl group, or a vinylidene group. In the cycloalkyl group, one or more of the ethylene groups constituting the cycloalkane ring may be replaced by vinylene groups.

The repeating unit represented by the formula (AI) preferably has a form in which, for example, Rx₁ is a methyl group or an ethyl group, and Rx₂ and Rx₃ are bonded together to form the above-described cycloalkyl group.

When the above-described groups each have a substituent, the substituent may be, for example, an alkyl group (having 1 to 4 carbon atoms), a halogen atom, a hydroxyl group, an alkoxy group (having 1 to 4 carbon atoms), a carboxyl group, or an alkoxycarbonyl group (having 2 to 6 carbon atoms). The substituent preferably has 8 or less carbon atoms.

The repeating unit represented by the formula (AI) is preferably an acid-decomposable (meth)acrylic acid tertiary alkyl ester-based repeating unit (repeating unit in which Xa₁ represents a hydrogen atom or a methyl group and T represents a single bond).

The following are non-limiting specific examples of the repeating unit having an acid-decomposable group. Note that, in the formulas, Xa₁ represent H, CH₃, CF₃, or CH₂OH, and Rxa and Rxb each independently represent a linear or branched alkyl group having 1 to 5 carbon atoms.

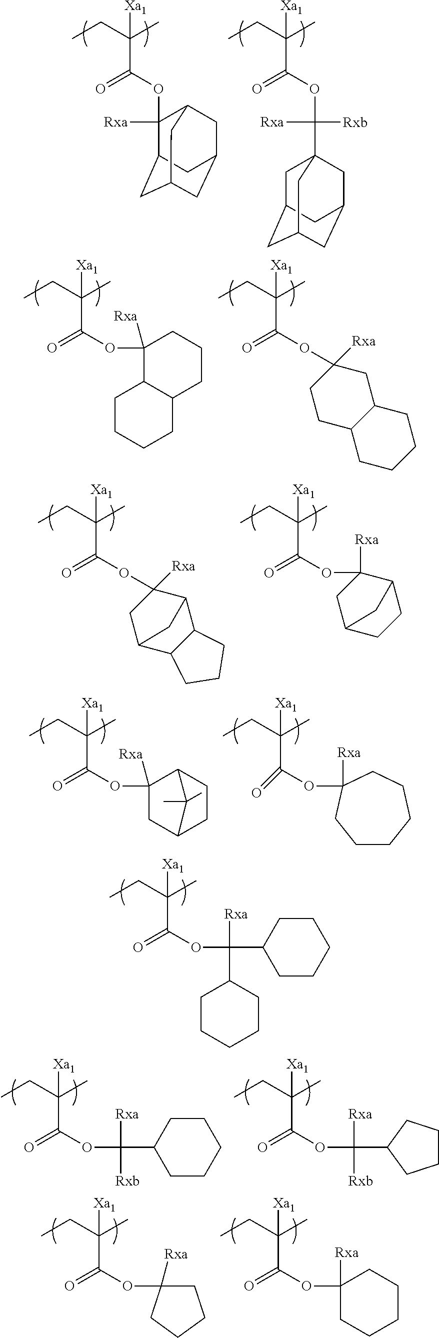

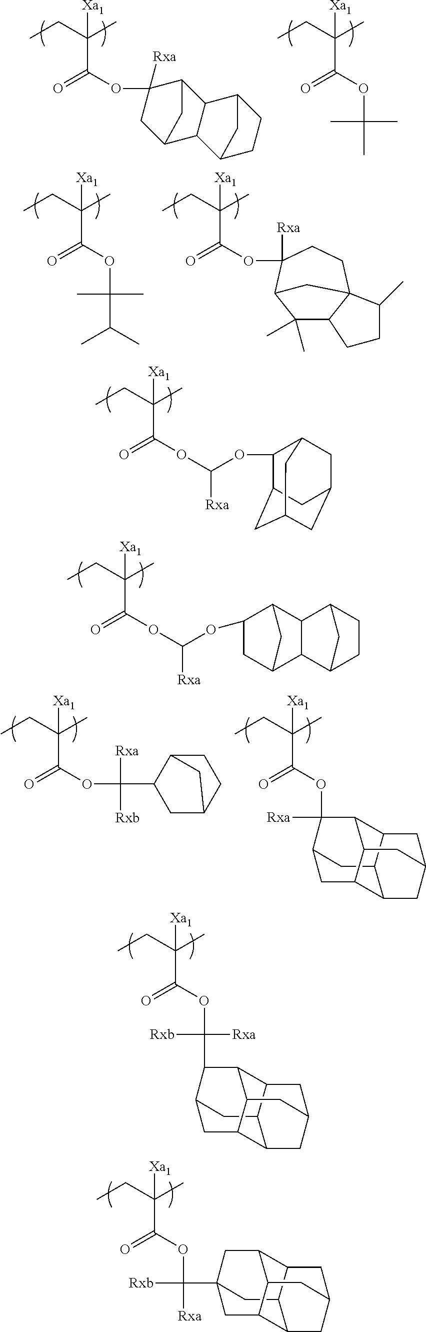

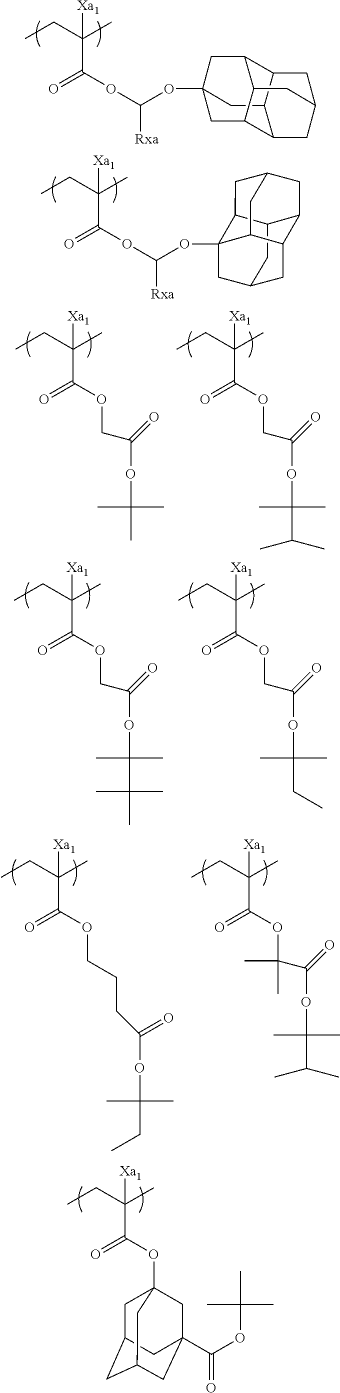

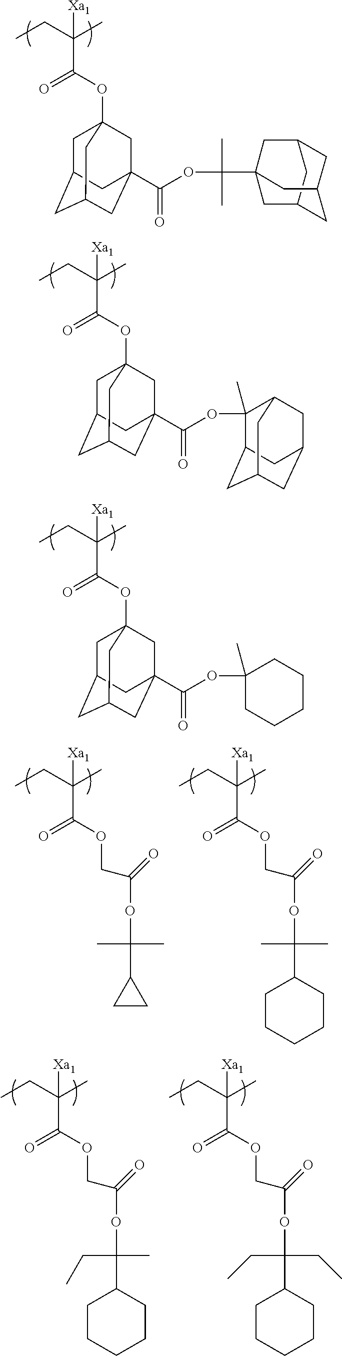

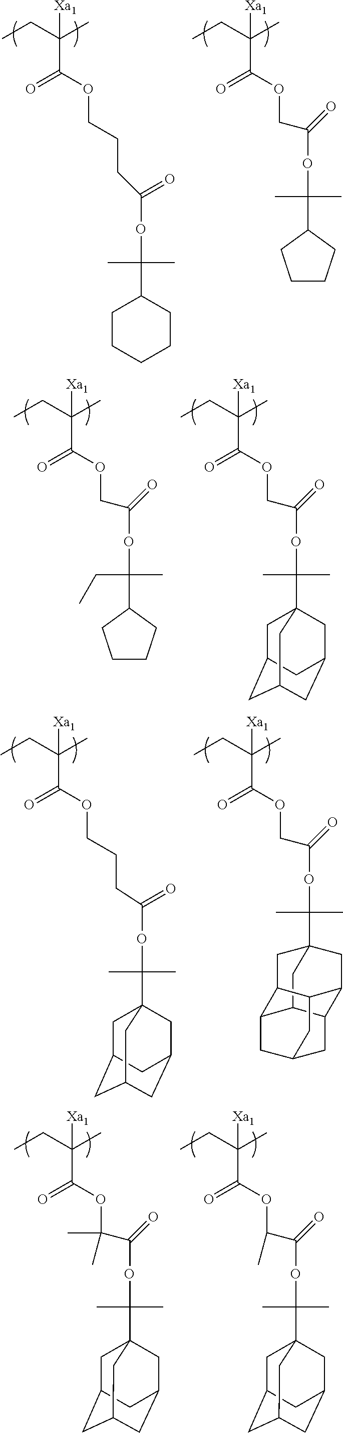

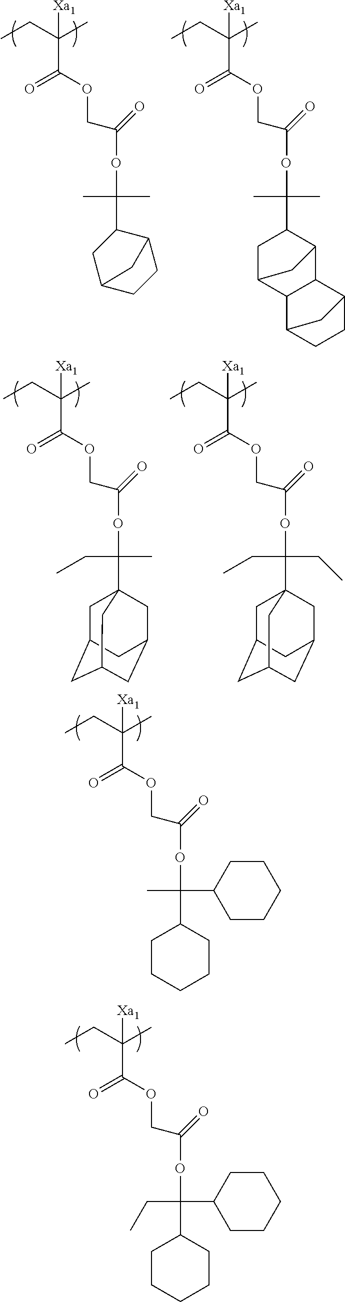

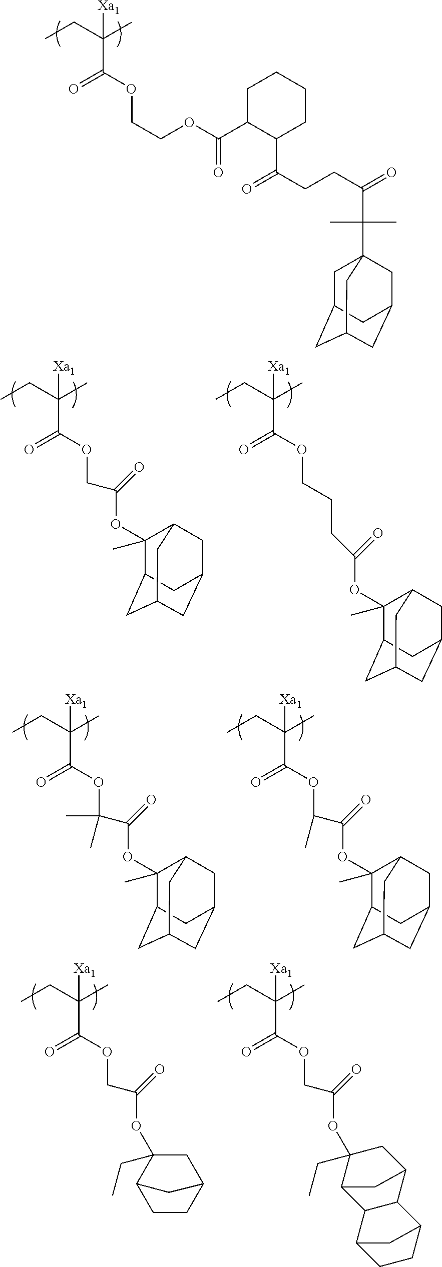

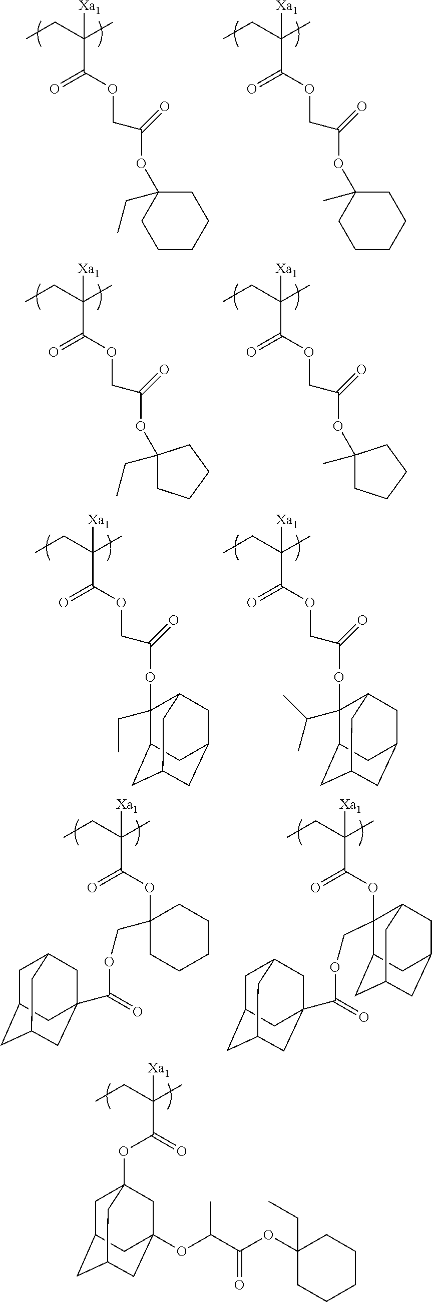

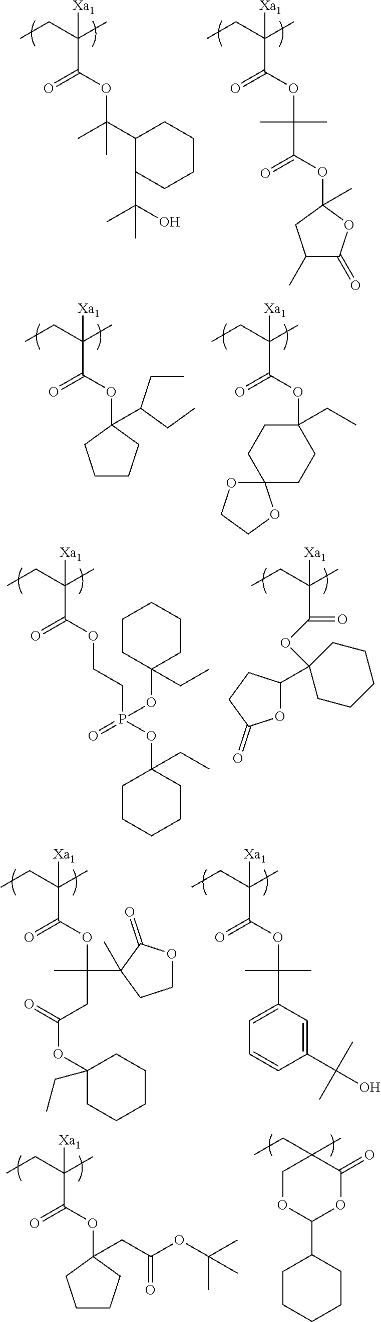

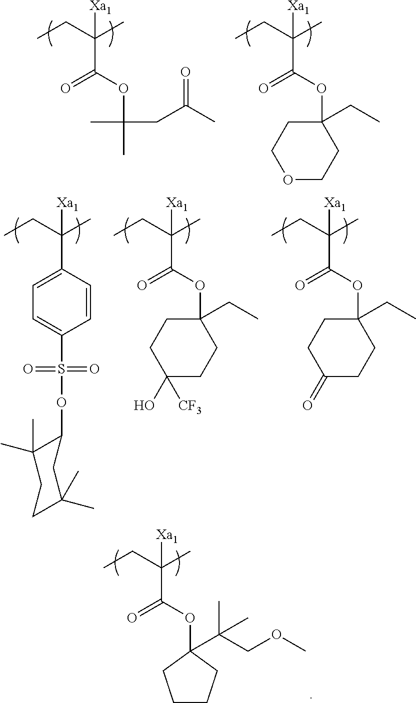

The resin (A) may have, as a repeating unit having an acid-decomposable group, a repeating unit having an acid-decomposable group including an unsaturated bond.

The repeating unit having an acid-decomposable group including an unsaturated bond is preferably a repeating unit represented by a formula (B).

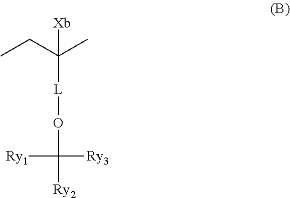

In the formula (B), Xb represents a hydrogen atom, a halogen atom, or an alkyl group that may have a substituent. L represents a single bond or a divalent linking group that may have a substituent. Ry₁ to Ry₃ each independently represent a linear or branched alkyl group, a monocyclic or polycyclic cycloalkyl group, an alkenyl group, an alkynyl group, or a monocyclic or polycyclic aryl group. Note that at least one of Ry₁ to Ry₃ represents an alkenyl group, an alkynyl group, a monocyclic or polycyclic cycloalkenyl group, or a monocyclic or polycyclic aryl group.

Two among Ry₁ to Ry₃ may be bonded together to form a monocycle or polycycle (such as a monocyclic or polycyclic cycloalkyl group or cycloalkenyl group).

For Xb, the alkyl group that may have a substituent may be, for example, a methyl group or a group represented by —CH₂—R₁₁. R₁₁ represents a halogen atom (such as a fluorine atom), a hydroxy group, or a monovalent organic group, may be, for example, an alkyl group that has 5 or less carbon atoms and that may be substituted with a halogen atom, an acyl group that has 5 or less carbon atoms and that may be substituted with a halogen atom, or an alkoxy group that has 5 or less carbon atoms and that may be substituted with a halogen atom, is preferably an alkyl group having 3 or less carbon atoms, and more preferably a methyl group. Xb is preferably a hydrogen atom, a fluorine atom, a methyl group, a trifluoromethyl group, or a hydroxymethyl group.

For L, the divalent linking group may be an -Rt- group, a —CO— group, a —COO-Rt- group, a —COO-Rt-CO— group, an -Rt-CO— group, or an —O-Rt- group. In the formulas, Rt represent an alkylene group, a cycloalkylene group, or an aromatic ring group, and is preferably an aromatic ring group.

L is preferably an -Rt- group, a —CO— group, a —COO-Rt-CO— group, or an -Rt-CO— group. Rt may have a substituent such as a halogen atom, a hydroxy group, or an alkoxy group.

For Ry₁ to Ry₃, the alkyl group is preferably an alkyl group having 1 to 4 carbon atoms such as a methyl group, an ethyl group, an n-propyl group, an isopropyl group, an n-butyl group, an isobutyl group, or a t-butyl group.

For Ry₁ to Ry₃, the cycloalkyl group is preferably a monocyclic cycloalkyl group such as a cyclopentyl group or a cyclohexyl group, or a polycyclic cycloalkyl group such as a norbornyl group, a tetracyclodecanyl group, a tetracyclododecanyl group, or an adamantyl group.

For Ry₁ to Ry₃, the aryl group is preferably an aryl group having 6 to 10 carbon atoms, and may be, for example, a phenyl group, a naphthyl group, or an anthryl group.

For Ry₁ to Ry₃, the alkenyl group is preferably a vinyl group.

For Ry₁ to Ry₃, the alkynyl group is preferably an ethynyl group.

For Ry₁ to Ry₃, the cycloalkenyl group is preferably a structure in which a monocyclic cycloalkyl group such as a cyclopentyl group or a cyclohexyl group includes partially a double bond.

The cycloalkyl group formed by bonding together two among Ry₁ to Ry₃ is preferably a monocyclic cycloalkyl group such as a cyclopentyl group or a cyclohexyl group, or a polycyclic cycloalkyl group such as a norbornyl group, a tetracyclodecanyl group, a tetracyclododecanyl group, or an adamantyl group. In particular, more preferred is a monocyclic cycloalkyl group having 5 to 6 carbon atoms.

In the cycloalkyl group or the cycloalkenyl group formed by bonding together two among Ry₁ to Ry₃, for example, one of methylene groups constituting the ring may be replaced by a heteroatom such as an oxygen atom, a group including a heteroatom such as a carbonyl group, a —SO₂— group, or a —SO₃— group, a vinylidene group, or a combination of the foregoing. In the cycloalkyl group or the cycloalkenyl group, one or more ethylene groups constituting the cycloalkane ring or the cycloalkene ring may be replaced by vinylene groups.

The repeating unit represented by the formula (B) preferably has a form in which, for example, Ry₁ is a methyl group, an ethyl group, a vinyl group, an allyl group, or an aryl group, and Ry₂ and Ry₃ are bonded together to form the above-described cycloalkyl group or cycloalkenyl group.

When the above-described groups each have a substituent, the substituent may be, for example, an alkyl group (having 1 to 4 carbon atoms), a halogen atom, a hydroxy group, an alkoxy group (having 1 to 4 carbon atoms), a carboxyl group, or an alkoxycarbonyl group (having 2 to 6 carbon atoms). The substituent preferably has 8 or less carbon atoms.

The repeating unit represented by the formula (B) is preferably an acid-decomposable (meth)acrylic acid tertiary ester-based repeating unit (a repeating unit in which Xb represents a hydrogen atom or a methyl group, and L represents a —CO— group), an acid-decomposable hydroxystyrene tertiary alkyl ether-based repeating unit (a repeating unit in which Xb represents a hydrogen atom or a methyl group, and L represents a phenyl group), or an acid-decomposable styrenecarboxylic acid tertiary ester-based repeating unit (a repeating unit in which Xb represents a hydrogen atom or a methyl group, and L represents an -Rt-CO— group (where Rt is an aromatic group)).

The content of the repeating unit having an acid-decomposable group including an unsaturated bond relative to all the repeating units in the resin (A) is preferably 15 mol % or more, more preferably 20 mol % or more, and still more preferably 30 mol % or more. The upper limit value relative to all the repeating units in the resin (A) is preferably 80 mol % or less, more preferably 70 mol % or less, and still more preferably 60 mol % or less.

The following are non-limiting specific examples of the repeating unit having an acid-decomposable group including an unsaturated bond. Note that, in the formulas, Xb and L₁ represent any one of the above-described substituents and linking groups; Ar represent an aromatic group; R represent a substituent such as a hydrogen atom, an alkyl group, a cycloalkyl group, an aryl group, an aralkyl group, an alkenyl group, a hydroxyl group, an alkoxy group, an acyloxy group, a cyano group, a nitro group, an amino group, a halogen atom, an ester group (—OCOR″′ or —COOR″′ where R″′ is an alkyl group or a fluorinated alkyl group having 1 to 20 carbon atoms), or a carboxyl group; R′ represent a linear or branched alkyl group, a monocyclic or polycyclic cycloalkyl group, an alkenyl group, an alkynyl group, or a monocyclic or polycyclic aryl group; Q represent a heteroatom such as an oxygen atom, a group including a heteroatom such as a carbonyl group, a —SO₂— group, or a —SO₃— group, a vinylidene group, or a combination of the foregoing; n, m, and I are an integer of 0 or more.

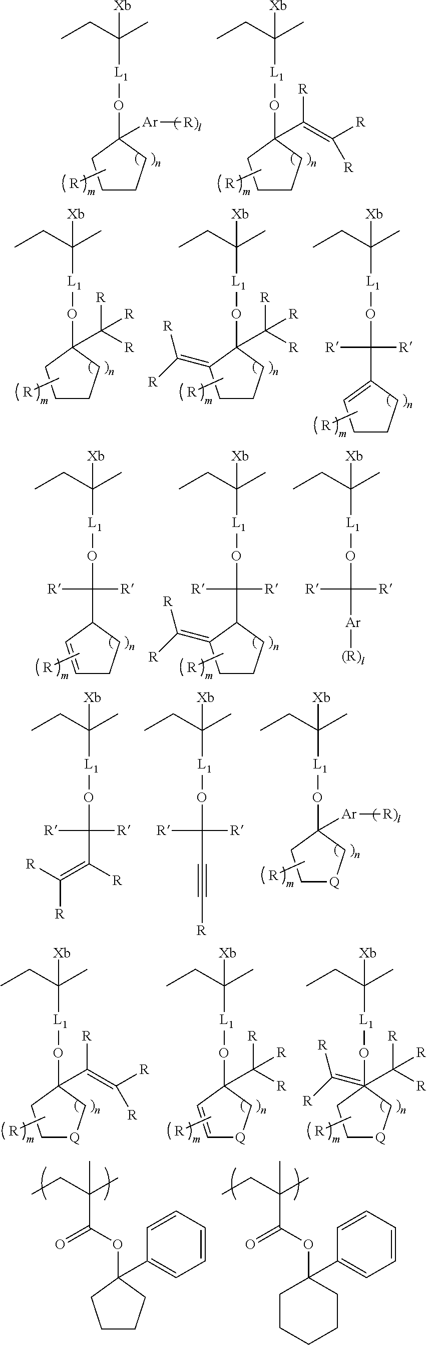

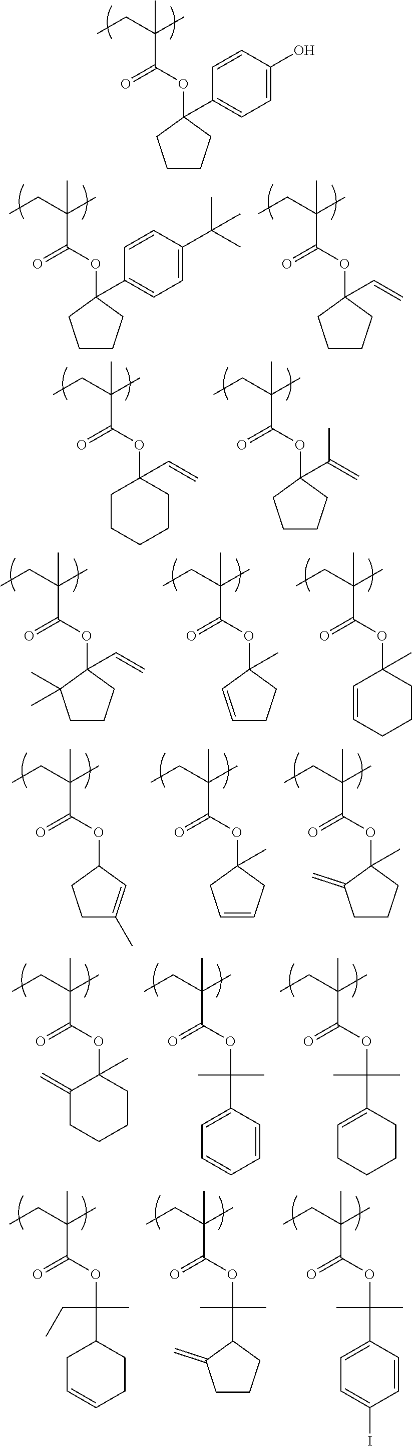

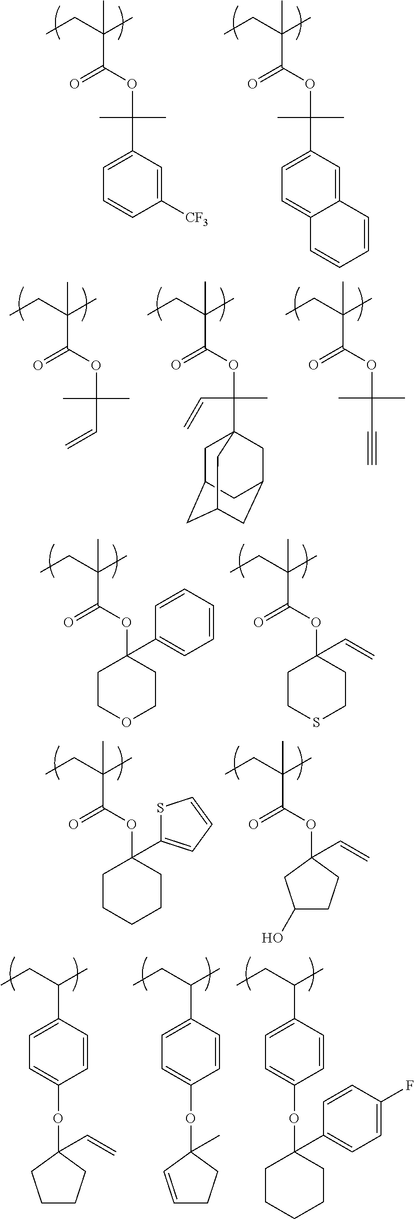

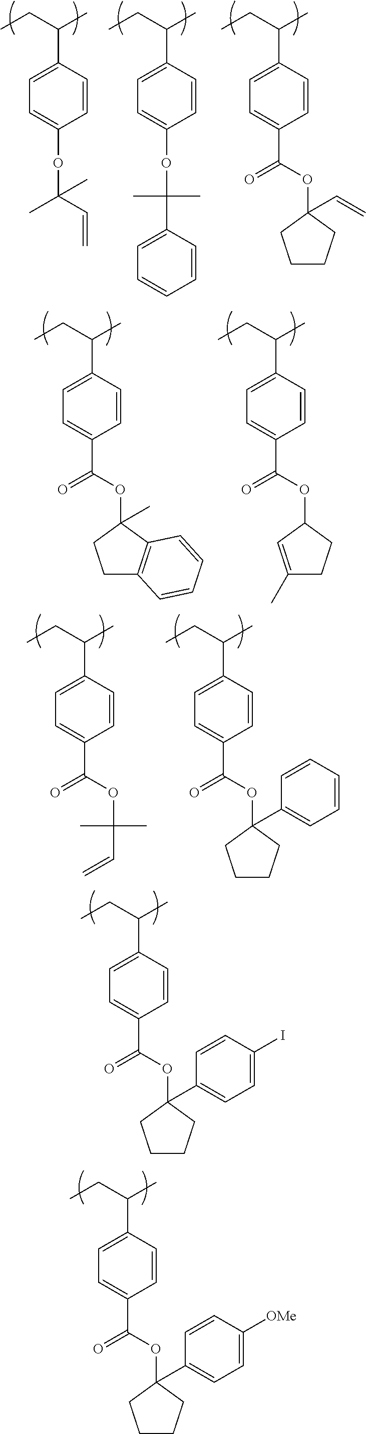

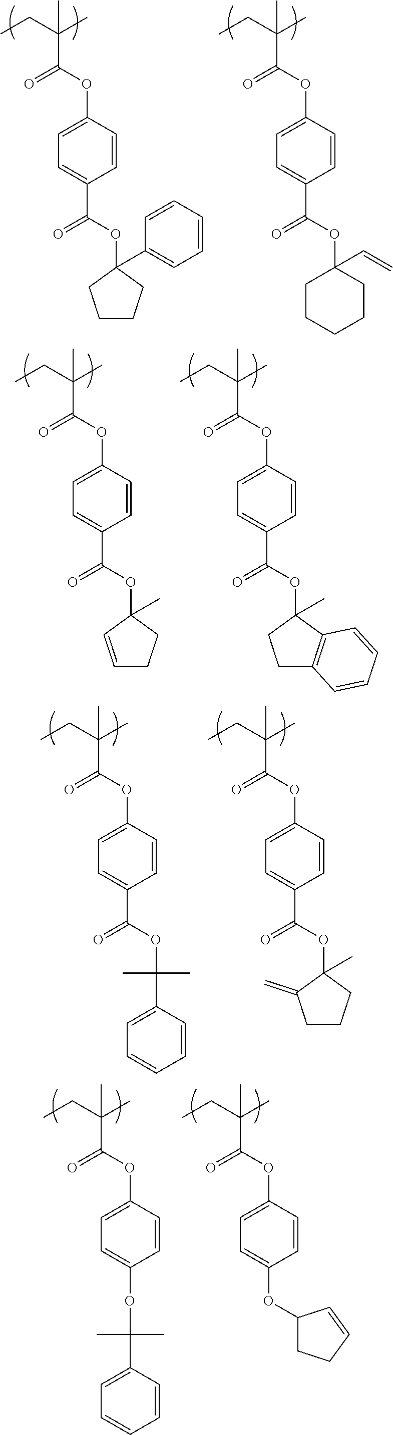

The content of the repeating unit (a2) having an acid-decomposable group relative to all the repeating units in the resin (A) is preferably 15 mol % or more, more preferably 20 mol % or more, and still more preferably 30 mol % or more. The upper limit value relative to all the repeating units in the resin (A) is preferably 90 mol % or less, more preferably 80 mol % or less, still more preferably 70 mol % or less, and particularly preferably 60 mol % or less. Repeating unit other than repeating units (a1) and (a2)

The resin (A) may include at least one repeating unit species selected from the group consisting of the following Group A and/or at least one repeating unit species selected from the group consisting of the following Group B.

Group A: a group consisting of the following repeating units (20) to (25)
(20) a repeating unit (described later) having an acid group
(21) a repeating unit (described later) not having an acid-decomposable group or an acid group, but having a fluorine atom, a bromine atom, or an iodine atom
(22) a repeating unit (described later) having a lactone group, a sultone group, or a carbonate group
(23) a repeating unit (described later) having a photoacid generation group
(24) a repeating unit (described later) represented by a formula (V-1) or a formula (V-2) below
(25) a repeating unit for lowering the mobility of the main chain

Note that repeating units represented by a formula (A) to a formula (E) described later correspond to the repeating unit (25) for lowering the mobility of the main chain.

Group B: a group consisting of the following repeating units (30) to (32)
(30) a repeating unit (described later) having at least one group species selected from the group consisting of a lactone group, a sultone group, a carbonate group, a hydroxy group, a cyano group, and an alkali-soluble group
(31) a repeating unit (described later) having an alicyclic hydrocarbon structure and not exhibiting acid decomposability
(32) a repeating unit (described later) not having a hydroxy group or a cyano group and represented by a formula (III)

The resin (A) preferably has an acid group and preferably includes a repeating unit having an acid group as described later. Note that the definition of the acid group will be described in a later part together with preferred examples of the repeating unit having an acid group. When the resin (A) has an acid group, a better interaction between the resin (A) and the acid generated from the photoacid generator is provided. This results in further suppression of diffusion of the acid to form a pattern having a more square profile.

The resin (A) may have at least one repeating unit species selected from the group consisting of Group A above. When the composition of the present invention is used as an actinic ray-sensitive or radiation-sensitive resin composition for EUV exposure, the resin (A) preferably has at least one repeating unit species selected from the group consisting of Group A above.

The resin (A) may include at least one of a fluorine atom or an iodine atom. When the composition of the present invention is used as an actinic ray-sensitive or radiation-sensitive resin composition for EUV exposure, the resin (A) preferably includes at least one of a fluorine atom or an iodine atom. When the resin (A) includes both of a fluorine atom and an iodine atom, the resin (A) may have a repeating unit including both of a fluorine atom and an iodine atom, or the resin (A) may include two species that are a repeating unit having a fluorine atom and a repeating unit including an iodine atom.

The resin (A) may have a repeating unit having an aromatic group. When the resist composition is used as an actinic ray-sensitive or radiation-sensitive resin composition for EUV exposure, the resin (A) also preferably has a repeating unit having an aromatic group.

The resin (A) may also have at least one repeating unit species selected from the group consisting of Group B above. When the composition of the present invention is used as an actinic ray-sensitive or radiation-sensitive resin composition for ArF, the resin (A) preferably has at least one repeating unit species selected from the group consisting of Group B above.

Note that, when the composition of the present invention is used as an actinic ray-sensitive or radiation-sensitive resin composition for ArF, the resin (A) preferably does not include a fluorine atom or a silicon atom.

### Repeating Unit Having Acid Group

The resin (A) may have a repeating unit having an acid group.

The acid group is preferably an acid group having a pKa of 13 or less. The acid group preferably has an acid dissociation constant of 13 or less, more preferably 3 to 13, and still more preferably 5 to 10.

When the resin (A) has an acid group having a pKa of 13 or less, the content of the acid group in the resin (A) is not particularly limited, but is often 0.2 to 6.0 mmol/g. In particular, preferred is 0.8 to 6.0 mmol/g, more preferred is 1.2 to 5.0 mmol/g, and still more preferred is 1.6 to 4.0 mmol/g. When the content of the acid group is within such a range, development suitably proceeds to form a pattern having a good profile at high resolution.

The acid group is preferably, for example, a carboxyl group, a phenolic hydroxyl group, a fluoroalcohol group (preferably a hexafluoroisopropanol group), a sulfonic acid group, a sulfonamide group, or an isopropanol group.

In the hexafluoroisopropanol group, one or more (preferably one to two) of the fluorine atoms may be substituted with groups other than fluorine atoms (such as alkoxycarbonyl groups). The acid group is also preferably —C(CF₃)(OH)—CF₂— formed in this manner. Alternatively, one or more of the fluorine atoms may be substituted with groups other than fluorine atoms, to form a ring including —C(CF₃)(OH)—CF₂—.

The repeating unit having an acid group is preferably a repeating unit different from the above-described repeating unit having a structure in which a polar group is protected with a group that leaves by the action of an acid and repeating units described later and having a lactone group, a sultone group, or a carbonate group.

The repeating unit having an acid group may have a fluorine atom or an iodine atom.

Examples of the repeating unit having an acid group include the following repeating units.

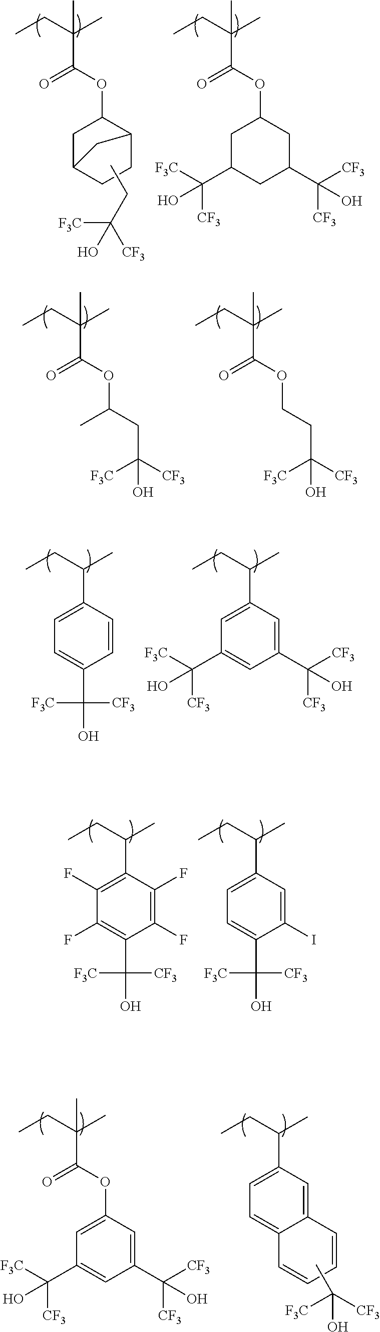

The repeating unit having an acid group is preferably a repeating unit represented by the following formula (1).

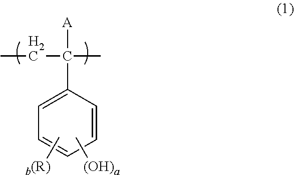

In the formula (1), A represents a hydrogen atom, an alkyl group, a cycloalkyl group, a halogen atom, or a cyano group. R represents a halogen atom, an alkyl group, a cycloalkyl group, an aryl group, an alkenyl group, an aralkyl group, an alkoxy group, an alkylcarbonyloxy group, an alkylsulfonyloxy group, an alkyloxycarbonyl group, or an aryloxycarbonyl group; and when a plurality of R's are present, they may be the same or different. When there are a plurality of R's, they may together form a ring. R is preferably a hydrogen atom. a represents an integer of 1 to 3. b represents an integer of 0 to (5-a).

The following are examples of the repeating unit having an acid group. In the formulas, a represent an integer of 1 to 3.

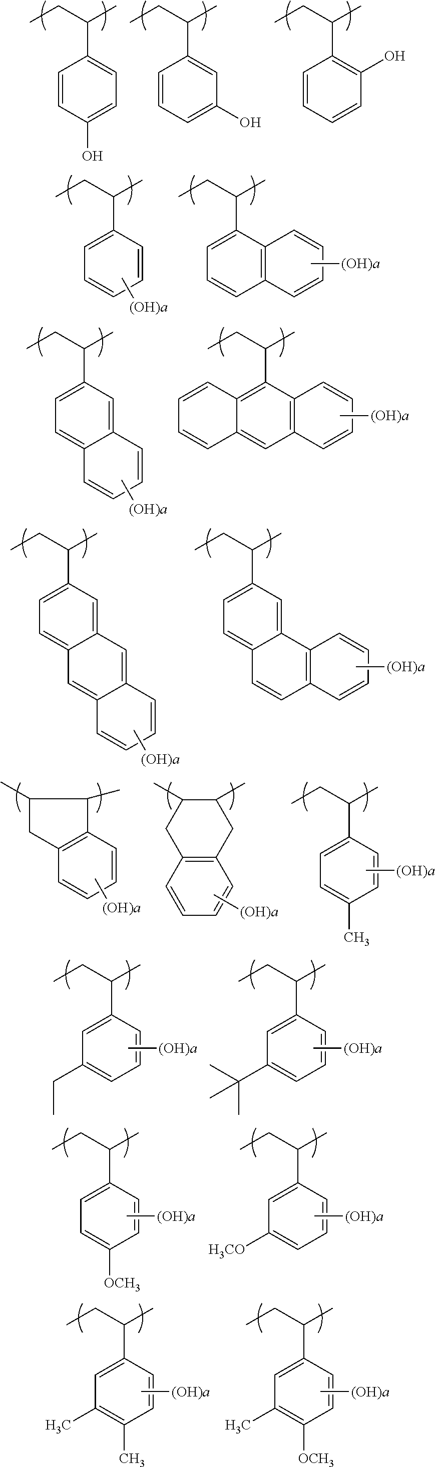

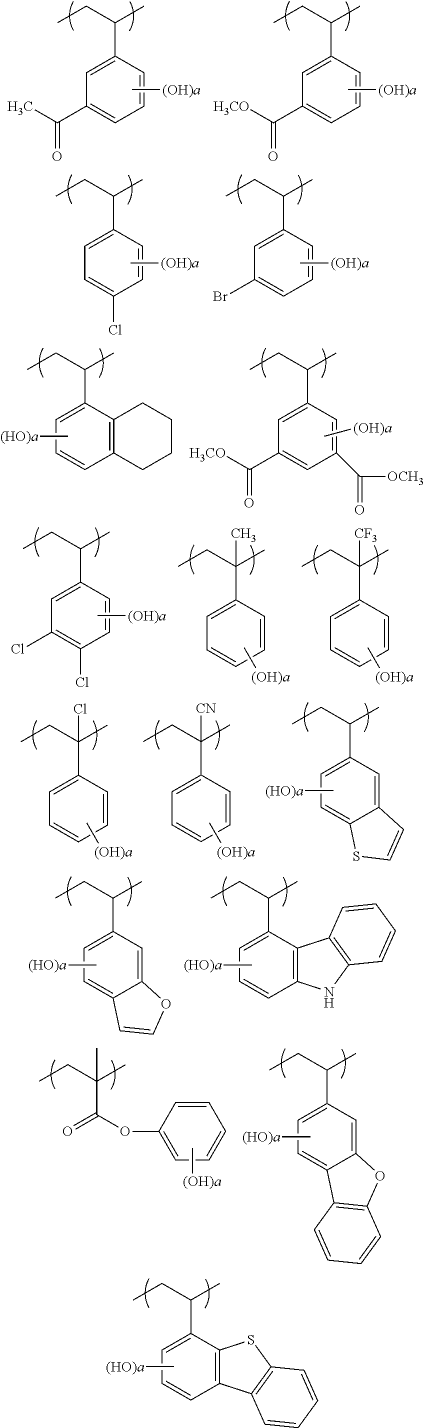

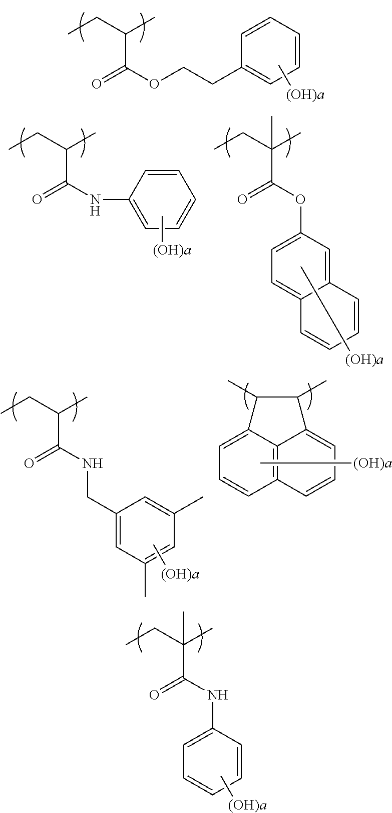

Note that, of the above-described repeating units, preferred are the following specific repeating units. In formulas, R represent a hydrogen atom or a methyl group, and a represent an integer of 1 to 3.

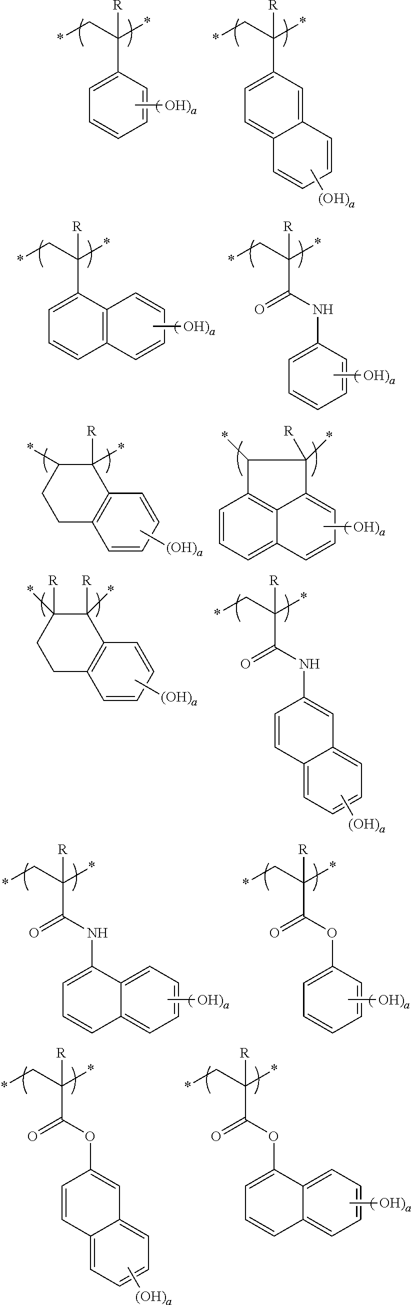

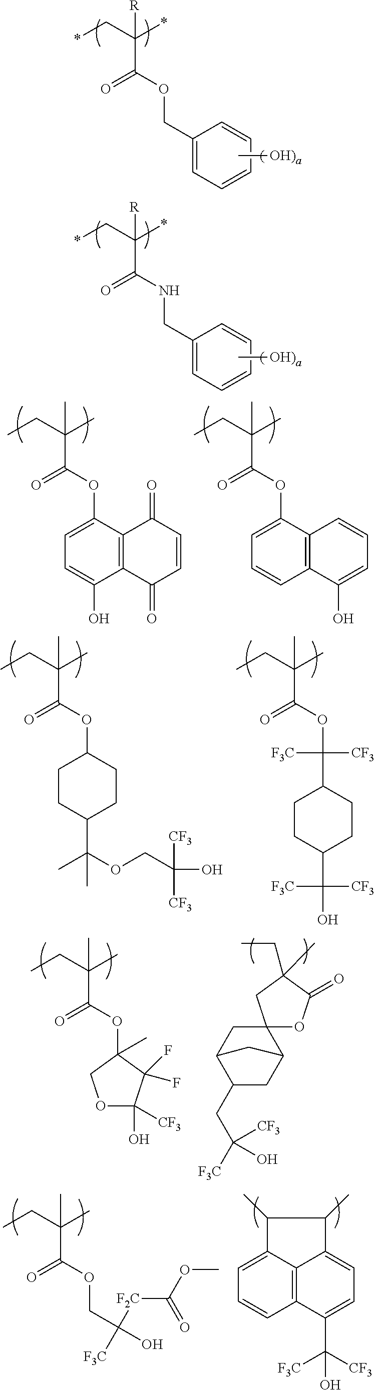

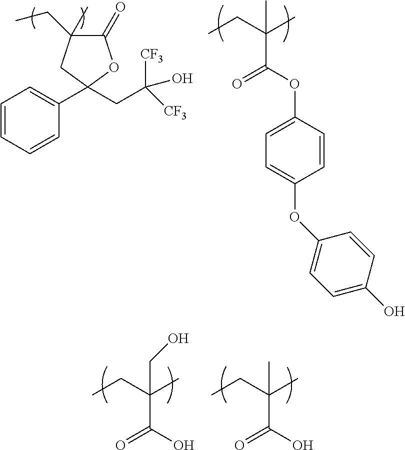

The content of the repeating unit having an acid group relative to all the repeating units in the resin (A) is preferably 10 mol % or more, and more preferably 15 mol % or more. The upper limit value relative to all the repeating units in the resin (A) is preferably 70 mol % or less, more preferably 65 mol % or less, and still more preferably 60 mol % or less.

### Repeating Unit not Having Acid-Decomposable Group or Acid Group, but Having Fluorine Atom, Bromine Atom, or Iodine Atom

The resin (A) may have, in addition to the above-described <repeating unit having an acid-decomposable group> and <repeating unit having an acid group>, a repeating unit not having an acid-decomposable group or an acid group, but having a fluorine atom, a bromine atom, or an iodine atom (hereafter, also referred to as unit X). This <repeating unit not having an acid-decomposable group or an acid group, but having a fluorine atom, a bromine atom, or an iodine atom> is preferably different from other repeating unit species belonging to Group A such as a<repeating unit having a lactone group, a sultone group, or a carbonate group> and a <repeating unit having a photoacid generation group> described later.

The unit X is preferably a repeating unit represented by a formula (C).

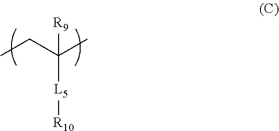

L₅ represents a single bond or an ester group. R₉ represents a hydrogen atom or an alkyl group that may have a fluorine atom or an iodine atom. R₁₀ represents a hydrogen atom, an alkyl group that may have a fluorine atom or an iodine atom, a cycloalkyl group that may have a fluorine atom or an iodine atom, an aryl group that may have a fluorine atom or an iodine atom, or a group that is a combination of the foregoing.

The following are examples of the repeating unit having a fluorine atom or an iodine atom.

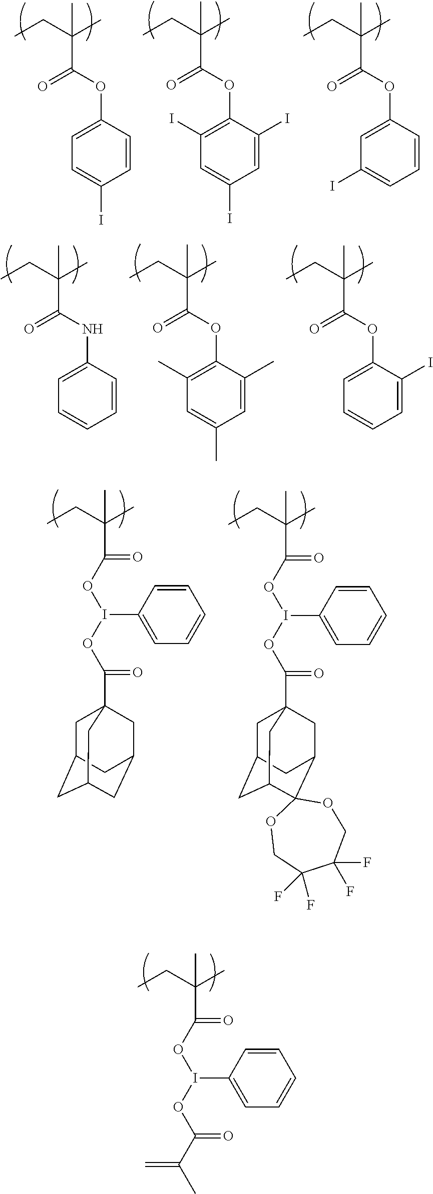

The unit X content relative to all the repeating units in the resin (A) is preferably 0 mol % or more, more preferably 5 mol % or more, and still more preferably 10 mol % or more. The upper limit value relative to all the repeating units in the resin (A) is preferably 50 mol % or less, more preferably 45 mol % or less, and still more preferably 40 mol % or less.

Of the repeating units of the resin (A), the total content of the repeating unit including at least one of a fluorine atom, a bromine atom, or an iodine atom relative to all the repeating units of the resin (A) is preferably 10 mol % or more, more preferably 20 mol % or more, still more preferably 30 mol % or more, and particularly preferably 40 mol % or more. The upper limit value is not particularly limited, but is, for example, relative to all the repeating units of the resin (A), 100 mol % or less.

Note that examples of the repeating unit including at least one of a fluorine atom, a bromine atom, or an iodine atom include a repeating unit having a fluorine atom, a bromine atom, or an iodine atom and having an acid-decomposable group, a repeating unit having a fluorine atom, a bromine atom, or an iodine atom and having an acid group, and a repeating unit having a fluorine atom, a bromine atom, or an iodine atom.

### Repeating Unit Having Lactone Group, Sultone Group, or Carbonate Group

The resin (A) may have a repeating unit having at least one species selected from the group consisting of a lactone group, a sultone group, and a carbonate group (hereafter, also referred to as “unit Y”).

The unit Y also preferably does not have acid groups such as a hydroxy group and a hexafluoropropanol group.

The lactone group or the sultone group has a lactone structure or a sultone structure. The lactone structure or the sultone structure is preferably a 5- to 7-membered lactone structure or a 5- to 7-membered sultone structure. In particular, more preferred is a 5- to 7-membered lactone structure to which another ring structure is fused so as to form a bicyclo structure or a spiro structure, or a 5- to 7-membered sultone structure to which another ring structure is fused so as to form a bicyclo structure or a spiro structure.

The resin (A) preferably has a repeating unit having a lactone group or a sultone group provided by withdrawing, from ring-member atoms of the lactone structure represented by any one of formulas (LC1-1) to (LC1-21) below or the sultone structure represented by any one of formulas (SL1-1) to (SL1-3) below, one or more hydrogen atoms, and a lactone group or a sultone group may be directly bonded to the main chain. For example, ring-member atoms of a lactone group or a sultone group may constitute the main chain of the resin (A).

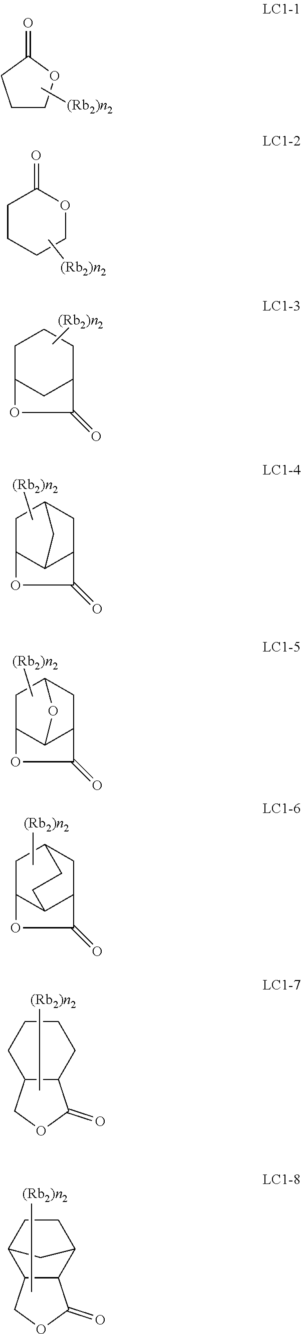

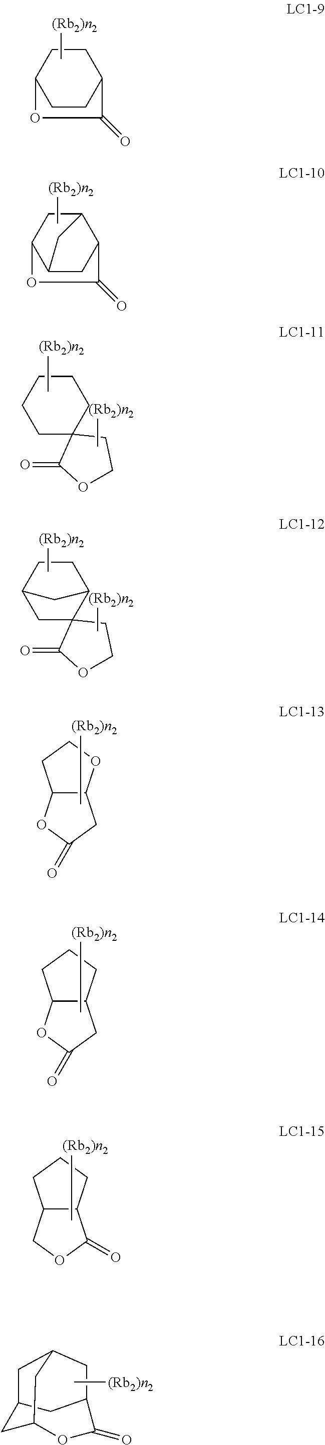

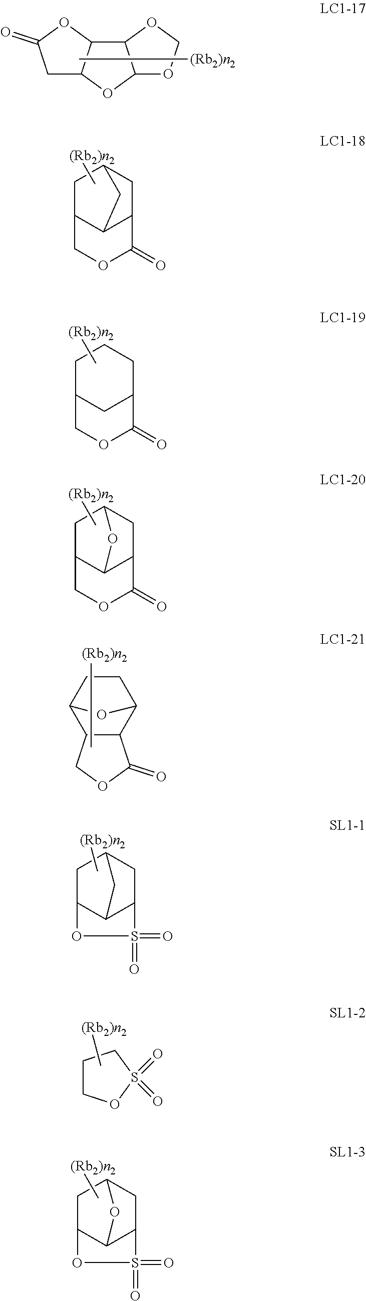

The above-described lactone structures or sultone structures may have a substituent (Rb₂). The substituent (Rb₂) is preferably an alkyl group having 1 to 8 carbon atoms, a cycloalkyl group having 4 to 7 carbon atoms, an alkoxy group having 1 to 8 carbon atoms, an alkoxycarbonyl group having 1 to 8 carbon atoms, a carboxyl group, a halogen atom, a cyano group, or an acid-decomposable group. n2 represents an integer of 0 to 4. When n2 is 2 or more, the plurality of Rb₂'s present may be different, and the plurality of Rb₂'s present may be linked together to form a ring.

The repeating unit having a group including the lactone structure represented by any one of the formulas (LC1-1) to (LC1-21) or the sultone structure represented by any one of the formulas (SL1-1) to (SL1-3) may be, for example, a repeating unit represented by the following formula (AI).

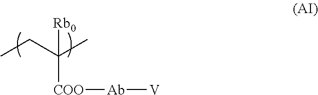

In the formula (AI), Rb₀ represents a hydrogen atom, a halogen atom, or an alkyl group having 1 to 4 carbon atoms. Preferred examples of the substituent that the alkyl group of Rb₀ may have include a hydroxy group and a halogen atom.

Examples of the halogen atom of Rb₀ include a fluorine atom, a chlorine atom, a bromine atom, and an iodine atom. Rb₀ is preferably a hydrogen atom or a methyl group.

Ab represents a single bond, an alkylene group, a divalent linking group having a monocyclic or polycyclic alicyclic hydrocarbon structure, an ether group, an ester group, a carbonyl group, a carboxyl group, or a divalent linking group that is a combination of the foregoing. In particular, Ab is preferably a single bond or a linking group represented by -Ab₁—CO₂—. Ab₁ is a linear or branched alkylene group or a monocyclic or polycyclic cycloalkylene group, and preferably a methylene group, an ethylene group, a cyclohexylene group, an adamantylene group, or a norbornylene group.

V represents a group formed by withdrawing, from a ring-member atom of the lactone structure represented by any one of the formulas (LC1-1) to (LC1-21), a single hydrogen atom, or a group formed by withdrawing, from a ring-member atom of the sultone structure represented by any one of the formulas (SL1-1) to (SL1-3), a single hydrogen atom.

When the repeating unit having a lactone group or a sultone group has an optical isomer, any optical isomer may be used. A single optical isomer may be used alone, or a plurality of optical isomers may be used in combination. In the case of mainly using one of the optical isomers, its optical purity (ee) is preferably 90 or more, and more preferably 95 or more.

The carbonate group is preferably a cyclic carbonic acid ester group.

The repeating unit having a cyclic carbonic acid ester group is preferably a repeating unit represented by the following formula (A-1).

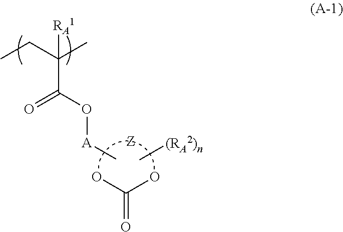

In the formula (A-1), R_{A}¹ represents a hydrogen atom, a halogen atom, or a monovalent organic group (preferably a methyl group). n represents an integer of 0 or more. R_{A}² represents a substituent. When n is 2 or more, the plurality of R_{A}²'s present may be the same or different. A represents a single bond or a divalent linking group. The divalent linking group is preferably an alkylene group, a divalent linking group having a monocyclic or polycyclic alicyclic hydrocarbon structure, an ether group, an ester group, a carbonyl group, a carboxyl group, or a divalent linking group that is a combination of the foregoing. Z represents an atomic group that forms, together with the group represented by —O—CO—O— in the formula, a monocyclic ring or a polycyclic ring.

The following are examples of the unit Y. In the formulas, Rx represent a hydrogen atom, —CH₃, —CH₂OH, or —CF₃.

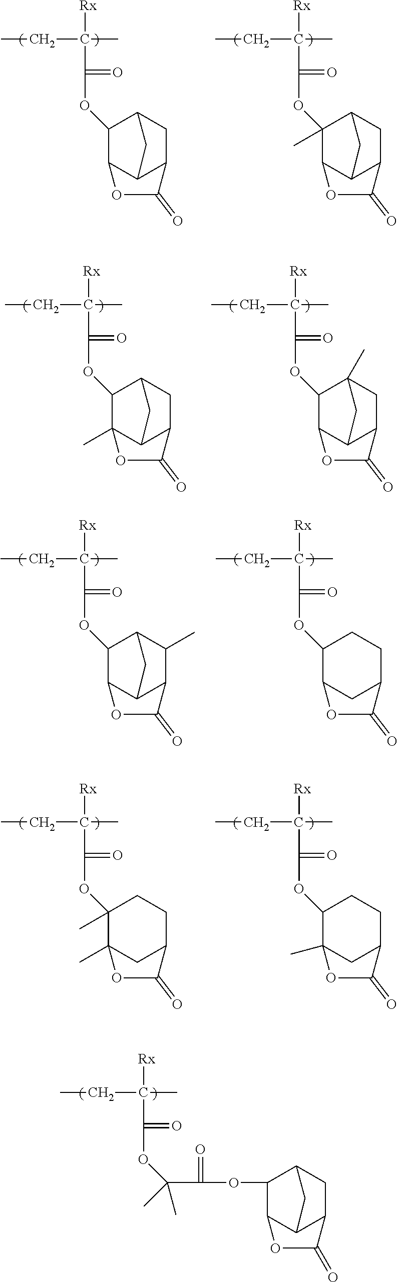

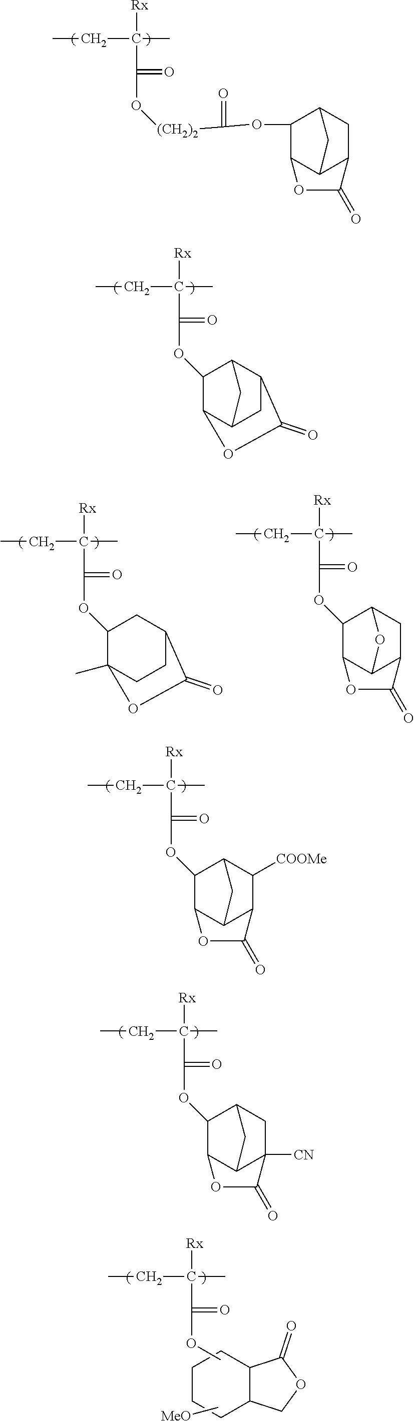

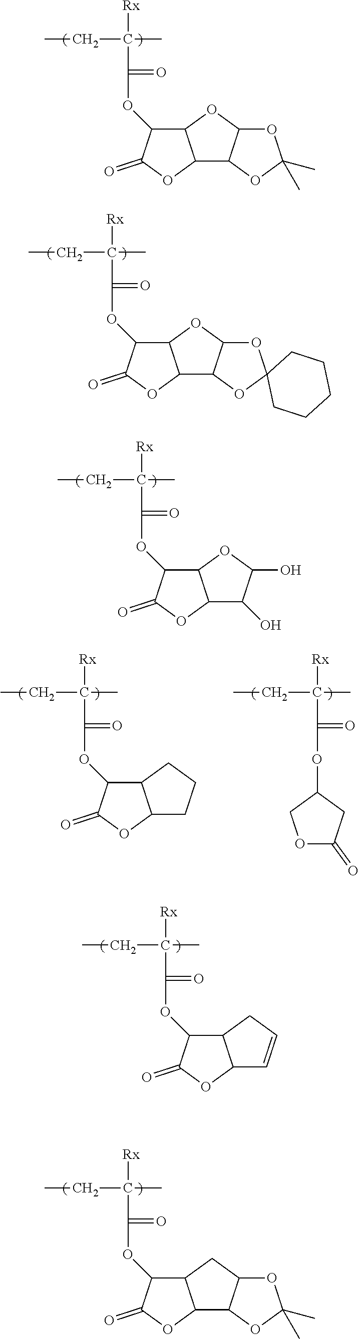

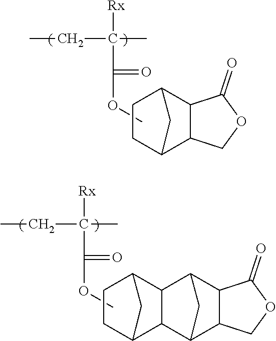

(In the formulas, Rx represent H, CH₃, CH₂OH, or CF₃.)

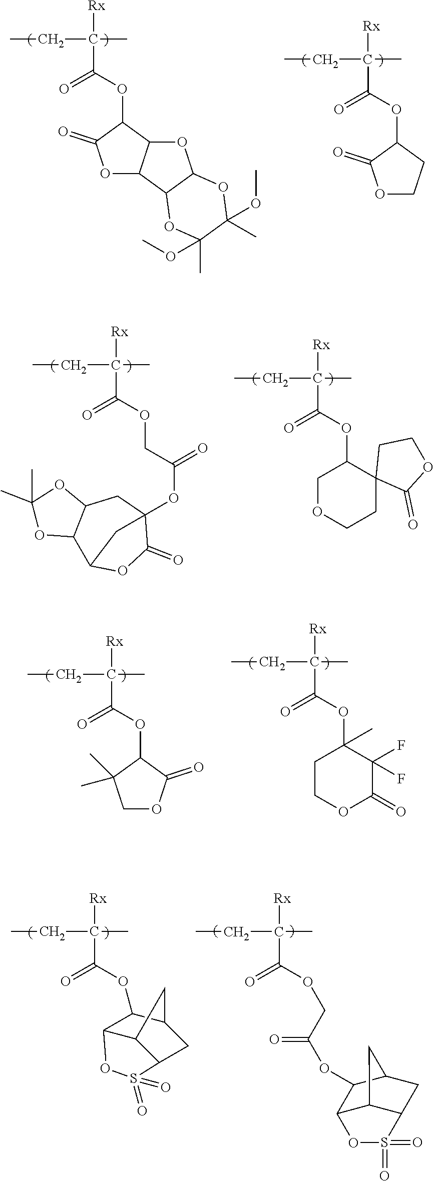

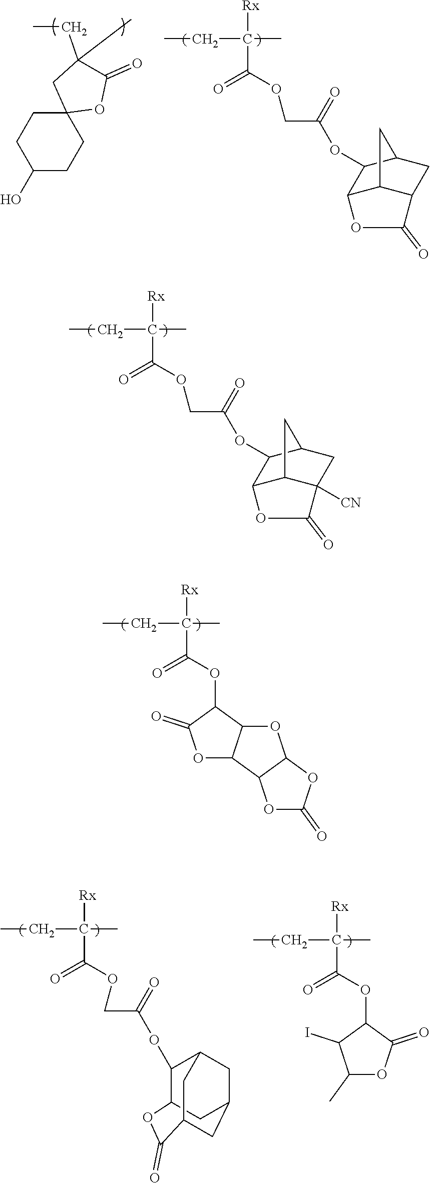

(In the formulas, Rx represent H, CH₃, CH₂OH, or CF₃.)

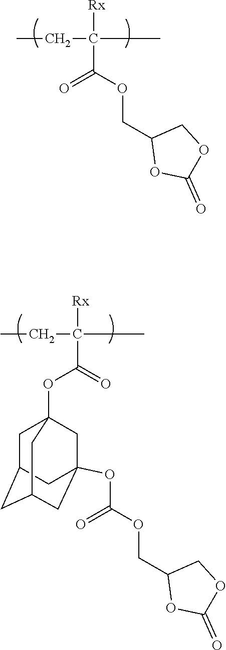

The unit Y content relative to all the repeating units in the resin (A) is preferably 1 mol % or more, and more preferably 10 mol % or more. The upper limit value relative to all the repeating units in the resin (A) is preferably 85 mol % or less, more preferably 80 mol % or less, still more preferably 70 mol % or less, and particularly preferably 60 mol % or less. Repeating unit having photoacid generation group

The resin (A) may have, as another repeating unit, a repeating unit having a group that generates an acid upon irradiation with an actinic ray or a radiation (hereafter, also referred to as “photoacid generation group”).

The repeating unit having a photoacid generation group may be a repeating unit represented by a formula (4).

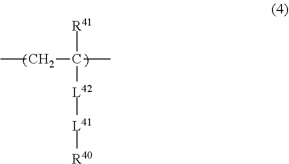

R⁴¹ represents a hydrogen atom or a methyl group. L⁴¹ represents a single bond or a divalent linking group. L⁴² represents a divalent linking group. R⁴⁰ represents a structural moiety that is decomposed upon irradiation with an actinic ray or a radiation to generate an acid in the side chain.

The following are examples of the repeating unit having a photoacid generation group.

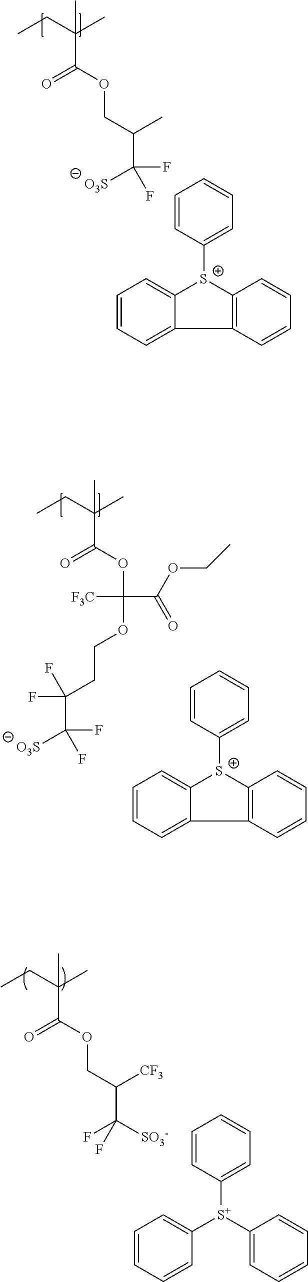

Other examples of the repeating unit represented by the formula (4) include the repeating units described in Paragraphs to of JP2014-041327A and the repeating units described in Paragraph of WO2018/193954A.

The content of the repeating unit having a photoacid generation group relative to all the repeating units in the resin (A) is preferably 1 mol % or more, and more preferably 5 mol % or more. The upper limit value relative to all the repeating units in the resin (A) is preferably 40 mol % or less, more preferably 35 mol % or less, and still more preferably 30 mol % or less. Repeating unit represented by formula (V-1) or formula (V-2) below

The resin (A) may have a repeating unit represented by a formula (V-1) below or a formula (V-2) below.

The repeating unit represented by the following formula (V-1) or the following formula (V-2) is preferably a repeating unit different from the above-described repeating units.

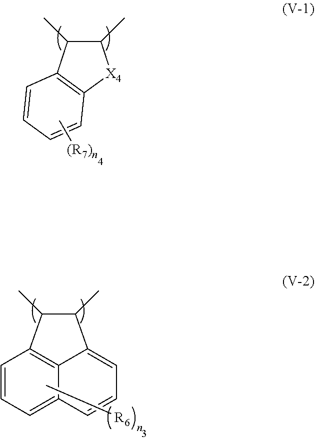

In the formulas,

R₆ and R₇ each independently represent a hydrogen atom, a hydroxy group, an alkyl group, an alkoxy group, an acyloxy group, a cyano group, a nitro group, an amino group, a halogen atom, an ester group (—OCOR or —COOR: R is an alkyl group or fluorinated alkyl group having 1 to 6 carbon atoms), or a carboxyl group. The alkyl group is preferably a linear, branched, or cyclic alkyl group having 1 to 10 carbon atoms.
n₃ represents an integer of 0 to 6.
n₄ represents an integer of 0 to 4.
X₄ is a methylene group, an oxygen atom, or a sulfur atom.

The following are examples of the repeating unit represented by the formula (V-1) or (V-2).

Examples of the repeating unit represented by the formula (V-1) or (V-2) include the repeating units described in Paragraph of WO2018/193954A.

### Repeating Unit for Lowering Mobility of Main Chain

The resin (A) preferably has, from the viewpoint of suppressing excessive diffusion of the generated acid or pattern collapse during development, a relatively high glass transition temperature (Tg). Tg is preferably more than 90° C., more preferably more than 100° C., still more preferably more than 110° C., and particularly preferably more than 125° C. Note that, from the viewpoint of having a high dissolution rate in developers, Tg is preferably 400° C. or less, and more preferably 350° C. or less.

Note that, in this Specification, the glass transition temperatures (Tg) of polymers such as the resin (A) (hereafter, “Tg's of repeating units”) are calculated in the following manner. First, for the repeating units included in a polymer, the Tg's of homopolymers composed only of the repeating units are individually calculated by the Bicerano method. Subsequently, the mass ratios (%) of the repeating units relative to all the repeating units in the polymer are calculated. Subsequently, the Fox equation (described in Materials Letters 62 (2008) 3152, for example) is used to calculate Tg's for the mass ratios and the Tg's are summed up to determine the Tg (° C.) of the polymer.

The Bicerano method is described in Prediction of polymer properties, Marcel Dekker Inc, New York (1993). The calculation of Tg by the Bicerano method can be performed using a software for estimating properties of polymers, MDL Polymer (MDL Information Systems, Inc.).

In order to increase the Tg of the resin (A) (preferably, making Tg be more than 90° C.), the mobility of the main chain of the resin (A) is preferably lowered. Examples of the method for lowering the mobility of the main chain of the resin (A) include the following methods (a) to (e):
(a) introduction of a bulky substituent to the main chain;
(b) introduction of a plurality of substituents to the main chain;
(c) introduction of a substituent that induces interaction between the resins (A), to the vicinity of the main chain;
(d) formation of the main chain having a ring structure; and
(e) linkage of a ring structure to the main chain.

Note that the resin (A) preferably has a repeating unit whose homopolymer has a Tg of 130° C. or more.

Note that the repeating unit species whose homopolymer has a Tg of 130° C. or more is not particularly limited and is a repeating unit whose homopolymer has a Tg of 130° C. or more calculated by the Bicerano method. Note that the repeating units represented by a formula (A) to a formula (E) described later may, depending on the functional group species, belong to the repeating unit whose homopolymer has a Tg of 130° C. or more.

An example of specific means for achieving (a) above is a method of introducing, into the resin (A), a repeating unit represented by a formula (A).

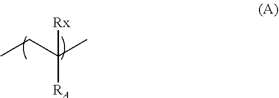

For the formula (A), RA represents a group including a polycyclic structure. Rx represents a hydrogen atom, a methyl group, or an ethyl group. The group including a polycyclic structure is a group including a plurality of cyclic structures; the plurality of cyclic structures may be fused together or may not be fused together.

Specific examples of the repeating unit represented by the formula (A) include those described in Paragraphs [0107] to [0119] of WO2018/193954A.

An example of specific means for achieving (b) above is a method of introducing, into the resin (A), a repeating unit represented by a formula (B).

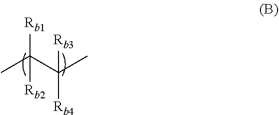

In the formula (B), R_{b1} to R_{b4} each independently represent a hydrogen atom or an organic group; at least two or more among R_{b1} to R_{b4} represent organic groups.

When at least one of the organic groups is a group whose cyclic structure is directly linked to the main chain in the repeating unit, the other organic group species is not particularly limited.

When none of the organic groups is a group whose cyclic structure is directly linked to the main chain in the repeating unit, at least two or more among the organic groups are substituents having three or more constituent atoms (except for hydrogen atoms).

Specific examples of the repeating unit represented by the formula (B) include those described in Paragraphs [0113] to [0115] of WO2018/193954A.

An example of specific means for achieving (c) above is a method of introducing, into the resin (A), a repeating unit represented by a formula (C).

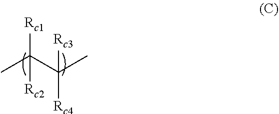

In the formula (C), R_{c1} to R_{c4} each independently represent a hydrogen atom or an organic group; at least one of R_{c1} to R_{c4} is a group including a hydrogen-bond-forming hydrogen atom positioned within three atoms from the carbon atom in the main chain. In particular, from the viewpoint of inducing the interaction between the main chains of the resin (A), it preferably has a hydrogen-bond-forming hydrogen atom positioned within two atoms (closer to the main chain side).

Specific examples of the repeating unit represented by the formula (C) include those described in Paragraphs [0119] to [0121] of WO2018/193954A.

An example of specific means for achieving (d) above is a method of introducing, into the resin (A), a repeating unit represented by a formula (D).

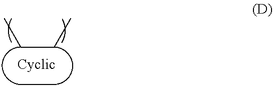

In the formula (D), “Cyclic” represents a group having a ring structure and forming the main chain. The number of atoms constituting the ring is not particularly limited.

Specific examples of the repeating unit represented by the formula (D) include those described in Paragraphs [0126] to [0127] of WO2018/193954A.

An example of specific means for achieving (e) above is a method of introducing, into the resin (A), a repeating unit represented by a formula (E).

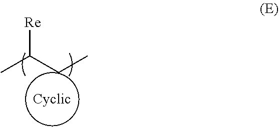

In the formula (E), Re each independently represent a hydrogen atom or an organic group. Examples of the organic group include alkyl groups, cycloalkyl groups, aryl groups, aralkyl groups, and alkenyl groups that may have substituents.

“Cyclic” is a cyclic group including a carbon atom of the main chain. The number of atoms included in the cyclic group is not particularly limited.

Specific examples of the repeating unit represented by the formula (E) include those described in Paragraphs [0131] to [0133] of WO2018/193954A.

Repeating unit having at least one group species selected from the group consisting of lactone group, sultone group, carbonate group, hydroxy group, cyano group, and alkali-soluble group

The resin (A) may have a repeating unit having at least one group species selected from the group consisting of a lactone group, a sultone group, a carbonate group, a hydroxy group, a cyano group, and an alkali-soluble group.

In the resin (A), the repeating unit having a lactone group, a sultone group, or a carbonate group may be the repeating unit having been described in <Repeating unit having lactone group, sultone group, or carbonate group>. Preferred contents are also the same as those having been described in <Repeating unit having lactone group, sultone group, or carbonate group>.

The resin (A) may have a repeating unit having a hydroxy group or a cyano group. This results in improvement in adhesiveness to the substrate and affinity for the developer.

The repeating unit having a hydroxy group or a cyano group is preferably a repeating unit having an alicyclic hydrocarbon structure substituted with a hydroxy group or a cyano group.

The repeating unit having a hydroxy group or a cyano group preferably does not have an acid-decomposable group. Examples of the repeating unit having a hydroxy group or a cyano group include those described in Paragraphs [0081] to [0084] of JP2014-098921A.

The resin (A) may have a repeating unit having an alkali-soluble group.

The alkali-soluble group may be a carboxyl group, a sulfonamide group, a sulfonylimide group, a bissulfonylimide group, or an aliphatic alcohol group substituted, at the a position, with an electron-withdrawing group (for example, a hexafluoroisopropanol group), and is preferably a carboxyl group. When the resin (A) includes the repeating unit having an alkali-soluble group, increased resolution is provided in the contact hole application. Examples of the repeating unit having an alkali-soluble group include those described in Paragraphs and of JP2014-098921A.

### Repeating Unit Having Alicyclic Hydrocarbon Structure and not Exhibiting Acid Decomposability

The resin (A) may have a repeating unit having an alicyclic hydrocarbon structure and not exhibiting acid decomposability. This results in, during liquid immersion exposure, a reduction in leaching of, from the resist film to the immersion liquid, low-molecular-weight components. Examples of the repeating unit having an alicyclic hydrocarbon structure and not exhibiting acid decomposability include a repeating unit derived from 1-adamantyl (meth)acrylate, diamantyl (meth)acrylate, tricyclodecanyl (meth)acrylate, or cyclohexyl (meth)acrylate.

### Repeating Unit not Having Hydroxy Group or Cyano Group and Represented by Formula (III)

The resin (A) may have a repeating unit not having a hydroxy group or a cyano group and represented by a formula (III).

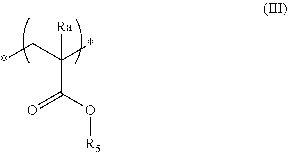

In the formula (III), R₅ represents a hydrocarbon group having at least one ring structure and not having a hydroxy group or a cyano group.

Ra represents a hydrogen atom, an alkyl group, or a —CH₂—O—Ra₂ group. In the formula, Ra₂ represents a hydrogen atom, an alkyl group, or an acyl group.

Examples of the repeating unit not having a hydroxy group or a cyano group and represented by the formula (III) include those described in Paragraphs to of JP2014-098921A.

The resin (A) may have, in addition to the above-described repeating structural units, various repeating structural units for the purpose of adjusting, for example, dry etching resistance, standard developer suitability, substrate adhesiveness, resist profile, resolution, heat resistance, and sensitivity.

The resin (A) can be synthesized in accordance with standard procedures (for example, radical polymerization).

The resin (A) has a weight-average molecular weight of, as a polystyrene-equivalent value determined by the GPC method, preferably 30,000 or less, more preferably 1,000 to 30,000, still more preferably 3,000 to 30,000, and particularly preferably 5,000 to 15,000.

The resin (A) has a dispersity (molecular weight distribution) of preferably 1 to 5, more preferably 1 to 3, still more preferably 1.2 to 3.0, and particularly preferably 1.2 to 2.0. As the dispersity lowers, the resolution becomes higher, the resist profile becomes better, the sidewalls of the resist pattern become smoother, and the roughness performance becomes higher.

In the composition of the present invention, the content of the resin (A) is, relative to the total solid content of the composition, preferably 40.0 to 99.9 mass %, and more preferably 50.0 to 90.0 mass %.

Such resins (A) may be used alone or in combination of two or more thereof.

The composition of the present invention may further include a resin different from the resin (A).

When the composition of the present invention includes a resin different from the resin (A), its content relative to the total solid content of the composition is preferably 0.01 to 20.0 mass %, and more preferably 0.1 to 15.0 mass %.

The resin different from the resin (A) is not particularly limited as long as it is a resin not including the above-described repeating unit (a1) having a partial structure in which a phenolic hydroxy group is protected with a structure represented by the formula (1), and examples thereof include a hydrophobic resin described later.

The composition of the present invention preferably further contains a photoacid generator and a solvent. Hereinafter, components other than the resin (A) will be described. Photoacid generator

The composition of the present invention preferably includes a compound that generates an acid upon irradiation with an actinic ray or a radiation (also referred to as a photoacid generator or a photoacid generator (B)). The photoacid generator is a compound that generates an acid upon exposure (preferably exposure to EUV light).

The photoacid generator (B) may have the form of a low-molecular-weight compound, or the form of being incorporated into a portion of a polymer (for example, the above-described resin (A)). Alternatively, the form of a low-molecular-weight compound and the form of being incorporated into a portion of a polymer (for example, the above-described resin (A)) may be used in combination.

When the photoacid generator (B) has the form of a low-molecular-weight compound, the photoacid generator preferably has a molecular weight of 3000 or less, more preferably 2000 or less, and still more preferably 1000 or less. The lower limit is not particularly limited, but is preferably 100 or more.

When the photoacid generator (B) has the form of being incorporated into a portion of a polymer, it may be incorporated into a portion of the resin (A) or may be incorporated into a resin different from the resin (A).

In this Specification, the photoacid generator (B) preferably has the form of a low-molecular-weight compound.

The photoacid generator (B) may be, for example, a compound represented by “M⁺X⁻” (onium salt), and is preferably a compound that generates an organic acid by exposure.

Examples of the organic acid include sulfonic acids (such as aliphatic sulfonic acids, aromatic sulfonic acids, and camphorsulfonic acid), carboxylic acids (such as aliphatic carboxylic acids, aromatic carboxylic acids, and aralkyl carboxylic acids), carbonylsulfonylimidic acid, bis(alkylsulfonyl) imidic acids, and tris(alkylsulfonyl) methide acids.

In the compound represented by “M⁺X⁻”, M⁺ represents an organic cation.

The organic cation is not particularly limited. For the valence, the organic cation may be mono-, di-, or higher valent.

In particular, the organic cation is preferably a cation represented by a formula (ZaI) (hereafter, also referred to as “cation (ZaI)”) or a cation represented by a formula (ZaII) (hereafter, also referred to as “cation (ZaII)”).

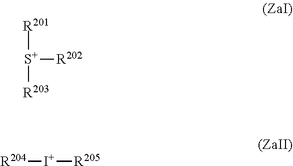

In the above-described formula (ZaI), R²⁰¹, R²⁰², and R²⁰³ each independently represent an organic group.

For R²⁰¹, R²⁰², and R²⁰³, such an organic group preferably has 1 to 30, and more preferably 1 to 20 carbon atoms. Among R²⁰¹ to R²⁰³, two may be bonded together to form a ring structure and the ring may include an oxygen atom, a sulfur atom, an ester group, an amide group, or a carbonyl group. Examples of the group formed by bonding together two among R²⁰¹ to R²⁰³ include alkylene groups (such as a butylene group and a pentylene group), and —CH₂—CH₂—O—CH₂—CH₂—.

Preferred examples of the organic cation in the formula (ZaI) include a cation (ZaI-1), a cation (ZaI-2), a cation (ZaI-3b), and a cation (ZaI-4b) described later.

First, the cation (ZaI-1) will be described.

The cation (ZaI-1) is an aryl sulfonium cation represented by the above-described formula (ZaI) where at least one of R²⁰¹ to R²⁰³ is an aryl group.

In the aryl sulfonium cation, all of R²⁰¹ to R²⁰³ may be aryl groups, or a part of R²⁰¹ to R²⁰³ may be an aryl group and the other may be an alkyl group or a cycloalkyl group.

Alternatively, one among R²⁰¹ to R²⁰³ may be an aryl group and the other two among R²⁰¹ to R²⁰³ may be linked together to form a ring structure in which the ring may include an oxygen atom, a sulfur atom, an ester group, an amide group, or a carbonyl group. Examples of the group formed by bonding together two among R²⁰¹ to R²⁰³ include alkylene groups in which one or more methylene groups may be substituted with an oxygen atom, a sulfur atom, an ester group, an amide group, and/or a carbonyl group (such as a butylene group, a pentylene group, and —CH₂—CH₂—O—CH₂—CH₂—).

Examples of the aryl sulfonium cation include triaryl sulfonium cations, diaryl alkyl sulfonium cations, aryl dialkyl sulfonium cations, diaryl cycloalkyl sulfonium cations, and aryl dicycloalkyl sulfonium cations.

The aryl group included in the aryl sulfonium cation is preferably a phenyl group or a naphthyl group, and more preferably a phenyl group. The aryl group may also be an aryl group having a heterocyclic structure having an oxygen atom, a nitrogen atom, or a sulfur atom, for example. Examples of the heterocyclic structure include a pyrrole residue, a furan residue, a thiophene residue, an indole residue, a benzofuran residue, and a benzothiophene residue. When the aryl sulfonium cation has two or more aryl groups, the two or more aryl groups may be the same or different.

The alkyl group or cycloalkyl group that the aryl sulfonium cation optionally has is preferably a linear alkyl group having 1 to 15 carbon atoms, a branched alkyl group having 3 to 15 carbon atoms, or a cycloalkyl group having 3 to 15 carbon atoms, and more preferably a methyl group, an ethyl group, a propyl group, an n-butyl group, a sec-butyl group, a t-butyl group, a cyclopropyl group, a cyclobutyl group, or a cyclohexyl group.

For R²⁰¹ to R²⁰³, a substituent that the aryl group, the alkyl group, and the cycloalkyl group may have is preferably an alkyl group (having, for example, 1 to 15 carbon atoms), a cycloalkyl group (having, for example, 3 to 15 carbon atoms), an aryl group (having, for example, 6 to 14 carbon atoms), an alkoxy group (having, for example, 1 to 15 carbon atoms), a cycloalkylalkoxy group (having, for example, 1 to 15 carbon atoms), a halogen atom (for example, fluorine or iodine), a hydroxyl group, a carboxyl group, an ester group, a sulfinyl group, a sulfonyl group, an alkylthio group, or a phenylthio group.

The substituent may further have, when possible, a substituent; the alkyl group also preferably has, as a substituent, a halogen atom to serve as an alkyl halide group such as a trifluoromethyl group.

Such substituents are also preferably combined appropriately to form an acid-decomposable group.

Note that the acid-decomposable group means a group that is decomposed by the action of an acid to generate a polar group, and preferably has a structure in which a group that leaves by the action of an acid protects the polar group. The polar group and the leaving group are as described above.

Hereinafter, the cation (ZaI-2) will be described.

The cation (ZaI-2) is a cation represented by the formula (ZaI) where R²⁰¹ to R²⁰³ each independently represent an organic group not having an aromatic ring. The aromatic ring also encompasses aromatic rings including a heteroatom.

For R²⁰¹ to R²⁰³, the organic group not having an aromatic ring preferably has 1 to 30 carbon atoms and more preferably 1 to 20 carbon atoms.

R²⁰¹ to R²⁰³ are each independently preferably an alkyl group, a cycloalkyl group, an allyl group, or a vinyl group, more preferably a linear or branched 2-oxoalkyl group, a 2-oxocycloalkyl group, or an alkoxycarbonylmethyl group, and still more preferably a linear or branched 2-oxoalkyl group.

For R²⁰¹ to R²⁰³, the alkyl group and the cycloalkyl group may be, for example, a linear alkyl group having 1 to 10 carbon atoms or a branched alkyl group having 3 to 10 carbon atoms (for example, a methyl group, an ethyl group, a propyl group, a butyl group, or a pentyl group), and a cycloalkyl group having 3 to 10 carbon atoms (for example, a cyclopentyl group, a cyclohexyl group, or a norbornyl group).

R²⁰¹ to R²⁰³ may be further substituted with a halogen atom, an alkoxy group (having, for example, 1 to 5 carbon atoms), a hydroxy group, a cyano group, or a nitro group.

For R²⁰¹ to R²⁰³, substituents are also preferably provided independently as appropriate combinations of substituents to form acid-decomposable groups.

Hereinafter, the cation (ZaI-3b) will be described.

The cation (ZaI-3b) is a cation represented by the following formula (ZaI-3b).

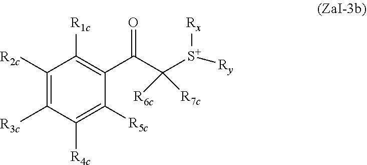

In the formula (ZaI-3b), R_{1c} to R_{5c} each independently represent a hydrogen atom, an alkyl group, a cycloalkyl group, an aryl group, an alkoxy group, an aryloxy group, an alkoxycarbonyl group, an alkylcarbonyloxy group, a cycloalkylcarbonyloxy group, a halogen atom, a hydroxy group, a nitro group, an alkylthio group, or an arylthio group.

R_{6c} and R_{7c} each independently represent a hydrogen atom, an alkyl group (for example, a t-butyl group), a cycloalkyl group, a halogen atom, a cyano group, or an aryl group.

Rₓ and R_{y} each independently represent an alkyl group, a cycloalkyl group, a 2-oxoalkyl group, a 2-oxocycloalkyl group, an alkoxycarbonylalkyl group, an allyl group, or a vinyl group.

For R_{1c} to R_{7c} and Rₓ and R_{y}, such substituents are also preferably provided independently as appropriate combinations of substituents to form acid-decomposable groups.

Any two or more among R_{1c} to R_{5c}, R_{5c} and R_{6c}, R_{6c} and R_{7c}, R_{5c} and Rₓ, and Rₓ and R_{y} may be individually bonded together to form rings; these rings may each independently include an oxygen atom, a sulfur atom, a ketone group, an ester bond, or an amide bond.

Such a ring may be an aromatic or non-aromatic hydrocarbon ring, an aromatic or non-aromatic heterocycle, or a polycyclic fused ring formed as a combination of two or more of these rings. The ring may be a 3- to 10-membered ring, and is preferably a 4- to 8-membered ring, and more preferably a 5- or 6-membered ring.

Examples of the groups formed by bonding together any two or more among R_{1c} to R_{5c}, R_{6c} and R_{7c}, and Rₓ and R_{y} include alkylene groups such as a butylene group and a pentylene group. In such an alkylene group, a methylene group may be substituted with a heteroatom such as an oxygen atom.

The groups formed by bonding together R_{5c} and R_{6c}, and R_{5c} and Rₓ are preferably single bonds or alkylene groups. Examples of the alkylene groups include a methylene group and an ethylene group.

R_{1c} to R_{5c}, R_{6c}, R_{7c}, Rₓ, R_{y}, and the rings formed by individually bonding together any two or more among R_{1c} to R_{5c}, R_{5c} and R_{6c}, R_{6c} and R_{7c}, R_{5c} and Rₓ, and Rₓ and R_{y} may have a substituent.

Hereinafter, the cation (ZaI-4b) will be described.

The cation (ZaI-4b) is a cation represented by the following formula (ZaI-4b).

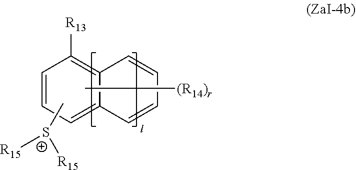

In the formula (ZaI-4b), 1 represents an integer of 0 to 2, and r represents an integer of 0 to 8.

R₁₃ represents a hydrogen atom, a halogen atom (for example, a fluorine atom or an iodine atom), a hydroxyl group, an alkyl group, an alkyl halide group, an alkoxy group, a carboxyl group, an alkoxycarbonyl group, or a group including a cycloalkyl group (may be the cycloalkyl group itself or may be a group including, as a part thereof, the cycloalkyl group). These groups may have a substituent.

R₁₄ represents a hydroxyl group, a halogen atom (for example, a fluorine atom or an iodine atom), an alkyl group, an alkyl halide group, an alkoxy group, an alkoxycarbonyl group, an alkylcarbonyl group, an alkylsulfonyl group, a cycloalkylsulfonyl group, or a group including a cycloalkyl group (may be the cycloalkyl group itself or may be a group including, as a part thereof, the cycloalkyl group). These groups may have a substituent. When there are a plurality of R₁₄'s, R₁₄'s each independently represent such a group, for example, a hydroxyl group.

R₁₅'s each independently represent an alkyl group, a cycloalkyl group, or a naphthyl group. Two R₁₅'s may be bonded together to form a ring. When two R₁₅'s are bonded together to form a ring, the ring skeleton may include a heteroatom such as an oxygen atom or a nitrogen atom.

In an example, two R₁₅'s are preferably alkylene groups and bonded together to form a ring structure. Note that the alkyl group, the cycloalkyl group, the naphthyl group, and the ring formed by bonding together two R₁₅'s may have a substituent.

In the formula (ZaI-4b), for R₁₃, R₁₄, and R₁₅, the alkyl groups may be linear or branched. Such an alkyl group preferably has 1 to 10 carbon atoms. Preferred examples of the alkyl group include a methyl group, an ethyl group, an n-butyl group, and a t-butyl group.

For R₁₃ to R₁₅, and Rₓ and R_{y}, such substituents are also preferably provided independently as appropriate combinations of substituents to form acid-decomposable groups.

Hereinafter, the formula (ZaII) will be described.

In the formula (ZaII), R²⁰⁴ and R²⁰⁵ each independently represent an aryl group, an alkyl group, or a cycloalkyl group.

For R²⁰⁴ and R²⁰⁵, the aryl group is preferably a phenyl group or a naphthyl group, and more preferably a phenyl group. For R²⁰⁴ and R²⁰⁵, the aryl group may be an aryl group having a heterocycle having an oxygen atom, a nitrogen atom, or a sulfur atom, for example. Examples of the skeleton of the aryl group having a heterocycle include pyrrole, furan, thiophene, indole, benzofuran, and benzothiophene.

For R²⁰⁴ and R²⁰⁵, the alkyl group and the cycloalkyl group are preferably a linear alkyl group having 1 to 10 carbon atoms, a branched alkyl group having 3 to 10 carbon atoms (for example, a methyl group, an ethyl group, a propyl group, a butyl group, or a pentyl group), or a cycloalkyl group having 3 to 10 carbon atoms (for example, a cyclopentyl group, a cyclohexyl group, or a norbornyl group).

For R²⁰⁴ and R²⁰⁵, the aryl group, the alkyl group, and the cycloalkyl group may each independently have a substituent. For R²⁰⁴ and R²⁰⁵, examples of the substituent that the aryl group, the alkyl group, and the cycloalkyl group may have include alkyl groups (having, for example, 1 to 15 carbon atoms), cycloalkyl groups (having, for example, 3 to 15 carbon atoms), aryl groups (having, for example, 6 to 15 carbon atoms), alkoxy groups (having, for example, 1 to 15 carbon atoms), halogen atoms, a hydroxy group, and a phenylthio group. For R²⁰⁴ and R²⁰⁵, substituents are also preferably provided independently as appropriate combinations of substituents to form acid-decomposable groups.

The following are specific examples of the organic cation; however, the present invention is not limited to these.

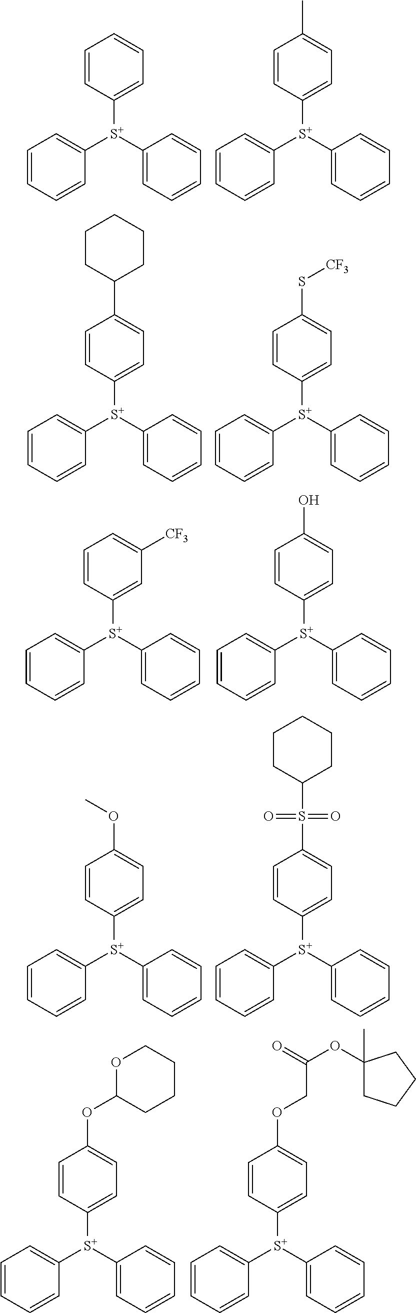

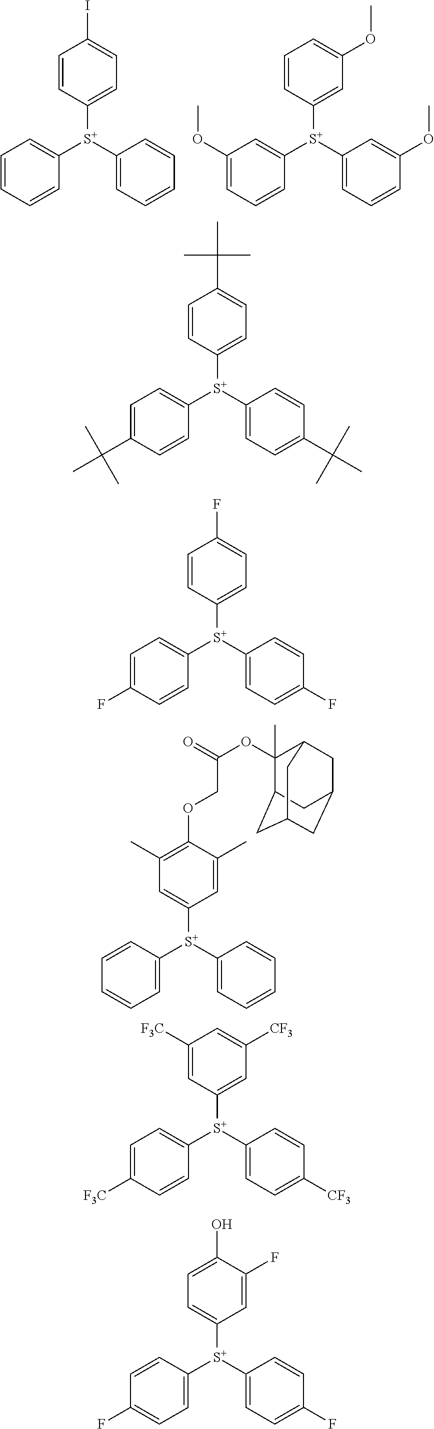

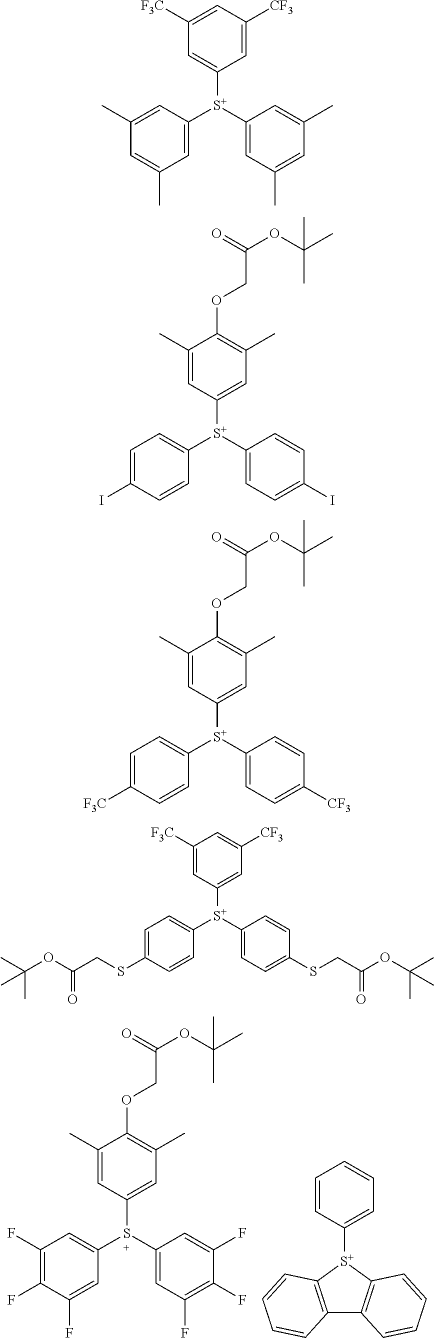

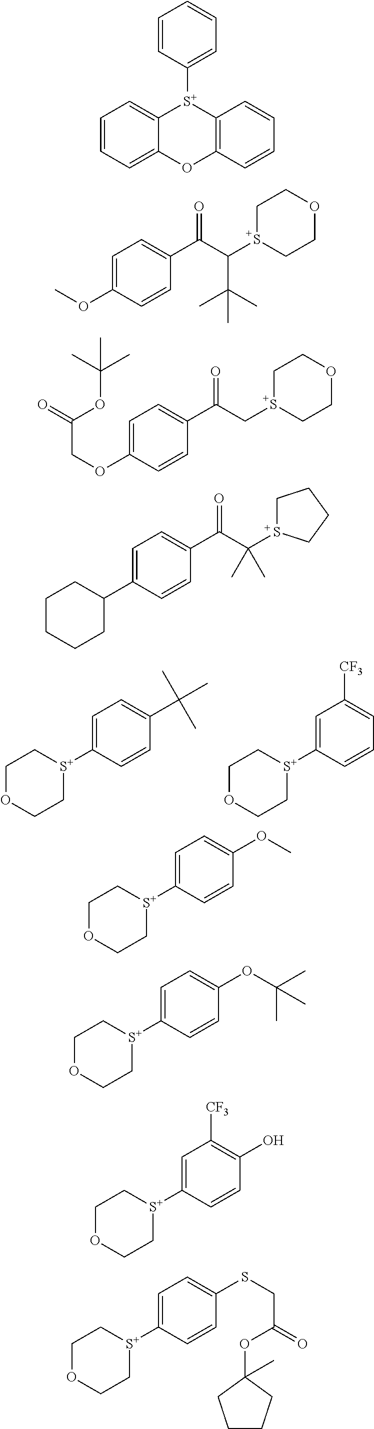

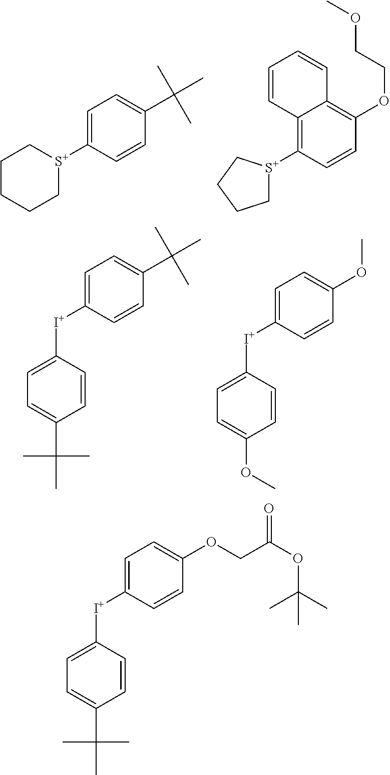 [SMILES: CC(C)(C)c1ccc([S+]2CCCCC2)cc1 ; COCCOc1ccc([S+]2CCCC2)c2ccccc12 ; CC(C)(C)c1ccc([I+]c2ccc(C(C)(C)C)cc2)cc1 ; COc1ccc([I+]c2ccc(OC)cc2)cc1 ; CC(C)(C)OC(=O)COc1ccc([I+]c2ccc(C(C)(C)C)cc2)cc1]

In the compound represented by “M⁺X⁻”, X⁻ represents an organic anion.

The organic anion is not particularly limited, but may be a mono-, di-, or higher valent organic anion.

The organic anion is preferably an anion that has a very low capability of causing a nucleophilic reaction, and more preferably a non-nucleophilic anion.

Examples of the non-nucleophilic anion include sulfonate anions (such as aliphatic sulfonate anions, aromatic sulfonate anions, and a camphorsulfonate anion), carboxylate anions (such as aliphatic carboxylate anions, aromatic carboxylate anions, and aralkyl carboxylate anions), a sulfonylimide anion, bis(alkylsulfonyl)imide anions, and tris(alkylsulfonyl) methide anions.

In such an aliphatic sulfonate anion or aliphatic carboxylate anion, the aliphatic moiety may be a linear or branched alkyl group or a cycloalkyl group, and is preferably a linear or branched alkyl group having 1 to 30 carbon atoms, or a cycloalkyl group having 3 to 30 carbon atoms.

The alkyl group may be, for example, a fluoroalkyl group (that may have a substituent other than a fluorine atom, or may be a perfluoroalkyl group).

In such an aromatic sulfonate anion or aromatic carboxylate anion, the aryl group is preferably an aryl group having 6 to 14 carbon atoms and may be, for example, a phenyl group, a tolyl group, or a naphthyl group.

The above-described alkyl group, cycloalkyl group, and aryl group may have a substituent. The substituent is not particularly limited; examples include a nitro group, halogen atoms such as a fluorine atom and a chlorine atom, a carboxyl group, a hydroxy group, an amino group, a cyano group, alkoxy groups (preferably having 1 to 15 carbon atoms), alkyl groups (preferably having 1 to 10 carbon atoms), cycloalkyl groups (preferably having 3 to 15 carbon atoms), aryl groups (preferably having 6 to 14 carbon atoms), alkoxycarbonyl groups (preferably having 2 to 7 carbon atoms), acyl groups (preferably having 2 to 12 carbon atoms), alkoxycarbonyloxy groups (preferably having 2 to 7 carbon atoms), alkylthio groups (preferably having 1 to 15 carbon atoms), alkylsulfonyl groups (preferably having 1 to 15 carbon atoms), alkyliminosulfonyl groups (preferably having 1 to 15 carbon atoms), and aryloxysulfonyl groups (preferably having 6 to 20 carbon atoms).

In such an aralkyl carboxylate anion, the aralkyl group is preferably an aralkyl group having 7 to 14 carbon atoms.

Examples of the aralkyl group having 7 to 14 carbon atoms include a benzyl group, a phenethyl group, a naphthylmethyl group, a naphthylethyl group, and a naphthylbutyl group.

The sulfonylimide anion may be, for example, a saccharin anion.

In such a bis(alkylsulfonyl)imide anion or a tris(alkylsulfonyl) methide anion, the alkyl groups are preferably an alkyl group having 1 to 5 carbon atoms. In the alkyl group, a substituent may be a halogen atom, an alkyl group substituted with a halogen atom, an alkoxy group, an alkylthio group, an alkyloxysulfonyl group, an aryloxysulfonyl group, or a cycloalkylaryloxysulfonyl group, and is preferably a fluorine atom or an alkyl group substituted with a fluorine atom.

In the bis(alkylsulfonyl)imide anion, the alkyl groups may be bonded together to form a ring structure. This results in an increase in the acid strength.

Other examples of the non-nucleophilic anion include phosphorus fluoride (for example, PF₆⁻), boron fluoride (for example, BF₄⁻), and antimony fluoride (for example, SbF₆⁻).

The non-nucleophilic anion is preferably an aliphatic sulfonate anion in which at least the a position of sulfonic acid is substituted with a fluorine atom, an aromatic sulfonate anion substituted with a fluorine atom or a group having a fluorine atom, a bis(alkylsulfonyl)imide anion in which the alkyl groups are substituted with fluorine atoms, or a tris(alkylsulfonyl) methide anion in which the alkyl groups are substituted with fluorine atoms. In particular, the anion is more preferably a perfluoroaliphatic sulfonate anion (preferably having 4 to 8 carbon atoms) or a benzenesulfonate anion having a fluorine atom, and still more preferably a nonafluorobutanesulfonate anion, a perfluorooctanesulfonate anion, a pentafluorobenzenesulfonate anion, or a 3,5-bis(trifluoromethyl)benzenesulfonate anion.

The non-nucleophilic anion is also preferably an anion represented by the following formula (AN1).

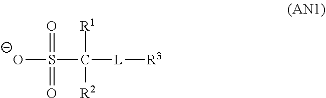

In the formula (AN1), R¹ and R² each independently represent a hydrogen atom or a substituent.

The substituent is not particularly limited, but is preferably a group that is not electron-withdrawing groups. Examples of the group that is not electron-withdrawing groups include hydrocarbon groups, a hydroxy group, oxyhydrocarbon groups, oxycarbonylhydrocarbon groups, an amino group, hydrocarbon-substituted amino groups, and hydrocarbon-substituted amide groups.

Such groups that are not electron-withdrawing groups are each independently preferably —R′, —OH, —OR′, —OCOR′, —NH₂, —NR′₂, —NHR′, or —NHCOR′. R′ are monovalent hydrocarbon groups.

Examples of the monovalent hydrocarbon groups represented by R′ above include monovalent linear or branched hydrocarbon groups such as alkyl groups such as a methyl group, an ethyl group, a propyl group, and a butyl group; alkenyl groups such as an ethenyl group, a propenyl group, and a butenyl group; and alkynyl groups such as an ethynyl group, a propynyl group, and a butynyl group; monovalent alicyclic hydrocarbon groups such as cycloalkyl groups such as a cyclopropyl group, a cyclobutyl group, a cyclopentyl group, a cyclohexyl group, a norbornyl group, and an adamantyl group; and cycloalkenyl groups such as a cyclopropenyl group, a cyclobutenyl group, a cyclopentenyl group, and a norbornenyl group; and monovalent aromatic hydrocarbon groups such as aryl groups such as a phenyl group, a tolyl group, a xylyl group, a mesityl group, a naphthyl group, a methylnaphthyl group, an anthryl group, and methylanthryl group; and aralkyl groups such as a benzyl group, a phenethyl group, a phenylpropyl group, a naphthylmethyl group, and an anthrylmethyl group.

In particular, R¹ and R² are each independently preferably a hydrocarbon group (preferably a cycloalkyl group) or a hydrogen atom.

L represents a divalent linking group.

When a plurality of L's are present, L's may be the same or different.

The divalent linking group may be, for example, —O—CO—O—, —COO—, —CONH—, —CO—, —O—, —S—, —SO—, —SO₂—, an alkylene group (preferably having 1 to 6 carbon atoms), a cycloalkylene group (preferably having 3 to 15 carbon atoms), an alkenylene group (preferably having 2 to 6 carbon atoms), or a divalent linking group that is a combination of a plurality of the foregoing. In particular, the divalent linking group is preferably —O—CO—O—, —COO—, —CONH—, —CO—, —O—, —SO₂—, —O—CO—O-alkylene group-, —COO-alkylene group-, or —CONH-alkylene group-, and more preferably —O—CO—O—, —O—CO—O-alkylene group-, —COO—, —CONH—, —SO₂—, or —COO-alkylene group-.

L is preferably, for example, a group represented by the following formula (AN1-1).

*^{a}—(CR^{2a}₂)_{X}-Q-(CR^{2b}₂)_{Y}—*^{b} (AN1-1)

In the formula (AN1-1), *^{a} represents the bonding site to R³ in the formula (AN1).

*^{b} represents the bonding site to —C(R₁)(R₂)— in the formula (AN1).

X and Y each independently represent an integer of 0 to 10, and is preferably an integer of 0 to 3.

R^{2a} and R^{2b} each independently represent a hydrogen atom or a substituent.

When a plurality of R^{2a}'s and a plurality of R^{2b}'s are present, the plurality of R^{2a}'s and the plurality of R^{2b}'s present may be individually the same or different.

Note that, when Y is 1 or more, in the formula (AN1), in CR^{2b}₂ directly bonded to —C(R¹)(R²)—, R^{2b}'s are not fluorine atoms.

Q represents *^{A}-O—CO—O—*^{B}, *^{A}-CO—*^{B}, *^{A}-CO—O—*^{B}, *^{A}-O—CO—*^{B}, *^{A}O—*^{B}, *^{A}-S—*^{B}, or *^{A}-SO₂—*^{B}.

Note that, when X+Y in the formula (AN1-1) is 1 or more, and R^{2a}'s and R^{2b}'s in the formula (AN1-1) are all hydrogen atoms, Q represents *^{A}-O—CO—O—*^{B}, *^{A}-CO—*^{B}, *^{A}-O—CO—*^{B}, *^{A}-O—*^{B}, *^{A}-S—*^{B}, or *^{A}-SO₂—*^{B}.

*^{A} represent a bonding site on the R³ side in the formula (AN1) and *^{B} represent a bonding site on the —SO₃⁻ side in the formula (AN1).

In the formula (AN1), R³ represents an organic group.

The organic group is not particularly limited as long as it has 1 or more carbon atoms, may be a linear group (for example, a linear alkyl group) or a branched group (for example, a branched alkyl group such as a t-butyl group), or may be a cyclic group. The organic group may have or may not have a substituent. The organic group may have or may not have a heteroatom (such as an oxygen atom, a sulfur atom, and/or a nitrogen atom).

In particular, R³ is preferably an organic group having a ring structure. The ring structure may be monocyclic or polycyclic, and may have a substituent. In the organic group including a ring structure, the ring is preferably directly bonded to L in the formula (AN1).

The organic group having a ring structure, for example, may have or may not have a heteroatom (such as an oxygen atom, a sulfur atom, and/or a nitrogen atom). The heteroatom may substitute one or more carbon atoms forming the ring structure.

The organic group having a ring structure is preferably, for example, a hydrocarbon group having a ring structure, a lactone ring group, or a sultone ring group. In particular, the organic group having a ring structure is preferably a hydrocarbon group having a ring structure.

The hydrocarbon group having a ring structure is preferably a monocyclic or polycyclic cycloalkyl group. Such groups may have a substituent.

The cycloalkyl group may be monocyclic (such as a cyclohexyl group) or polycyclic (such as an adamantyl group), and preferably has 5 to 12 carbon atoms.

The lactone group and the sultone group are, for example, preferably a group provided by removing, in any one of the above-described structures represented by the formulas (LC1-1) to (LC1-21) and structures represented by the formulas (SL1-1) to (SL1-3), a single hydrogen atom from a ring-member atom constituting the lactone structure or the sultone structure.

The non-nucleophilic anion may be a benzenesulfonate anion, and is preferably a benzenesulfonate anion substituted with a branched alkyl group or a cycloalkyl group.

The non-nucleophilic anion is also preferably an anion represented by the following formula (AN2).

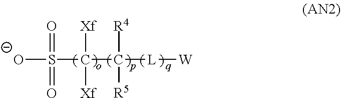

In the formula (AN2), o represents an integer of 1 to 3. p represents an integer of 0 to 10. q represents an integer of 0 to 10.

Xf's represent a hydrogen atom, a fluorine atom, an alkyl group substituted with at least one fluorine atom, or an organic group not having fluorine atoms. The alkyl group preferably has 1 to 10 carbon atoms, and more preferably 1 to 4 carbon atoms. The alkyl group substituted with at least one fluorine atom is preferably a perfluoroalkyl group.

Xf's are preferably a fluorine atom or a perfluoroalkyl group having 1 to 4 carbon atoms, and more preferably a fluorine atom or CF₃; still more preferably, both of Xf's are fluorine atoms.

R⁴ and R⁵ each independently represent a hydrogen atom, a fluorine atom, an alkyl group, or an alkyl group substituted with at least one fluorine atom. When a plurality of R⁴'s and a plurality of R⁵'s are present, R⁴'s and R⁵'s may be individually the same or different.

The alkyl groups represented by R⁴ and R⁵ preferably have 1 to 4 carbon atoms. The alkyl groups may have a substituent. R⁴ and R⁵ are preferably a hydrogen atom.

L represents a divalent linking group. L has the same definition as L in the formula (AN1).

W represents an organic group, and preferably represents an organic group including a ring structure. In particular, preferred is a cyclic organic group.

The cyclic organic group may be, for example, an alicyclic group, an aryl group, or a heterocyclic group.

The alicyclic group may be monocyclic or may be polycyclic. Examples of the monocyclic alicyclic group include monocyclic cycloalkyl groups such as a cyclopentyl group, a cyclohexyl group, and a cyclooctyl group. Examples of the polycyclic alicyclic group include polycyclic cycloalkyl groups such as a norbornyl group, a tricyclodecanyl group, a tetracyclodecanyl group, a tetracyclododecanyl group, and an adamantyl group. In particular, preferred are alicyclic groups having a bulky structure having 7 or more carbon atoms such as a norbornyl group, a tricyclodecanyl group, a tetracyclodecanyl group, a tetracyclododecanyl group, and an adamantyl group.

The aryl group may be monocyclic or polycyclic. Examples of the aryl group include a phenyl group, a naphthyl group, a phenanthryl group, and an anthryl group.

The heterocyclic group may be monocyclic or polycyclic. In particular, in the case of a polycyclic heterocyclic group, diffusion of acid can be further suppressed. The heterocyclic group may have aromaticity or may not have aromaticity. Examples of the heterocycle having aromaticity include a furan ring, a thiophene ring, a benzofuran ring, a benzothiophene ring, a dibenzofuran ring, a dibenzothiophene ring, and a pyridine ring. Examples of the heterocycle not having aromaticity include a tetrahydropyran ring, a lactone ring, a sultone ring, and a decahydroisoquinoline ring. In the heterocyclic group, the heterocycle is preferably a furan ring, a thiophene ring, a pyridine ring, or a decahydroisoquinoline ring.

The cyclic organic group may have a substituent. The substituent may be, for example, an alkyl group (that may be linear or branched and preferably has 1 to 12 carbon atoms), a cycloalkyl group (that may have a monocycle, a polycycle, or a spiro ring, and preferably has 3 to 20 carbon atoms), an aryl group (preferably having 6 to 14 carbon atoms), a hydroxy group, an alkoxy group, an ester group, an amide group, a urethane group, a ureido group, a thioether group, a sulfonamide group, or a sulfonic acid ester group. Note that a carbon constituting the cyclic organic group (carbon contributing to formation of the ring) may be a carbonyl carbon.

The anion represented by the formula (AN2) is preferably SO₃⁻—CF₂—CH₂—OCO-(L)_{q′}-W, SO₃⁻—CF₂—CHF—CH₂—OCO-(L)_{q′}-W, SO₃—CF₂—COO-(L)_{q′}-W, SO₃—CF₂—CF₂—CH₂—CH₂-(L)_{q}-W, or SO₃⁻—CF₂—CH(CF₃)—OCO-(L)_{q′}-W. Here, L, q, and W are the same as those in the formula (AN2). q′ represents an integer of 0 to 10.

The non-nucleophilic anion is also preferably an aromatic sulfonate anion represented by the following formula (AN3).

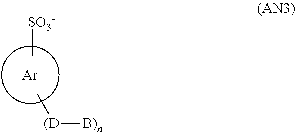

In the formula (AN3), Ar represents an aryl group (such as a phenyl group), and may further have a substituent other than the sulfonate anion and the-(D-B) group. Examples of the substituent that Ar may further have include a fluorine atom and a hydroxy group.

n represents an integer of 0 or more. n is preferably 1 to 4, more preferably 2 to 3, and still more preferably 3.

D represents a single bond or a divalent linking group. The divalent linking group may be an ether group, a thioether group, a carbonyl group, a sulfoxide group, a sulfo group, a sulfonic acid ester group, an ester group, or a group that is a combination of two or more of the foregoing.

B represents a hydrocarbon group.

B is preferably an aliphatic hydrocarbon group, and more preferably an isopropyl group, a cyclohexyl group, or an aryl group that may further have a substituent (such as a tricyclohexylphenyl group).

The non-nucleophilic anion is also preferably a disulfonamide anion.

The disulfonamide anion is, for example, an anion represented by N⁻(SO₂—R^{q})₂.

R^{q}'s represent an alkyl group that may have a substituent, are preferably a fluoroalkyl group, and more preferably a perfluoroalkyl group. Two R^{q}'s may be bonded together to form a ring. The group formed by bonding together two R^{q}'s is preferably an alkylene group that may have a substituent, preferably a fluoroalkylene group, and more preferably a perfluoroalkylene group. The alkylene group preferably has 2 to 4 carbon atoms.

Other examples of the non-nucleophilic anion include anions represented by the following formulas (d1-1) to (d1-4).

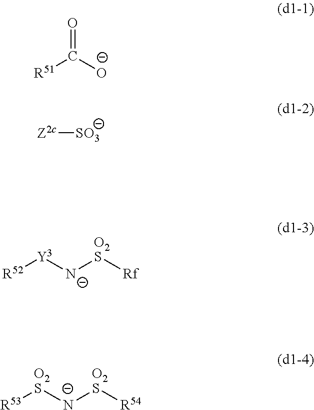

In the formula (d1-1), R⁵¹ represents a hydrocarbon group that may have a substituent (such as a hydroxy group) (for example, an aryl group such as a phenyl group).

In the formula (d1-2), Z^{2c} represents a hydrocarbon group that has 1 to 30 carbon atoms and that may have a substituent (provided that the carbon atom adjacent to S is not substituted with a fluorine atom).

In Z^{2c}, the hydrocarbon group may be linear or branched, and may have a ring structure. In the hydrocarbon group, a carbon atom (preferably, in a case where the hydrocarbon group has a ring structure, a carbon atom serving as a ring-member atom) may be a carbonyl carbon (—CO—). The hydrocarbon group may be, for example, a group that has a norbornyl group that may have a substituent. A carbon atom forming the norbornyl group may be a carbonyl carbon.

In the formula (d1-2), “Z^{2c}—SO₃⁻” is preferably different from the anions represented by the above-described formulas (AN1) to (AN3). For example, Z^{2c} is preferably not aryl groups. For example, in Z^{2c}, the atoms at the a position and the β position with respect to —SO₃⁻ are preferably atoms other than carbon atoms having, as a substituent, a fluorine atom. For example, in Z^{2c}, the atom at the α position and/or the atom at the β position with respect to —SO₃⁻ is preferably a ring-member atom in a ring group.

In the formula (d1-3), R⁵² represents an organic group (preferably a hydrocarbon group having a fluorine atom); Y³ represents a linear, branched, or cyclic alkylene group, an arylene group, or a carbonyl group; and Rf represents a hydrocarbon group.

In the formula (d1-4), R⁵³ and R⁵⁴ each independently represent an organic group (preferably a hydrocarbon group having a fluorine atom). R⁵³ and R⁵⁴ may be bonded together to form a ring.

Such organic anions may be used alone or in combination of two or more thereof.

The photoacid generator is also preferably at least one selected from the group consisting of compounds (I) and (II).

### Compound (I)

The compound (I) is a compound having one or more structural moieties X below and one or more structural moieties Y below and is a compound that generates, upon irradiation with an actinic ray or a radiation, an acid including a first acidic moiety below derived from the structural moiety X below and a second acidic moiety below derived from the structural moiety Y below.

Structural moiety X: a structural moiety that is constituted by an anionic moiety A₁⁻ and a cationic moiety M₁⁺ and forms, upon irradiation with an actinic ray or a radiation, the first acidic moiety represented by HA₁

Structural moiety Y: a structural moiety that is constituted by an anionic moiety A₂⁻ and a cationic moiety M₂⁺ and forms, upon irradiation with an actinic ray or a radiation, the second acidic moiety represented by HA₂

The compound (I) satisfies the following condition I.

Condition I: A compound PI in which the cationic moiety M₁⁺ in the structural moiety X and the cationic moiety M₂⁺ in the structural moiety Y in the compound (I) are replaced by H⁺ has an acid dissociation constant a1 derived from an acidic moiety represented by HA₁ in which the cationic moiety M₁⁺ in the structural moiety X is replaced by H⁺, and an acid dissociation constant a2 derived from an acidic moiety represented by HA₂ in which the cationic moiety M₂⁺ in the structural moiety Y is replaced by H⁺, and the acid dissociation constant a2 is larger than the acid dissociation constant a1.

Hereinafter, the condition I will be more specifically described.

When the compound (I) is, for example, a compound that generates an acid having one first acidic moiety derived from the structural moiety X and one second acidic moiety derived from the structural moiety Y, the compound PI corresponds to a “compound having HA₁ and HA₂”.

The acid dissociation constant a1 and the acid dissociation constant a2 of the compound PI will be more specifically described as follows: in determination of the acid dissociation constants of the compound PI, the pKa at the time when the compound PI turns into a “compound having A₁⁻ and HA₂” is the acid dissociation constant a1, and the pKa at the time when the “compound having A₁⁻ and HA²” turns into a “compound having A₁⁻ and A₂⁻” is the acid dissociation constant a2.

When the compound (I) is, for example, a compound that generates an acid having two first acidic moieties derived from the structural moieties X and one second acidic moiety derived from the structural moiety Y, the compound PI corresponds to a “compound having two HA₁ and one HA₂”.

In determination of the acid dissociation constants of the compound PI, the acid dissociation constant at the time when the compound PI turns into a “compound having one A₁⁻, one HA₁, and one HA₂” and the acid dissociation constant at the time when the “compound having one A₁⁻, one HA₁, and one HA₂” turns into a “compound having two A₁⁻ and one HA₂” correspond to the above-described acid dissociation constant a1. The acid dissociation constant at the time when the “compound having two A₁⁻ and one HA₂” turns into a “compound having two A₁⁻ and A₂⁻” corresponds to the acid dissociation constant a2. In other words, when the compound PI has a plurality of acid dissociation constants derived from the acidic moieties represented by HA₁ in which the cationic moiety M₁⁺ in the structural moiety X is replaced by H⁺, the value of the acid dissociation constant a2 is larger than the largest value among the plurality of the acid dissociation constants a1. Note that, in a case where the acid dissociation constant at the time when the compound PI turns into the “compound having one A₁⁻, one HA₁, and one HA₂” is defined as aa, and the acid dissociation constant at the time when the “compound having one A₁⁻, one HA₁, and one HA₂” turns into the “compound having two A₁⁻ and one HA₂” is defined as ab, the relationship between aa and ab satisfies aa<ab.

The acid dissociation constant a1 and the acid dissociation constant a2 can be determined by the above-described method of measuring an acid dissociation constant.

The compound PI corresponds to an acid generated upon irradiation of the compound (I) with an actinic ray or a radiation.

When the compound (I) has two or more structural moieties X, the structural moieties X may be the same or different. The two or more A₁⁻ and the two or more M₁⁺ may be individually the same or different.

In the compound (I), A₁⁻ above and A₂⁻ above, and M₁⁺ above and M₂⁺ above may be individually the same or different, but A₁⁻ above and A₂⁻ above are preferably different from each other.

In the compound PI, the difference (absolute value) between the acid dissociation constant a1 (when a plurality of acid dissociation constants a1 are present, the maximum value thereof) and the acid dissociation constant a2 is preferably 0.1 or more, more preferably 0.5 or more, and still more preferably 1.0 or more. Note that the upper limit value of the difference (absolute value) between the acid dissociation constant a1 (when a plurality of acid dissociation constants a1 are present, the maximum value thereof) and the acid dissociation constant a2 is not particularly limited, but is, for example, 16 or less.

In the compound PI, the acid dissociation constant a2 is preferably 20 or less, and more preferably 15 or less. Note that the lower limit value of the acid dissociation constant a2 is preferably −4.0 or more.

In the compound PI, the acid dissociation constant a1 is preferably 2.0 or less, and more preferably 0 or less. Note that the lower limit value of the acid dissociation constant a1 is preferably −20.0 or more.

The anionic moiety A₁⁻ and the anionic moiety A₂⁻ are structural moieties including a negatively charged atom or atomic group and are, for example, structural moieties selected from the group consisting of the following formulas (AA-1) to (AA-3) and formulas (BB-1) to (BB-6).

The anionic moiety A₁⁻ is preferably an anionic moiety that can form an acidic moiety having a small acid dissociation constant, in particular, more preferably any one of the formulas (AA-1) to (AA-3), and still more preferably any one of the formulas (AA-1) and (AA-3).

The anionic moiety A₂⁻ is preferably an anionic moiety that can form an acidic moiety having a larger acid dissociation constant than the anionic moiety A₁⁻, more preferably any one of the formulas (BB-1) to (BB-6), and still more preferably any one of the formulas (BB-1) and (BB-4).

Note that, in the formulas (AA-1) to (AA-3) and the formulas (BB-1) to (BB-6) below, * represent a bonding site.

In the formula (AA-2), R^{A} represent a monovalent organic group. The monovalent organic groups represented by RA are not particularly limited, but may be, for example, a cyano group, a trifluoromethyl group, or a methanesulfonyl group.

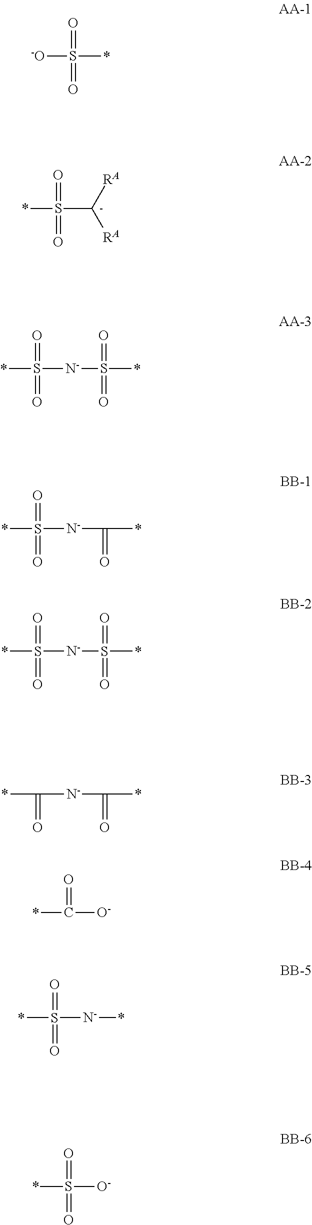

The cationic moiety M₁⁺ and the cationic moiety M₂⁺ are structural moieties including a positively charged atom or atomic group and may be, for example, singly charged organic cations. Note that such an organic cation may be, for example, the above-described organic cation represented by M⁺.

### Compound (II)

The compound (II) is a compound having two or more structural moieties X described above and one or more structural moieties Z described below, and is a compound that generates, upon irradiation with an actinic ray or a radiation, an acid including two or more first acidic moieties derived from the above-described structural moieties X and the above-described structural moiety Z.

Structural moiety Z: a nonionic moiety that can neutralize acid

In the compound (II), the definition of the structural moiety X and the definitions of A₁⁻ and M₁⁺ are the same as the definition of the structural moiety X and the definitions of A₁⁻ and M₁⁺ in the above-described compound (I), and preferred examples thereof are also the same.

In a compound PII in which the cationic moiety M₁⁺ in the structural moiety X in the compound (II) is replaced by H⁺, the preferred range of the acid dissociation constant a1 derived from the acidic moiety represented by HA₁ in which the cationic moiety M₁⁺ in the structural moiety X is replaced by H⁺ is the same as in the acid dissociation constant a1 in the compound PI.

Note that, when the compound (II) is, for example, a compound that generates an acid having two first acidic moieties derived from the structural moiety X and the structural moiety Z, the compound PII corresponds to a “compound having two HA₁”. In determination of the acid dissociation constants of this compound PII, the acid dissociation constant at the time when the compound PII turns into a “compound having one A⁻ and one HA₁” and the acid dissociation constant at the time when the “compound having one A₁⁻ and one HA₁” turns into a “compound having two A₁⁻” correspond to the acid dissociation constant a1.

The acid dissociation constant a1 can be determined by the above-described method of measuring an acid dissociation constant.

The compound PII corresponds to an acid generated upon irradiation of the compound (II) with an actinic ray or a radiation.

Note that the two or more structural moieties X may be the same or different. The two or more A₁⁻ and the two or more M₁⁺ may be individually the same or different.

The nonionic moiety that can neutralize acid in the structural moiety Z is not particularly limited, and is preferably, for example, a moiety including a group that can electrostatically interact with a proton or a functional group having an electron.

Examples of the group that can electrostatically interact with a proton or the functional group having an electron include a functional group having a macrocyclic structure such as cyclic polyether, and a functional group having a nitrogen atom having an unshared electron pair that does not contribute to π-conjugation. Examples of the nitrogen atom having an unshared electron pair that does not contribute to x-conjugation include nitrogen atoms having partial structures represented by the following formulas.

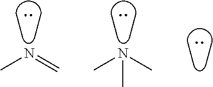

Unshared electron pair

The partial structure of the group that can electrostatically interact with a proton or the functional group having an electron may be, for example, a crown ether structure, an azacrown ether structure, a primary to tertiary amine structure, a pyridine structure, an imidazole structure, or a pyrazine structure; in particular, preferred are primary to tertiary amine structures.

Examples of the non-cationic moieties that the compound (I) and the compound (II) can have are as follows.

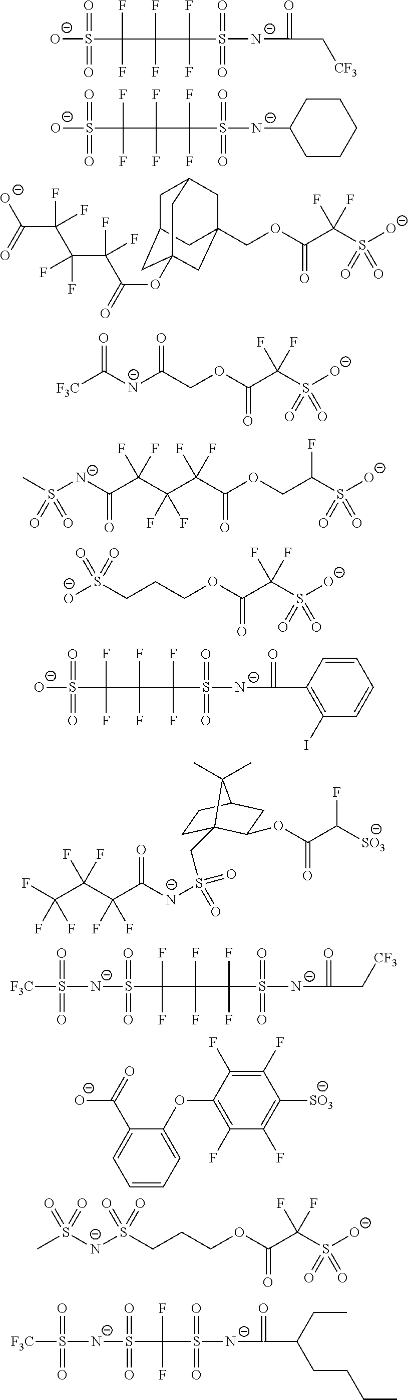

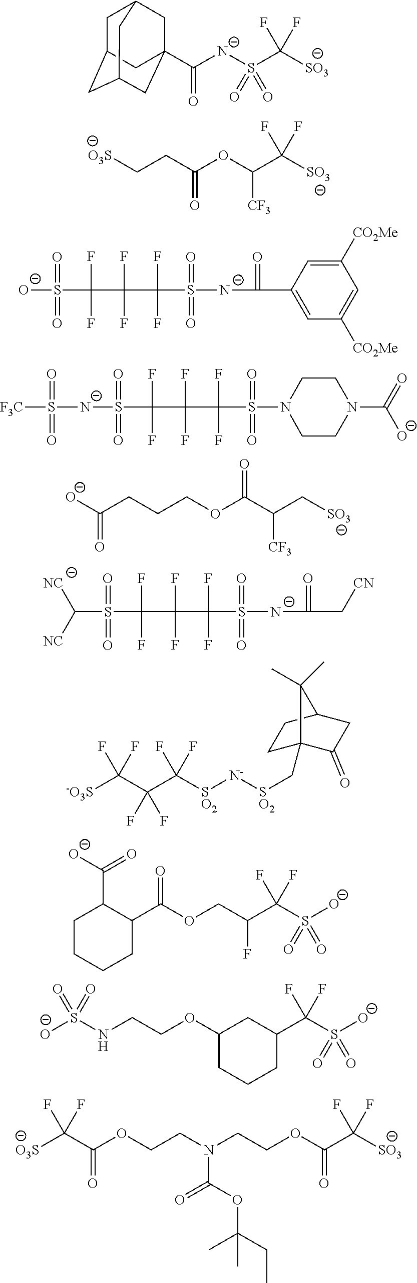

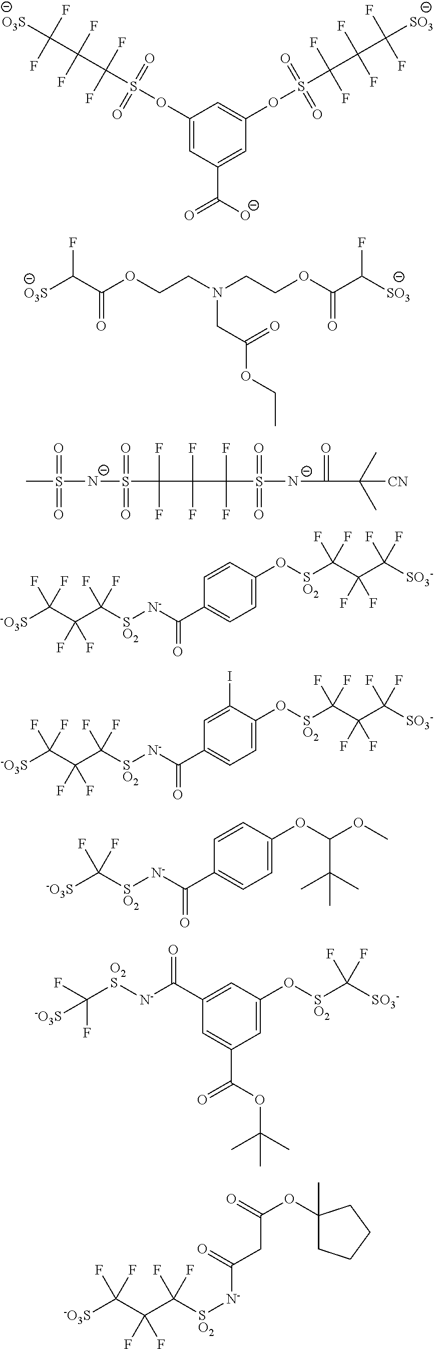

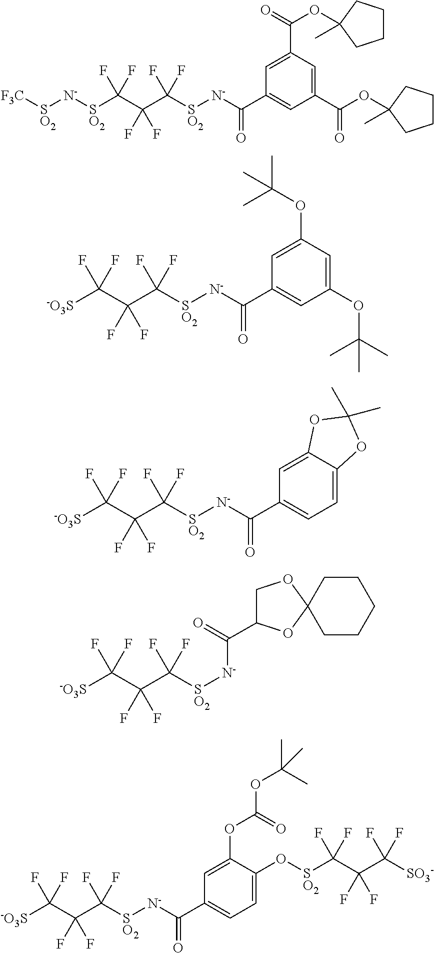

The following are non-limiting specific examples of the photoacid generator.

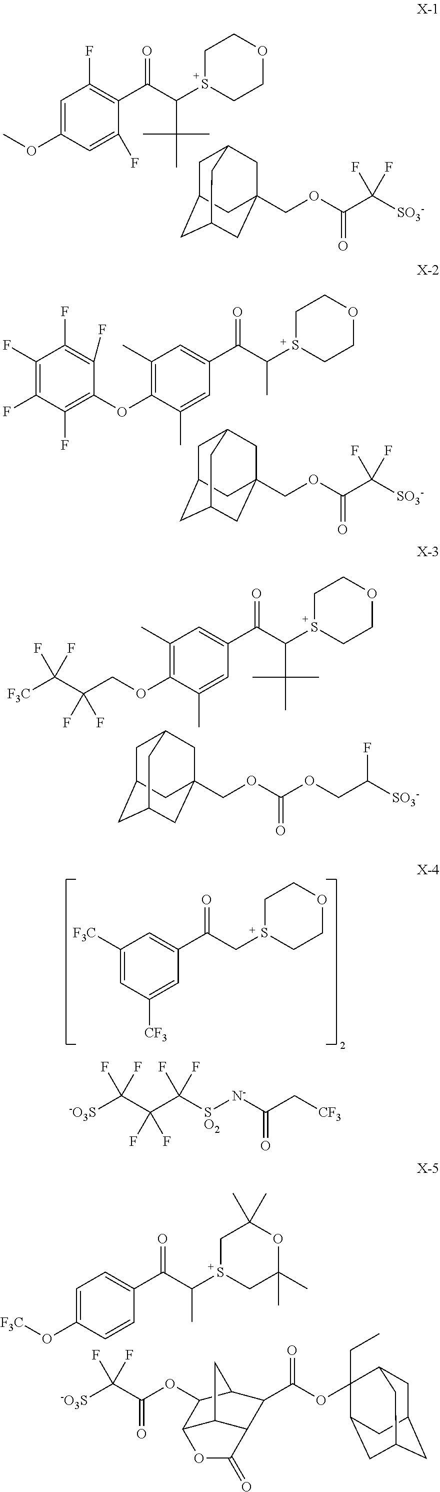

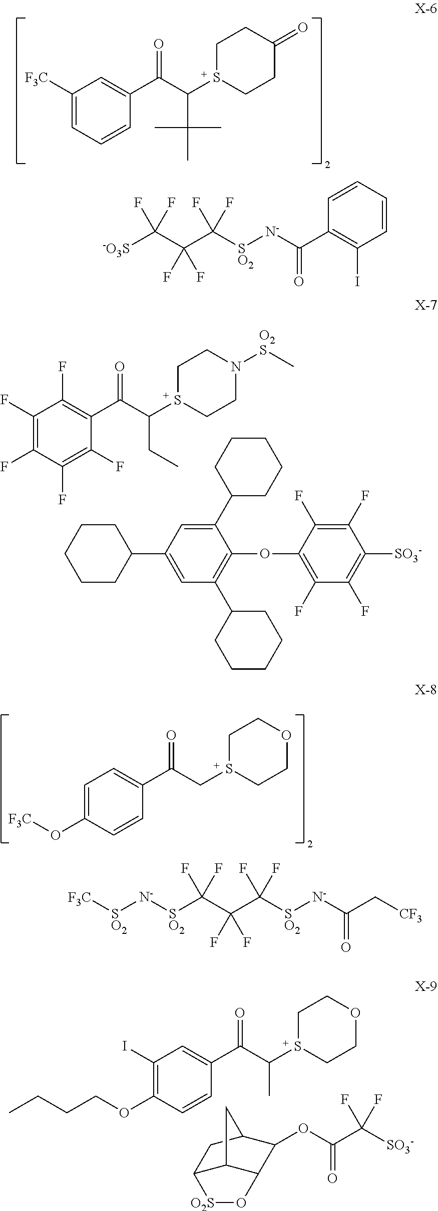

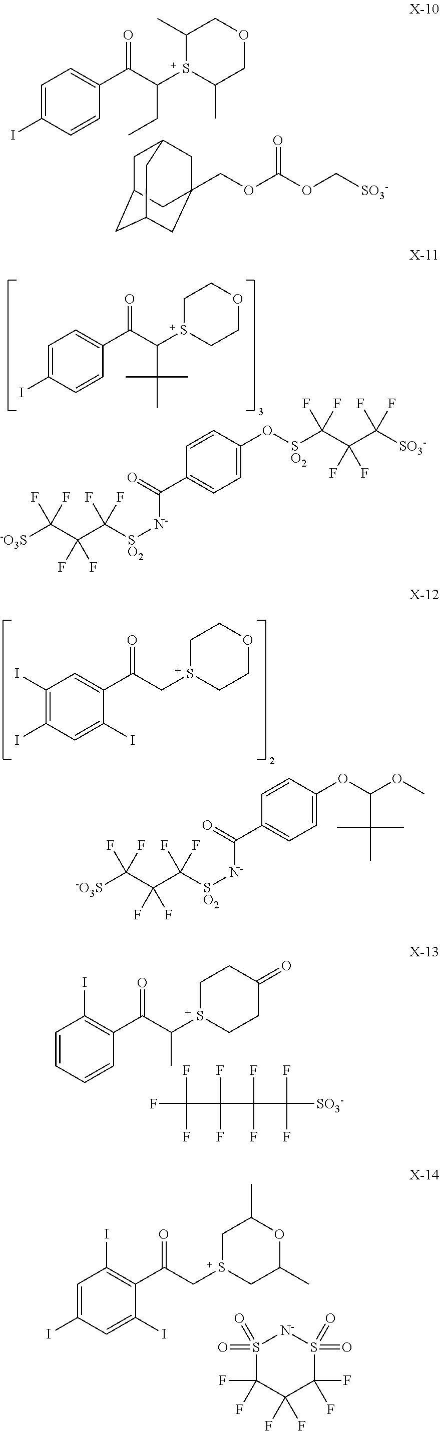

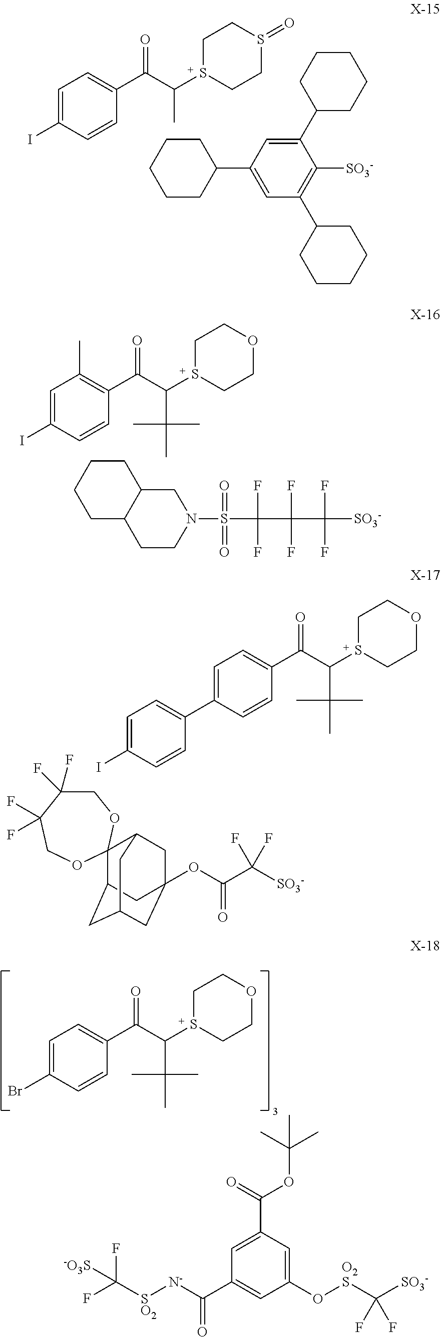

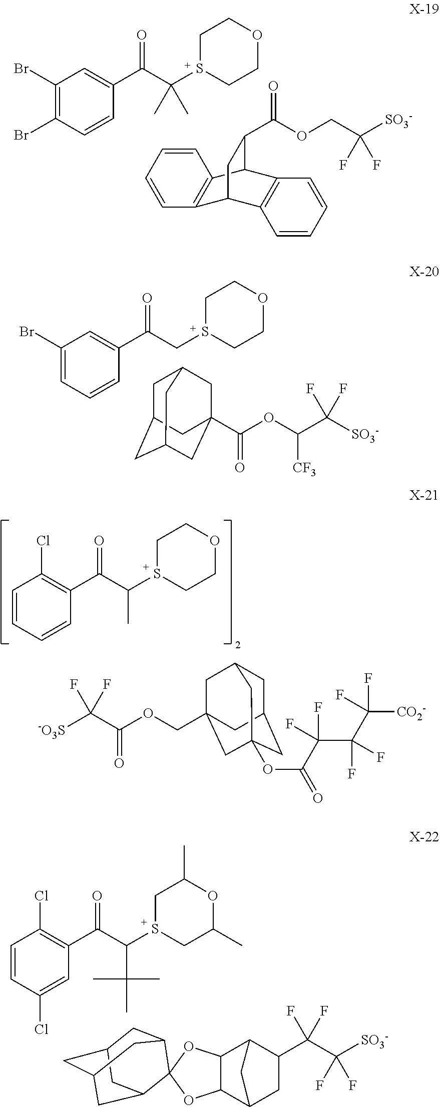

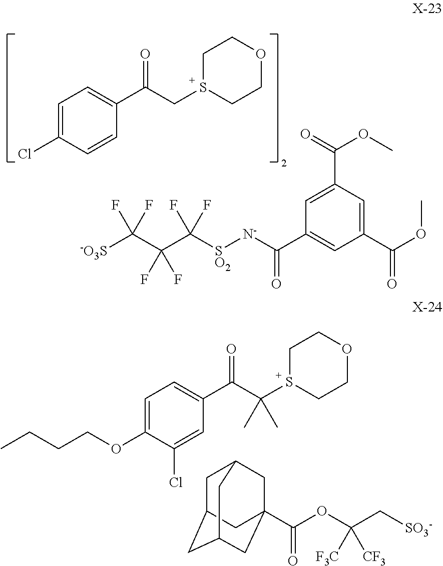

In addition, compounds B-1 to B-39 used in Examples can also be suitably used.

When the composition of the present invention includes the photoacid generator (B), the content thereof is not particularly limited, and is, from the viewpoint of forming a pattern having a more square profile, relative to the total solid content of the composition, preferably 0.5 mass % or more, and more preferably 1.0 mass % or more. The content relative to the total solid content of the composition is preferably 50.0 mass % or less, more preferably 30.0 mass % or less, and still more preferably 25.0 mass % or less.

Such photoacid generators (B) may be used alone or in combination of two or more thereof.

### Acid Diffusion Control Agent (C)

The composition of the present invention may include an acid diffusion control agent.

The acid diffusion control agent serves as a quencher that traps the acid generated from the photoacid generator or the like upon exposure and that suppresses the reaction of the acid-decomposable resin, in the unexposed region, caused by an excess of generated acid.

The type of the acid diffusion control agent is not particularly limited, and examples thereof include a basic compound (CA), a low-molecular-weight compound (CB) having a nitrogen atom and having a group that leaves by the action of an acid, and a compound (CC) whose acid diffusion control ability is reduced or lost upon irradiation with an actinic ray or a radiation.

Examples of the compound (CC) include an onium salt compound (CD) that becomes a weak acid relative to the photoacid generator, and a basic compound (CE) whose basicity is reduced or lost upon irradiation with an actinic ray or a radiation.

Specific examples of the basic compound (CA) include, for example, those described in Paragraphs [0132] to [0136] of WO2020/066824A; specific examples of the basic compound (CE) whose basicity is reduced or lost upon irradiation with an actinic ray or a radiation include those described in Paragraphs [0137] to [0155] of WO2020/066824A and those described in Paragraph [0164] of WO2020/066824A; specific examples of the low-molecular-weight compound (CB) having a nitrogen atom and having a group that leaves by the action of an acid include those described in Paragraphs [0156] to [0163] of WO2020/066824A.

Specific examples of the onium salt compound (CD) that becomes a weak acid relative to the photoacid generator include, for example, those described in Paragraphs [0305] to [0314] of WO2020/158337A.

In addition to those described above, for example, the publicly known compounds disclosed in Paragraphs [0627] to [0664] in US2016/0070167A1, Paragraphs [0095] to [0187] in US2015/0004544A1, Paragraphs [0403] to [0423] in US2016/0237190A1, and Paragraphs [0259] to [0328] in US2016/0274458A1 can be suitably used as acid diffusion control agents.

When the composition of the present invention includes an acid diffusion control agent, the content of the acid diffusion control agent (when a plurality of acid diffusion control agents are present, the total content thereof) relative to the total solid content of the composition is preferably 0.1 to 15.0 mass % and more preferably 1.0 to 15.0 mass %.

In the composition of the present invention, such acid diffusion control agents may be used alone or in combination of two or more thereof.

### Hydrophobic Resin (D)

The composition of the present invention may further include a hydrophobic resin different from the resin (A).

The hydrophobic resin is preferably designed so as to be localized in the surface of a resist film; however, unlike surfactants, the hydrophobic resin does not necessarily need to have intramolecularly a hydrophilic group, and does not necessarily contribute to homogeneous mixing of a polar substance and a nonpolar substance.

Advantages due to addition of the hydrophobic resin may be control of static and dynamic contact angles (for water) at the surface of the resist film, and suppression of outgassing.

The hydrophobic resin, from the viewpoint of localization in the surface layer of the film, preferably has one or more species, more preferably two or more species, selected from the group consisting of a fluorine atom, a silicon atom, and a CH₃ moiety included in the side chain moiety of the resin. The hydrophobic resin preferably has a hydrocarbon group having 5 or more carbon atoms. The resin may have such a group in the main chain or, as a substituent, in a side chain.

Examples of the hydrophobic resin include the compounds described in Paragraphs to in WO2020/004306A.

When the composition of the present invention includes a hydrophobic resin, the content of the hydrophobic resin relative to the total solid content of the composition is preferably 0.01 to 20.0 mass %, and more preferably 0.1 to 15.0 mass %.

### Surfactant (E)

The composition of the present invention may include a surfactant. In the case of including a surfactant, a pattern having higher adhesiveness and a less number of development defects can be formed.

The surfactant is preferably a fluorine-based and/or silicone-based surfactant.

Examples of the fluorine-based and/or silicone-based surfactant include the surfactants disclosed in Paragraphs [0218] and [0219] of WO2018/193954A.

Such surfactants may be used alone or in combination of two or more thereof.

When the composition of the present invention includes a surfactant, the surfactant content relative to the total solid content of the composition is preferably 0.0001 to 2.0 mass %, more preferably 0.0005 to 1.0 mass %, and still more preferably 0.1 to 1.0 mass %.

### Solvent (F)

The composition of the present invention preferably includes a solvent.

The solvent preferably includes at least one of (M1) a propylene glycol monoalkyl ether carboxylate or (M2) at least one selected from the group consisting of a propylene glycol monoalkyl ether, a lactate, an acetate, an alkoxypropionate, a chain ketone, a cyclic ketone, a lactone, and an alkylene carbonate. Note that the solvent may further include a component other than the components (M1) and (M2).

A combination of the above-described solvent and the above-described resin is preferred from the viewpoint of improving the coatability of the composition of the present invention and reducing the number of development defects in patterns. The above-described solvent is well-balanced in terms of solubility of the above-described resin, boiling point, and viscosity, to thereby suppress, for example, unevenness of the film thickness of the resist film and generation of deposit during spin-coating.

Details of the component (M1) and the component (M2) are described in Paragraphs [0218] to [0226] in WO2020/004306A, and these contents are incorporated herein by reference.

When the solvent further includes a component other than the components (M1) and (M2), the content of the component other than the components (M1) and (M2) relative to the total amount of the solvent is preferably 5 to 30 mass %.

The content of the solvent in the composition of the present invention is determined such that the solid-content concentration is preferably 0.5 to 30 mass %, and more preferably 1 to 20 mass %. This further improves the coatability of the composition of the present invention.

Note that the solid content means all the components other than the solvent, and, as described above, means components that form the actinic ray-sensitive or radiation-sensitive film.

The solid-content concentration is a mass percentage of the mass of other components excluding the solvent relative to the total mass of the composition of the present invention.

The “total solid content” refers to the total mass of the components excluding the solvent from all the components of the composition of the present invention. As described above, the “solid content” is components excluding the solvent, and may be a solid or may be a liquid at 25° C., for example.

### Other Additives

The composition of the present invention may further include a dissolution-inhibiting compound, a dye, a plasticizer, a photosensitizer, a light absorbent, and/or a compound that promotes solubility in a developer (for example, a phenol compound having a molecular weight of 1000 or less, or an alicyclic or aliphatic compound including a carboxyl group).

The “dissolution-inhibiting compound” is a compound that is decomposed by the action of an acid to undergo a decrease in the degree of solubility in organic-based developers, and has a molecular weight of 3000 or less.

The resist composition of this Specification is suitably used as a photosensitive composition for EB exposure or a photosensitive composition for EUV exposure.

The EUV light has a wavelength of 13.5 nm, which is a shorter wavelength than in the ArF (having a wavelength of 193 nm) light and the like, and hence provides, upon exposure at the same sensitivity, a smaller number of incident photons. Thus, “photon shot noise”, which is random variations in the number of photons, exerts a strong effect, which leads to degradation of LER and bridge defects. In order to reduce the photon shot noise, a method of increasing the exposure dose to increase the number of incident photons may be employed; however, there is a tradeoff between this method and the demand for an increase in the sensitivity.

### Actinic Ray-Sensitive or Radiation-Sensitive Film and Pattern Forming Method

The procedures of the pattern forming method using the above-described composition are not particularly limited, but preferably have the following steps.
Step 1: a step of using the actinic ray-sensitive or radiation-sensitive resin composition to form an actinic ray-sensitive or radiation-sensitive film on a substrate
Step 2: a step of exposing the actinic ray-sensitive or radiation-sensitive film
Step 3: a step of developing the exposed actinic ray-sensitive or radiation-sensitive film using a developer

Hereinafter, procedures of the steps will be individually described in detail.

### Step 1: Actinic Ray-Sensitive or Radiation-Sensitive Film Formation Step

The step 1 is a step of using the actinic ray-sensitive or radiation-sensitive resin composition to form an actinic ray-sensitive or radiation-sensitive film on a substrate.

Examples of the method of using the actinic ray-sensitive or radiation-sensitive resin composition to form an actinic ray-sensitive or radiation-sensitive film (preferably, a resist film) on a substrate include a method of applying the composition of the present invention onto a substrate.

Note that the composition of the present invention is preferably filtered through a filter before application as needed. The filter preferably has a pore size of 0.1 μm or less, more preferably 0.05 μm or less, and still more preferably 0.03 μm or less. The filter is preferably formed of polytetrafluoroethylene, polyethylene, or nylon.

The composition of the present invention can be applied onto a substrate (such as a silicon, silicon dioxide-coated substrate) used in the production of an integrated circuit element, by an appropriate application process using a spinner, a coater, or the like. The application process is preferably spin-coating using a spinner. The spin-coating using a spinner is preferably performed at a rotation rate of 1000 to 3000 rpm.

After application of the composition of the present invention, the substrate may be dried to form an actinic ray-sensitive or radiation-sensitive film. Note that, as needed, as underlayers of the actinic ray-sensitive or radiation-sensitive film, various underlying films (an inorganic film, an organic film, or an antireflection film) may be formed.

The drying process may be, for example, a process of performing heating to achieve drying. The heating can be performed using means included in an ordinary exposure device and/or an ordinary development device, or may alternatively be performed using a hot plate, for example. The heating temperature is preferably 80 to 150° C., more preferably 80 to 140° C., and still more preferably 80 to 130° C. The heating time is preferably 30 to 1000 seconds, more preferably 60 to 800 seconds, and still more preferably 60 to 600 seconds.

The film thickness of the actinic ray-sensitive or radiation-sensitive film is not particularly limited, but is, from the viewpoint of enabling formation of more precise fine patterns, preferably 10 to 120 nm. In particular, in the case of employing EUV exposure, the film thickness of the actinic ray-sensitive or radiation-sensitive film is more preferably 10 to 65 nm, and still more preferably 15 to 50 nm. In the case of employing ArF liquid immersion exposure, the film thickness of the actinic ray-sensitive or radiation-sensitive film is more preferably 10 to 120 nm, and still more preferably 15 to 90 nm.

Note that, for an overlying layer of the actinic ray-sensitive or radiation-sensitive film, a topcoat composition may be used to form a topcoat.

The topcoat composition preferably does not mix with the actinic ray-sensitive or radiation-sensitive film, and can further be uniformly applied for an overlying layer of the actinic ray-sensitive or radiation-sensitive film. The topcoat is not particularly limited; a publicly known topcoat can be formed by a publicly known process; for example, on the basis of descriptions of Paragraphs [0072] to [0082] in JP2014-059543A, a topcoat can be formed.

For example, a topcoat including a basic compound and described in JP2013-61648A is preferably formed on the actinic ray-sensitive or radiation-sensitive film. Specific examples of the basic compound that can be included in the topcoat include basic compounds that may be included in the resist composition.

The topcoat also preferably includes a compound including at least one group or bond selected from the group consisting of an ether bond, a thioether bond, a hydroxy group, a thiol group, a carbonyl bond, and an ester bond.

### Step 2: Exposure Step

The step 2 is a step of exposing the actinic ray-sensitive or radiation-sensitive film.

The exposure process may be a process of irradiating the formed actinic ray-sensitive or radiation-sensitive film, through a predetermined mask, with an actinic ray or a radiation.

Examples of the actinic ray or the radiation include infrared light, visible light, ultraviolet light, far-ultraviolet light, extreme ultraviolet light, X-rays, and an electron beam; preferred is 250 nm or less, more preferred is 220 nm or less, and particularly preferred are far-ultraviolet light having a wavelength of 1 to 200 nm and specifically KrF excimer laser (248 nm), ArF excimer laser (193 nm), F₂ excimer laser (157 nm), EUV (13.5 nm), X-rays, and an electron beam.

After the exposure, before development, baking (heating) is preferably performed. The baking accelerates the reaction in the exposed regions, to provide higher sensitivity and a better pattern profile.

The heating temperature is preferably 80 to 150° C., more preferably 80 to 140° C., and still more preferably 80 to 130° C.

The heating time is preferably 10 to 1000 seconds, more preferably 10 to 180 seconds, and still more preferably 30 to 120 seconds.

The heating can be performed using means included in an ordinary exposure device and/or an ordinary development device, and may alternatively be performed using a hot plate, for example.

This step is also referred to as post-exposure baking.

### Step 3: Development Step

The step 3 is a step of using a developer to develop the exposed actinic ray-sensitive or radiation-sensitive film, to form a pattern.

The developer may be an alkali developer or may be a developer containing an organic solvent (hereafter, also referred to as organic-based developer).

Examples of the development process include a process of immersing, for a predetermined time, the substrate in a tank filled with the developer (dipping process), a process of puddling, with the developer, the surface of the substrate using surface tension and leaving the developer at rest for a predetermined time to achieve development (puddling process), a process of spraying the developer to the surface of the substrate (spraying process), and a process of scanning, at a constant rate, over the substrate rotated at a constant rate, a developer ejection nozzle to continuously eject the developer (dynamic dispensing process).

After the step of performing development, a step of performing exchange with another solvent to stop the development may be performed.

The development time is not particularly limited as long as the resin in the unexposed regions is sufficiently dissolved in the time, and is preferably 10 to 300 seconds, and more preferably 20 to 120 seconds.

The temperature of the developer is preferably 0 to 50° C., and more preferably 15 to 35° C.

The alkali developer employed is preferably an alkali aqueous solution including an alkali. The type of the alkali aqueous solution is not particularly limited, but may be, for example, an alkali aqueous solution including a quaternary ammonium salt represented by tetramethylammonium hydroxide, an inorganic alkali, a primary amine, a secondary amine, a tertiary amine, an alcoholamine, a cyclic amine, or the like. In particular, the alkali developer is preferably an aqueous solution of a quaternary ammonium salt represented by tetramethylammonium hydroxide (TMAH). To the alkali developer, an appropriate amount of an alcohol, a surfactant, or the like may be added. The alkali developer ordinarily preferably has an alkali concentration of 0.1 to 20 mass %. The alkali developer ordinarily preferably has a pH of 10.0 to 15.0.

The organic-based developer is preferably a developer containing at least one organic solvent selected from the group consisting of ketone-based solvents, ester-based solvents, alcohol-based solvents, amide-based solvents, ether-based solvents, and hydrocarbon-based solvents.

A plurality of such solvents may be mixed together, or such a solvent may be mixed with a solvent other than those described above or water. The developer as a whole has a moisture content of preferably less than 50 mass %, more preferably less than 20 mass %, still more preferably less than 10 mass %, and particularly preferably contains substantially no moisture.

In the organic-based developer, the content of the organic solvent relative to the total amount of the developer is preferably 50 mass % or more and 100 mass % or less, more preferably 80 mass % or more and 100 mass % or less, still more preferably 90 mass % or more and 100 mass % or less, and particularly preferably 95 mass % or more and 100 mass % or less.

### Other Step

The pattern forming method preferably includes a step of, after the step 3, using a rinse liquid to perform rinsing.

After the development step using an alkali developer, in the rinsing step, the rinse liquid employed may be, for example, pure water. Note that, to the pure water, an appropriate amount of surfactant may be added.

To the rinse liquid, an appropriate amount of surfactant may be added.

After the development step using an organic-based developer, in the rinsing step, the rinse liquid employed is not particularly limited as long as it does not dissolve the pattern, and may be a solution including an ordinary organic solvent. The rinse liquid employed is preferably a rinse liquid containing at least one organic solvent selected from the group consisting of hydrocarbon-based solvents, ketone-based solvents, ester-based solvents, alcohol-based solvents, amide-based solvents, and ether-based solvents.

The process of performing the rinsing step is not particularly limited; examples include a process of continuously ejecting, onto the substrate rotated at a constant rate, the rinse liquid (spin-coating process), a process of immersing, in a tank filled with the rinse liquid, the substrate for a predetermined time (dipping process), and a process of spraying, to the surface of the substrate, the rinse liquid (spraying process).

The pattern forming method may include a heating step (Post Bake) performed after the rinsing step. In this step, baking removes the developer and the rinse liquid remaining between and within the patterns. In addition, this step also provides an effect of annealing the resist pattern to address the rough surface of the pattern. The heating step after the rinsing step is performed ordinarily at 40 to 250° C. (preferably 90 to 200° C.) for ordinarily 10 seconds to 3 minutes (preferably 30 seconds to 120 seconds).

The formed pattern may be used as a mask for subjecting the substrate to etching treatment. Specifically, the pattern formed in the step 3 may be used as a mask for processing the substrate (or the underlayer film and the substrate), to form a pattern in the substrate.

The process of processing the substrate (or the underlayer film and the substrate) is not particularly limited, but is preferably a process of using the pattern formed in the step 3 as a mask for subjecting the substrate (or the underlayer film and the substrate) to dry etching, to thereby form a pattern in the substrate. The dry etching is preferably oxygen plasma etching.

Various materials used in the composition of this Specification and the pattern forming method of this Specification (for example, a solvent, a developer, a rinse liquid, an antireflection film-forming composition, and a topcoat-forming composition) preferably do not include impurities such as metals. The content of impurities included in such materials is preferably 1 mass ppm or less, more preferably 10 mass ppb or less, still more preferably 100 mass ppt or less, particularly preferably 10 mass ppt or less, and most preferably 1 mass ppt or less. The lower limit is not particularly limited, but is preferably 0 mass ppt or more. Examples of the metallic impurities include Na, K, Ca, Fe, Cu, Mg, Al, Li, Cr, Ni, Sn, Ag, As, Au, Ba, Cd, Co, Pb, Ti, V, W, and Zn.

The process of removing, from the various materials, impurities such as metals may be, for example, filtration using a filter. The details of filtration using a filter are described in Paragraph in WO2020/004306A.

Examples of the process of reducing the amount of impurities such as metals included in the various materials include a process of selecting, as raw materials constituting the various materials, raw materials having lower metal content, a process of subjecting raw materials constituting the various materials to filtration using a filter, and a process of performing distillation under conditions under which contamination is minimized by, for example, lining the interior of the apparatuses with TEFLON (registered trademark).

Instead of the filtration using a filter, an adsorption material may be used to remove impurities; alternatively, the filtration using a filter may be used in combination with an adsorption material. Such adsorption materials can be publicly known adsorption materials, and examples include inorganic-based adsorption materials such as silica gel and zeolite, and organic-based adsorption materials such as active carbon. In order to reduce the amount of impurities such as metals included in the various materials, ingress of metallic impurities in the production steps needs to be prevented. Whether or not metallic impurities are sufficiently removed from the production apparatuses can be determined by measuring the content of metallic components included in the washing liquid having been used for washing the production apparatuses. The content of metallic components included in the washing liquid having been used is preferably 100 mass ppt (parts per trillion) or less, more preferably 10 mass ppt or less, and still more preferably 1 mass ppt or less. The lower limit is not particularly limited, but is preferably 0 mass ppt or more.

To organic-based treatment liquids such as the rinse liquid, in order to prevent electrostatic buildup and the subsequent electrostatic discharge causing failure of the chemical solution pipe and various parts (such as a filter, an O-ring, and a tube), a conductive compound may be added. The conductive compound is not particularly limited, but may be, for example, methanol. The amount of addition is not particularly limited, but is, from the viewpoint of maintaining preferred development performance or rinsing performance, preferably 10 mass % or less, and more preferably 5 mass % or less. The lower limit is not particularly limited, but is preferably 0.01 mass % or more.

Examples of the chemical solution pipe include various pipes formed of SUS (stainless steel), or coated with polyethylene, polypropylene, or a fluororesin (such as polytetrafluoroethylene or a perfluoroalkoxy resin) treated so as to be antistatic. Similarly for the filter and the O-ring, polyethylene, polypropylene, or a fluororesin (such as polytetrafluoroethylene or a perfluoroalkoxy resin) treated so as to be antistatic can be used.

### Method for Producing Electronic Device

This Specification also relates to a method for producing an electronic device, the method including the above-described pattern forming method, and an electronic device produced by the production method.

The electronic device in this Specification is, in a preferred embodiment, mounted on electric or electronic devices (such as household appliances, OA (Office Automation), media-related devices, optical devices, and communication devices).

### Compound Represented by Formula (2) or (3)

The present invention also relates to a compound represented by the above-described formula (2) or (3). Preferred examples of the substituents of the compound represented by the formula (2) or (3) and preferred specific examples of the compound are as described above.

### Production Method

The compound represented by the formula (2) is not particularly limited in terms of the production method, but can be obtained by, for example, in the following manner: to a solution including a starting monomer having a phenolic hydroxy group before being protected by a structure represented by the formula (1) described above, a compound represented by the formula (1a) described below is added in the presence of a basic compound, and they are caused to react.

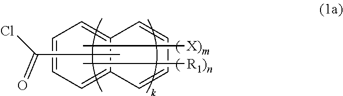

In the formula (1a), X, R₁, k, n, and m have the same definitions as X, R₁, k, n, and m in the formula (1).

Examples of the basic compound include 4-dimethylaminopyridine and triethylamine.

The reaction time is not particularly limited, and is preferably 1 to 12 hours. The reaction temperature is preferably 0 to 80° C.

The method for producing the compound represented by the formula (3) is not particularly limited, but may be, for example, as follows: to a solution of an acenaphthene compound having a phenolic hydroxy group, the compound represented by the above-described formula (1a) is added in the presence of a basic compound; they are caused to react to thereby obtain an acenaphthene compound having a partial structure in which the phenolic hydroxy group is protected by the structure represented by the formula (1); the acenaphthene compound is subjected to a halogenation reaction into a 1,2-dihalogenated acenaphthylene compound, and subsequently to dehalogenation into an acenaphthylene compound.

Examples of the basic compound include 4-dimethylaminopyridine and triethylamine.

The reaction time of the acenaphthene compound and the compound represented by the formula (1a) is not particularly limited, and is preferably 1 to 12 hours. The reaction temperature is preferably 0 to 80° C.

In the halogenation reaction, examples of the halogenating agent include N-bromosuccinimide, bromine, N-iodosuccinimide, iodine, N-chlorosuccinimide, and chlorine.

The reaction time of the halogenation reaction is not particularly limited, and is preferably 1 to 12 hours. The reaction temperature is preferably 0 to 130° C.

In the dehalogenation, examples of the dehalogenating agent include potassium iodide and Zn (zinc).

The reaction time of the dehalogenation reaction is not particularly limited, and is preferably 1 to 12 hours. The reaction temperature is preferably 0 to 130° C.

Resin Containing Repeating Unit Derived from Monomer Represented by Formula (2) or (3)

The present invention also relates to a resin containing a repeating unit derived from the monomer represented by the above-described formula (2) or (3). Preferred examples of the substituents of the monomer represented by the formula (2) or (3) and preferred examples of the compound are as described above. In the resin containing a repeating unit derived from the monomer represented by the formula (2) or (3), examples of the other repeating unit include the above-described repeating units other than the repeating unit (a1) in the section of the resin (A) described above, and preferred examples thereof are also the same.

### Production Method

The resin containing a repeating unit derived from the monomer represented by the formula (2) or (3) is not particularly limited in terms of the production method, and a publicly known production method can be employed. Examples of the production (synthesis) method include a radical polymerization method. Examples of the radical polymerization method include a batch polymerization method in which monomer species, an initiator, and the like are dissolved in a solvent and heated to cause polymerization, and a dropwise polymerization method in which a solution of monomer species and an initiator is added dropwise to a heated solvent over 1 to 10 hours; preferred is the dropwise polymerization method.

For the monomer species, the monomer represented by the formula (2) or (3) is essentially used and, as needed, other starting monomers may be used, such as the monomer represented by any one of the above-described formulas (4) to (6).

Examples of the reaction solvent include ethers such as tetrahydrofuran, 1,4-dioxane, and diisopropyl ether; ketones such as methyl ethyl ketone and methyl isobutyl ketone; esters such as ethyl acetate; amides such as dimethylformamide and dimethylacetamide; propylene glycol monomethyl ether acetate, propylene glycol monomethyl ether, and cyclohexanone.

The polymerization reaction is preferably performed in an atmosphere of an inert gas such as nitrogen and/or argon. For the polymerization initiator, a commercially available radical initiator (such as an azo-based initiator and a peroxide) can be used. The radical initiator is preferably an azo-based initiator, and more preferably an azo-based initiator having an ester group, a cyano group, or a carboxyl group. Specific examples of the polymerization initiator include azobisisobutyronitrile, azobisdimethylvaleronitrile, and dimethyl 2,2′-azobis(2-methylpropionate). As needed, a polymerization initiator is added additionally or added in portions and, after the reaction is complete, the resin is recovered. The concentration of the reaction product is preferably 5 to 50 mass %, and more preferably 10 to 30 mass %. The reaction temperature is not particularly limited, and is ordinarily preferably 10 to 150° C., more preferably 30 to 120° C., and still more preferably 60 to 100° C.

The purification method may be an ordinary method such as a purification method in a solution state such as a liquid extraction method in which washing with water and/or a combination of appropriate solvents is used to remove residual monomers and/or oligomers or ultrafiltration in which compounds having a specified molecular weight or less are extracted and removed; and a purification method in a solid state such as a reprecipitation method in which a solution containing the resin precursor is added dropwise to a poor solvent to solidify the resin precursor in the poor solvent to thereby remove the residual monomers and the like or washing, with a poor solvent, a resin slurry isolated by filtration.

### EXAMPLES

Hereinafter, the present invention will be described further in detail with reference to Examples. In the following Examples, materials, usage amounts, ratios, details of treatments, orders of treatments, and the like can be appropriately changed without departing from the spirit and scope of the present invention. Thus, the scope of the present invention should not be construed as being limited to the following Examples.

### Synthesis Example 1: Synthesis of Monomer M-80

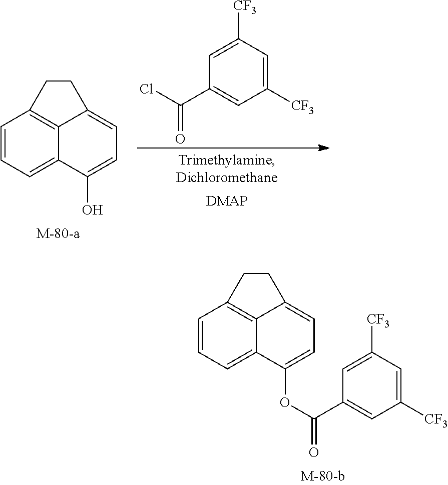 [SMILES: Oc1ccc2c3c(cccc13)CC2 ; O=C(Cl)c1cc(C(F)(F)F)cc(C(F)(F)F)c1 ; O=C(Oc1ccc2c3c(cccc13)CC2)c1cc(C(F)(F)F)cc(C(F)(F)F)c1]

M-80-a (15.0 g), triethylamine (18.7 g), and 4-dimethylaminopyridine (DMAP) (0.11 g) were dissolved in methylene chloride (dichloromethane) (300.0 g). The reaction solution was cooled in an ice bath and subsequently 3,5-bis(trifluoromethyl)benzoyl chloride (26.6 g) was added. The mixed solution was stirred at room temperature (25° C.) for 2 hours; subsequently water (100 g) was added and the solvent was distilled off from the organic layer to thereby obtain M-80-b (35.7 g, yield: 99%).

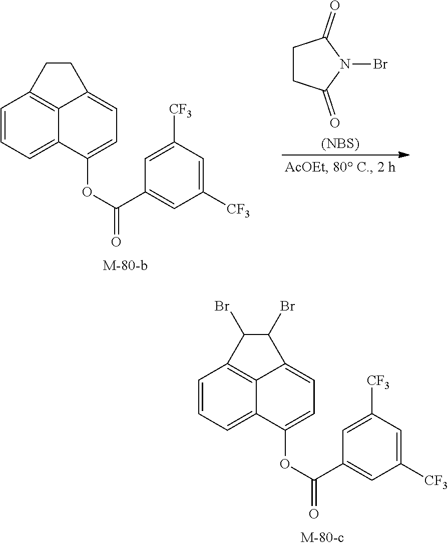

M-80-b (10.0 g) and N-bromosuccinimide (NBS) (11.7 g) were dissolved in ethyl acetate (AcOEt) (80.0 g). The mixed solution was stirred at 80° C. for 2 hours, subsequently diluted with ethyl acetate (200 mL), and washed with a saturated aqueous sodium bicarbonate solution (150 mL) and distilled water (150 mL). The solvent was distilled off from the organic layer to thereby obtain M-80-c (17.4 g) (yield: 99%).

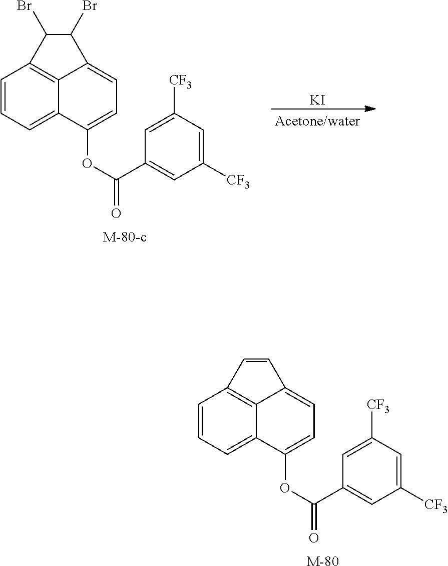

To acetone (300.0 g), M-80-c (17.4 g) and a 1.2 mol/L aqueous potassium iodide solution (130 mL) were added. The mixed solution was stirred for 2 hours and subsequently ethyl acetate (300 mL) was added; the organic layer was washed with water (300 mL) and the solvent was distilled off. The crude product was recrystallized from methanol to thereby obtain a monomer M-80 (7.6 g) (yield: 61%).

The measurement results of the monomer formula (M-80) by 1H-NMR are as follows. 1H-NMR (CDCl₃): δ=8.76 (s, 2H), 8.20 (s, 1H), 7.64-7.76 (m, 3H), 7.54 (t, 1H), 7.37 (d, 1H), 7.07 (dd, 2H)

### Synthesis Example 2: Synthesis of Monomer M-81

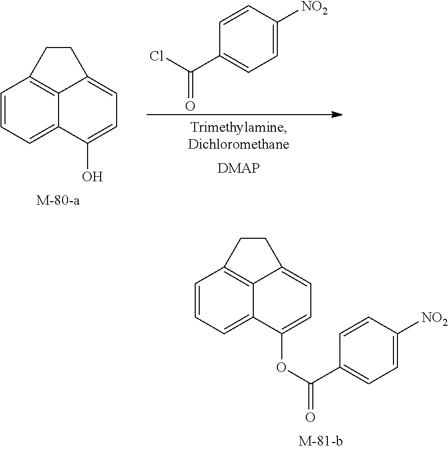 [SMILES: Oc1ccc2c3c(cccc13)CC2 ; O=C(Cl)c1ccc([N+](=O)[O-])cc1 ; O=C(Oc1ccc2c3c(cccc13)CC2)c1ccc([N+](=O)[O-])cc1]

M-80-a (15.0 g), triethylamine (18.7 g), and 4-dimethylaminopyridine (DMAP) (0.11 g) were dissolved in methylene chloride (dichloromethane) (300.0 g). The reaction solution was cooled in an ice bath, and subsequently 4-nitrobenzoyl chloride (17.2 g) was added. The mixed solution was stirred at room temperature (25° C.) for 2 hours; subsequently water (100 g) was added and the solvent was distilled off from the organic layer to thereby obtain M-81-b (27.8 g, yield: 99%).

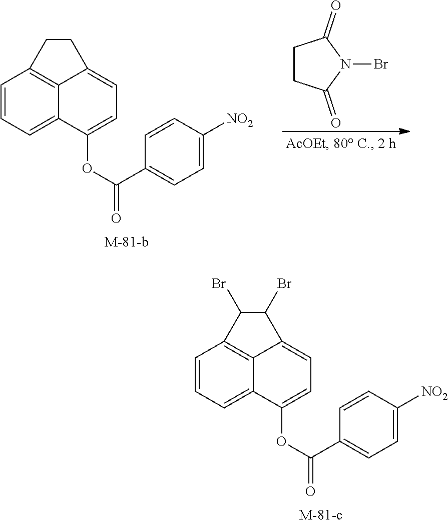 [SMILES: O=C(Oc1ccc2c3c(cccc13)CC2)c1ccc([N+](=O)[O-])cc1 ; O=C1CCC(=O)N1Br ; O=C(Oc1ccc2c3c(cccc13)C(Br)C2Br)c1ccc([N+](=O)[O-])cc1]

M-81-b (10.0 g) and N-bromosuccinimide (NBS) (11.7 g) were dissolved in ethyl acetate (AcOEt) (80.0 g). The mixed solution was stirred at 80° C. for 2 hours, subsequently diluted with ethyl acetate (200 mL), and washed with a saturated aqueous sodium bicarbonate solution (150 mL) and distilled water (150 mL). The solvent was distilled off from the organic layer to thereby obtain M-81-c (14.6 g) (yield: 99%).

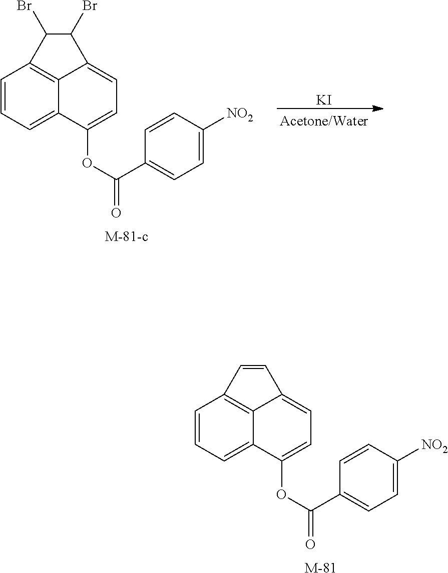

M-81-c (14.6 g) and a 1.2 mol/L aqueous potassium iodide solution (130 mL) were added to acetone (300.0 g). The mixed solution was stirred for 2 hours; subsequently ethyl acetate (300 mL) was added; the organic layer was washed with water (300 mL), and the solvent was distilled off. The crude product was recrystallized from methanol to obtain a monomer M-81 (5.9 g) (yield: 61%).

The measurement results of the monomer (M-81) by ¹H-NMR are as follows. ¹H-NMR (CDCl₃): δ=8.46-8.54 (m, 2H), 8.38-8.46 (m, 2H), 7.75 (d, 1H), 7.68 (t, 2H), 7.54 (dd, 1H), 7.39 (d, 1H), 7.07 (dd, 2H)

### Synthesis Example 3: Synthesis of Monomer M-89

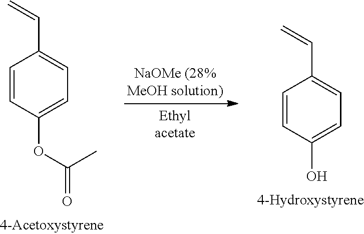

4-Acetoxystyrene (500 g) was dissolved in ethyl acetate (929 g). The reaction solution was cooled to −15° C.; subsequently a 28 mass % solution of sodium methoxide in methanol (238 g) was added. The solution was stirred at 5° C. or lower for 1 hour; subsequently, a 1 mol/L aqueous hydrochloric acid solution (800 mL) was added, and the organic layer was extracted. The organic layer was washed twice with a 1 mol/L aqueous hydrochloric acid solution (500 mL) and subsequently washed five times with distilled water (500 mL). The organic layer was concentrated to thereby obtain 730 g of a 50 mass % solution of 4-hydroxystyrene in ethyl acetate (yield: 99%).

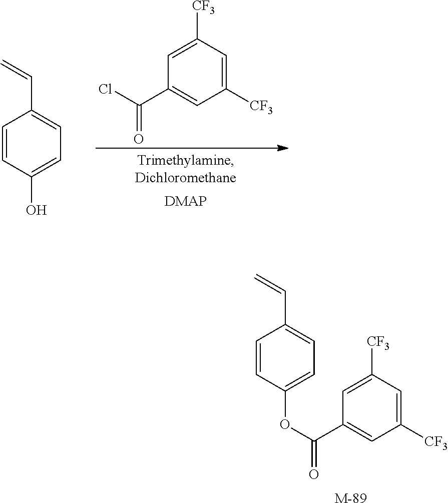

In methylene chloride (dichloromethane) (300.0 g), a 50 wt % solution of 4-hydroxystyrene in ethyl acetate (60.0 g), triethylamine (53.0 g), and 4-dimethylaminopyridine (DMAP) (0.31 g) were dissolved. The reaction solution was cooled in an ice bath, and subsequently 3,5-bis(trifluoromethyl)benzoyl chloride (72.5 g) was added. The mixed solution was stirred at room temperature (25° C.) for 2 hours; subsequently, water (100 g) was added and the solvent was distilled off from the organic layer; subsequently, column purification (developing solvent: hexane/ethyl acetate) was performed to thereby obtain M-89 (70 g, yield: 78%).

The measurement results of the monomer (M-89) by ₁H-NMR are as follows. ¹H-NMR (CDCl₃): δ=8.76 (s, 2H), 8.20 (s, 1H), 7.43-7.50 (m, 2H), 7.08-7.14 (m, 2H), 6.70 (dd, 1H), 5.70 (d, 1H), 5.23 (d, 1H)

### Synthesis Example 4: Synthesis of Resin A-1-1-a

Cyclohexanone (45 g) was heated to 85° C. under a nitrogen stream. To this liquid under stirring, a mixed solution of a monomer represented by a formula M-80 below (monomer (M-80)) (51 g), a monomer represented by a formula M-4 below (monomer (M-4)) (7 g), a monomer represented by a formula M-33 below (monomer (M-33)) (42 g), cyclohexanone (186 g), and dimethyl 2,2′-azobisisobutyrate [V-601, manufactured by Wako Pure Chemical Industries, Ltd.] (5.9 g) was added dropwise over 6 hours, to obtain a reaction solution. After the completion of the dropwise addition, the reaction solution was further stirred at 85° C. for 2 hours to obtain an A-1-1-a solution.

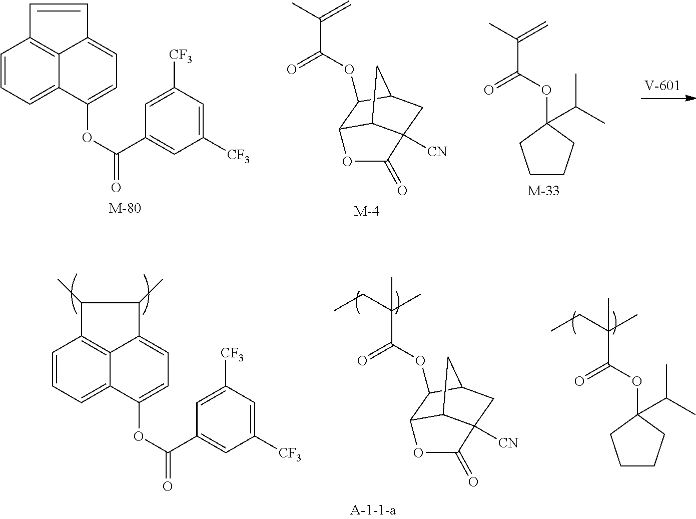

The obtained A-1-1-a solution was subjected to reprecipitation using a large amount of a heptane/ethyl acetate mixed solution and subsequently filtered; the obtained solid was vacuum-dried to thereby obtain 82 g of a resin A-1-1-a.

The compositional ratio of the repeating units (mol % ratio; sequentially described from the left) as measured by ¹³C-NMR (nuclear magnetic resonance) was 34/8/58. The weight-average molecular weight (Mw) was 6400 and the dispersity (Mw/Mn) was 1.61. The weight-average molecular weight (Mw) and the dispersity (Mw/Mn) were measured by GPC (carrier: tetrahydrofuran (THF)) (polystyrene-equivalent amounts).

### Synthesis Example 5: Synthesis of Resin A-1-2-a

Cyclohexanone (45 g) was heated to 85° C. under a nitrogen stream. To this liquid under stirring, a mixed solution of a monomer represented by a formula M-89 below (monomer (M-89)) (56 g), a monomer represented by a formula M-4 below (monomer (M-4)) (13 g), a monomer represented by a formula M-31 below (monomer (M-31)) (31 g), cyclohexanone (192 g), and dimethyl 2,2′-azobisisobutyrate [V-601, manufactured by Wako Pure Chemical Industries, Ltd.] (5.9 g) was added dropwise over 6 hours, to obtain a reaction solution. After the completion of the dropwise addition, the reaction solution was further stirred at 85° C. for 2 hours to obtain an A-1-2-a solution.

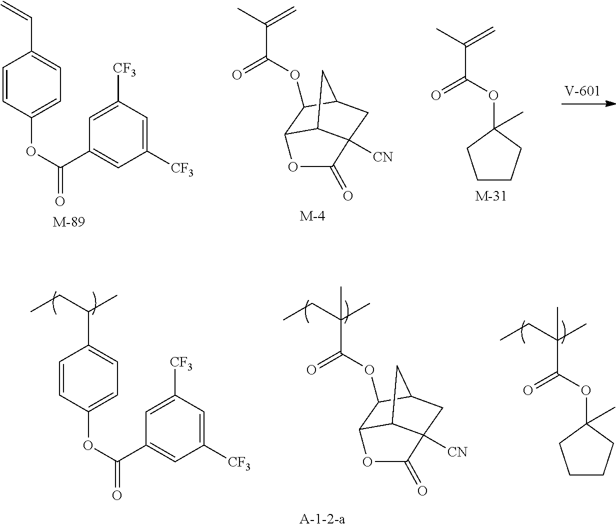

The obtained A-1-2-a solution was subjected to reprecipitation using a large amount of a heptane/ethyl acetate mixed solution and subsequently filtered; the obtained solid was vacuum-dried to thereby obtain 85 g of a resin A-1-2-a.

The compositional ratio of the repeating units (mol % ratio; sequentially described from the left) as measured by ¹³C-NMR was 40/13/47. The weight-average molecular weight (Mw) was 7100 and the dispersity (Mw/Mn) was 1.61.

### Synthesis Example 6: Synthesis of Resin A-1-3-a

Cyclohexanone (27 g) was heated to 85° C. under a nitrogen stream. To this liquid under stirring, a mixed solution of a monomer represented by a formula M-81 below (monomer (M-81)) (32 g), a monomer represented by a formula M-6 below (monomer (M-6)) (17 g), a monomer represented by a formula M-31 below (monomer (M-31)) (51 g), cyclohexanone (88 g), and dimethyl 2,2′-azobisisobutyrate [V-601, manufactured by Wako Pure Chemical Industries, Ltd.] (9.2 g) was added dropwise over 6 hours, to obtain a reaction solution. After the completion of the dropwise addition, the reaction solution was further stirred at 85° C. for 2 hours to obtain an A-1-3-a solution.

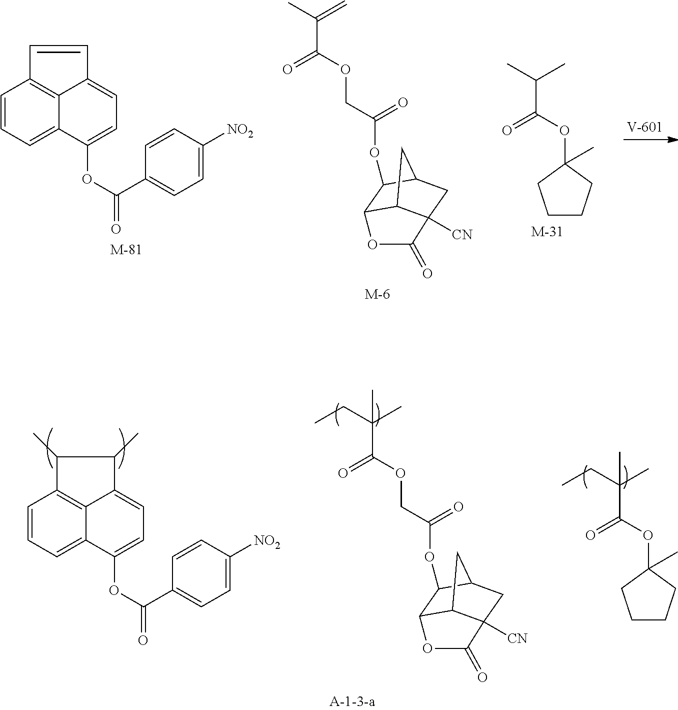

The obtained A-1-3-a solution was subjected to reprecipitation using a large amount of a heptane/ethyl acetate mixed solution and subsequently filtered; the obtained solid was vacuum-dried to thereby obtain 80 g of a resin A-1-3-a.

The compositional ratio of the repeating units (mol % ratio; sequentially described from the left) as measured by ¹³C-NMR was 22/12/66. The weight-average molecular weight (Mw) was 6900 and the dispersity (Mw/Mn) was 1.59.

### Synthesis Example 7: Synthesis of Resin A-1-4-a

Cyclohexanone (45 g) was heated to 85° C. under a nitrogen stream. To this liquid under stirring, a mixed solution of a monomer (52 g) represented by a formula M-89 below, a monomer (14 g) represented by a formula M-80 below, a monomer (34 g) represented by a formula M-31 below, cyclohexanone (170 g), and dimethyl 2,2′-azobisisobutyrate [V-601, manufactured by Wako Pure Chemical Industries, Ltd.] (5.6 g) was added dropwise over 6 hours, to obtain a reaction solution. After the completion of the dropwise addition, the reaction solution was further stirred at 85° C. for 2 hours to obtain an A-1-4-a solution.

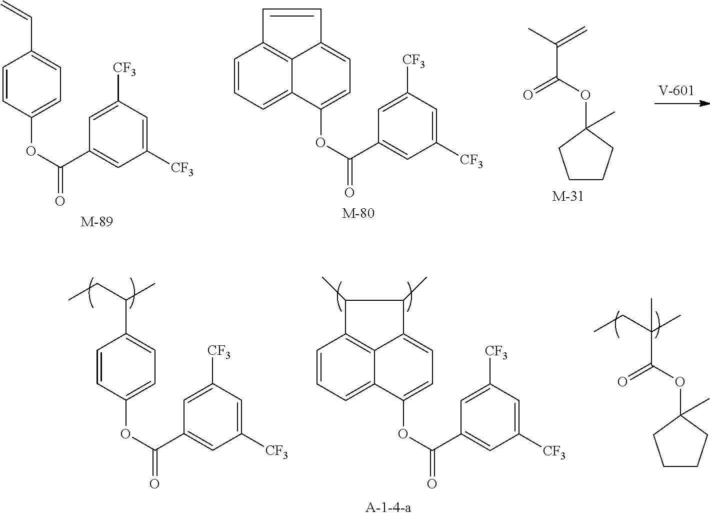

The obtained A-1-4-a solution was subjected to reprecipitation using a large amount of a heptane/ethyl acetate mixed solution and subsequently filtered; the obtained solid was vacuum-dried to thereby obtain 90 g of a resin A-1-4-a.

The compositional ratio of the repeating units (mol % ratio; sequentially described from the left) as measured by ¹³C-NMR was 38/9/53. The weight-average molecular weight (Mw) was 6500 and the dispersity (Mw/Mn) was 1.54.

### Various Components of Actinic Ray-Sensitive or Radiation-Sensitive Resin Composition

### Resin (A)

The resin (A) (resins A-1 to A-67 and A-1R to A-2R) described in Table 3 will be described below.

The resins A-1 to A-67 and A-1R to A-2R used were synthesized in accordance with the above-described method for synthesizing the resin A-1-1-a (Synthesis Example 4). Table 1 describes, for the repeating units described later, the compositional ratio (mol % ratios; sequentially described from the left), weight-average molecular weight (Mw), and dispersity (Mw/Mn).

Note that, for the resins A-1 to A-67 and A-1R to A-2R, the weight-average molecular weight (Mw) and the dispersity (Mw/Mn) were measured by GPC (carrier: tetrahydrofuran (THF)) (polystyrene-equivalent amounts). The compositional ratios (mol % ratios) of the resins were measured by ¹³C-NMR (nuclear magnetic resonance).

Note that A-1R to A-2R, which are not the resin (A), are described, for convenience, as the resin (A).

TABLE 1

| | Molar ratio of | | Molar ratio of | | Molar ratio of | | Molar ratio of | | Molar ratio of | | | |
|---|---|---|---|---|---|---|---|---|---|---|---|---|
| | repeating unit | | repeating unit | | repeating unit | | repeating unit | | repeating unit | | | |
| Table 1 | 1 | | 2 | | 3 | | 5 | | 5 | | Mw | Mw/Mn |
| Resin A-1 | M-18 | 30 | — | — | M-80 | 20 | M-31 | 50 | — | — | 6500 | 1.60 |
| Resin A-2 | — | — | M-71 | 10 | M-81 | 25 | M-32 | 40 | M-33 | 25 | 8000 | 1.54 |
| Resin A-3 | — | — | M-72 | 15 | M-82 | 15 | M-33 | 70 | — | — | 9000 | 1.67 |
| Resin A-4 | — | — | M-73 | 20 | M-83 | 20 | M-34 | 60 | — | — | 7500 | 1.55 |
| Resin A-5 | — | — | M-74 | 25 | M-84 | 20 | M-35 | 55 | — | — | 8500 | 1.59 |
| Resin A-6 | M-3 | 15 | M-75 | 30 | M-85 | 5 | M-36 | 30 | M-37 | 20 | 5500 | 1.68 |
| Resin A-7 | — | — | M-76 | 15 | M-86 | 30 | M-37 | 30 | M-38 | 25 | 4500 | 1.77 |
| Resin A-8 | M-69 | 10 | M-77 | 5 | M-87 | 35 | M-38 | 50 | — | — | 12000 | 1.84 |
| Resin A-9 | — | — | M-68 | 15 | M-88 | 25 | M-39 | 60 | — | — | 14000 | 1.65 |
| Resin A-10 | M-67 | 5 | — | — | M-89 | 40 | M-40 | 55 | — | — | 8800 | 1.55 |
| Resin A-11 | M-66 | 10 | — | — | M-90 | 30 | M-41 | 45 | M-32 | 15 | 22000 | 1.56 |
| Resin A-12 | — | — | M-1 | 35 | M-91 | 25 | M-42 | 40 | — | — | 14000 | 1.65 |
| Resin A-13 | — | — | M-2 | 5 | M-92 | 55 | M-43 | 40 | — | — | 6500 | 1.40 |
| Resin A-14 | — | — | M-3 | 15 | M-93 | 35 | M-44 | 50 | — | — | 6700 | 1.50 |
| Resin A-15 | M-70 | 30 | M-4 | 10 | M-94 | 25 | M-45 | 15 | M-41 | 20 | 7200 | 1.54 |
| Resin A-16 | — | — | M-5 | 5 | M-95 | 40 | M-46 | 25 | M-46 | 30 | 8000 | 1.29 |
| Resin A-17 | — | — | M-6 | 30 | M-96 | 10 | M-47 | 60 | — | — | 4500 | 1.35 |
| Resin A-18 | M-7 | 10 | M-78 | 20 | M-97 | 15 | M-48 | 55 | — | — | 5000 | 1.25 |
| Resin A-19 | M-8 | 25 | M-79 | 10 | M-98 | 15 | M-49 | 40 | M-40 | 10 | 5500 | 1.50 |
| Resin A-20 | M-9 | 25 | — | — | M-99 | 25 | M-50 | 50 | — | — | 5600 | 1.60 |
| Resin A-21 | M-10 | 40 | — | — | M-100 | 30 | M-51 | 10 | M-58 | 20 | 7800 | 1.56 |
| Resin A-22 | M-11 | 15 | — | — | M-101 | 25 | M-52 | 60 | — | — | 9000 | 1.54 |
| Resin A-23 | M-12 | 25 | — | — | M-80 | 25 | M-53 | 50 | — | — | 8000 | 1.74 |
| Resin A-24 | M-13 | 30 | — | — | M-81 | 15 | M-54 | 15 | M-31 | 40 | 7500 | 1.55 |
| Resin A-25 | M-14 | 40 | — | — | M-82 | 5 | M-55 | 20 | M-32 | 35 | 8600 | 1.72 |
| Resin A-26 | M-15 | 30 | — | — | M-83 | 10 | M-56 | 60 | — | — | 12500 | 1.80 |
| Resin A-27 | M-19 | 10 | M-16 | 10 | M-84 | 10 | M-57 | 70 | — | — | 5500 | 1.33 |
| Resin A-28 | M-17 | 15 | — | — | M-85 | 40 | M-58 | 45 | — | — | 4500 | 1.40 |
| Resin A-29 | M-18 | 20 | — | — | M-86 | 25 | M-59 | 55 | — | — | 6500 | 1.55 |
| Resin A-30 | M-19 | 25 | — | — | M-87 | 15 | M-60 | 60 | — | — | 6000 | 1.65 |
| Resin A-31 | M-20 | 20 | — | — | M-88 | 10 | M-61 | 70 | — | — | 5900 | 1.56 |
| Resin A-32 | M-21 | 10 | — | — | M-89 | 40 | M-62 | 50 | — | — | 8900 | 1.55 |
| Resin A-33 | M-22 | 15 | — | — | M-90 | 25 | M-63 | 60 | — | — | 12000 | 1.65 |
| Resin A-34 | M-23 | 10 | — | — | M-91 | 20 | M-64 | 70 | — | — | 8000 | 1.55 |
| Resin A-35 | M-24 | 5 | — | — | M-92 | 20 | M-65 | 75 | — | — | 14000 | 1.56 |

TABLE 2

| | Molar ratio of | | Molar ratio of | | Molar ratio of | | Molar ratio of | | Molar ratio of | | | |
|---|---|---|---|---|---|---|---|---|---|---|---|---|
| Table 1 | repeating unit | | repeating unit | | repeating unit | | repeating unit | | repeating unit | | | |
| (continued) | 1 | | 2 | | 3 | | 5 | | 5 | | Mw | Mw/Mn |
| Resin A-36 | M-25 | 5 | — | — | M-93 | 35 | M-31 | 60 | — | — | 12000 | 1.65 |
| Resin A-37 | M-26 | 10 | — | — | M-94 | 25 | M-32 | 65 | — | — | 8000 | 1.40 |
| Resin A-38 | — | — | M-27 | 15 | M-95 | 40 | M-33 | 45 | — | — | 6500 | 1.54 |
| Resin A-39 | M-28 | 35 | — | — | M-96 | 10 | M-34 | 55 | — | — | 5500 | 1.29 |
| Resin A-40 | M-29 | 10 | — | — | M-97 | 30 | M-35 | 60 | — | — | 4000 | 1.35 |
| Resin A-41 | — | — | M-30 | 10 | M-98 | 35 | M-36 | 55 | — | — | 8800 | 1.25 |
| Resin A-42 | — | — | M-1 | 20 | M-99 | 10 | M-37 | 70 | — | — | 10000 | 1.50 |
| Resin A-43 | — | — | M-2 | 15 | M-100 | 30 | M-38 | 55 | — | — | 7100 | 1.67 |
| Resin A-44 | — | — | M-3 | 15 | M-101 | 25 | M-39 | 60 | — | — | 6600 | 1.65 |
| Resin A-45 | — | — | M-4 | 30 | M-80 | 25 | M-40 | 45 | — | — | 12200 | 1.55 |
| Resin A-46 | M-19 | 20 | M-5 | 5 | M-81 | 25 | M-41 | 50 | — | — | 7700 | 1.56 |
| Resin A-47 | M-19 | 30 | M-6 | 5 | M-82 | 15 | M-42 | 50 | — | — | 6700 | 1.65 |
| Resin A-48 | M-20 | 20 | M-4 | 10 | M-83 | 20 | M-43 | 50 | — | — | 5400 | 1.40 |
| Resin A-49 | — | — | M-4 | 30 | M-84 | 20 | M-31 | 50 | — | — | 4300 | 1.54 |
| Resin A-50 | M-15 | 40 | — | — | M-85 | 5 | M-32 | 55 | — | — | 5400 | 1.29 |
| Resin A-51 | M-19 | 15 | M-1 | 5 | M-86 | 30 | M-33 | 50 | — | — | 6800 | 1.35 |
| Resin A-52 | M-22 | 15 | M-2 | 10 | M-87 | 20 | M-34 | 55 | — | — | 7100 | 1.25 |
| Resin A-53 | — | — | M-3 | 20 | M-88 | 30 | M-35 | 50 | — | — | 7400 | 1.50 |
| Resin A-54 | — | — | M-4 | 15 | M-89 | 25 | M-36 | 60 | — | — | 6900 | 1.60 |
| Resin A-55 | — | — | M-5 | 20 | M-90 | 20 | M-31 | 60 | — | — | 8500 | 1.55 |
| Resin A-56 | — | — | M-6 | 30 | M-91 | 20 | M-32 | 50 | — | — | 6500 | 1.55 |
| Resin A-57 | M-9 | 10 | — | — | M-92 | 45 | M-33 | 45 | — | — | 5500 | 1.55 |
| Resin A-58 | M-13 | 15 | — | — | M-93 | 35 | M-43 | 50 | — | — | 4000 | 1.55 |
| Resin A-59 | — | — | M-1 | 20 | M-94 | 15 | M-32 | 65 | — | — | 8800 | 1.55 |
| Resin A-60 | — | — | M-2 | 15 | M-95 | 25 | M-43 | 60 | — | — | 10000 | 1.55 |
| Resin A-61 | — | — | M-3 | 20 | M-96 | 10 | M-33 | 70 | — | — | 7100 | 1.55 |
| Resin A-62 | M-19 | 20 | M-4 | 10 | M-97 | 15 | M-31 | 55 | — | — | 6600 | 1.55 |
| Resin A-63 | — | — | M-5 | 35 | M-98 | 15 | M-32 | 50 | — | — | 12200 | 1.55 |
| Resin A-64 | — | — | M-6 | 25 | M-99 | 25 | M-33 | 50 | — | — | 7700 | 1.55 |
| Resin A-65 | M-22 | 20 | — | — | M-100 | 30 | M-33 | 50 | — | — | 6700 | 1.55 |
| Resin A-66 | M-22 | 25 | — | — | M-101 | 25 | M-33 | 50 | — | — | 6700 | 1.55 |
| Resin A-67 | M-19 | 30 | — | — | M-80 | 15 | M-31 | 55 | — | — | 6500 | 1.60 |
| Resin A-1R | M-19 | 30 | — | — | — | — | M-31 | 70 | — | — | 6500 | 1.60 |
| Resin A-2R | M-19 | 45 | — | — | — | — | M-31 | 55 | — | — | 6500 | 1.60 |

The structural formulas of the monomers described in Table 1 (monomers corresponding to the repeating units) are as follows. Me represent a methyl group.

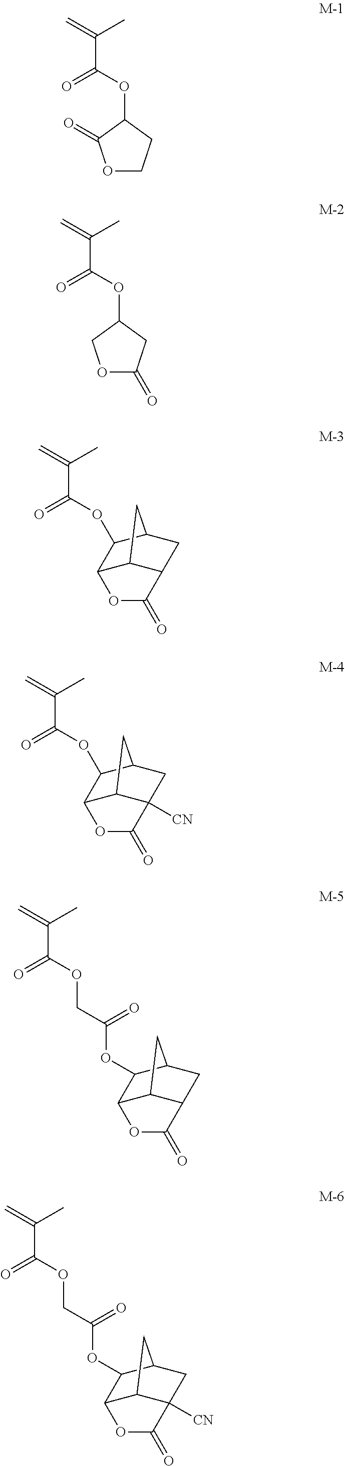

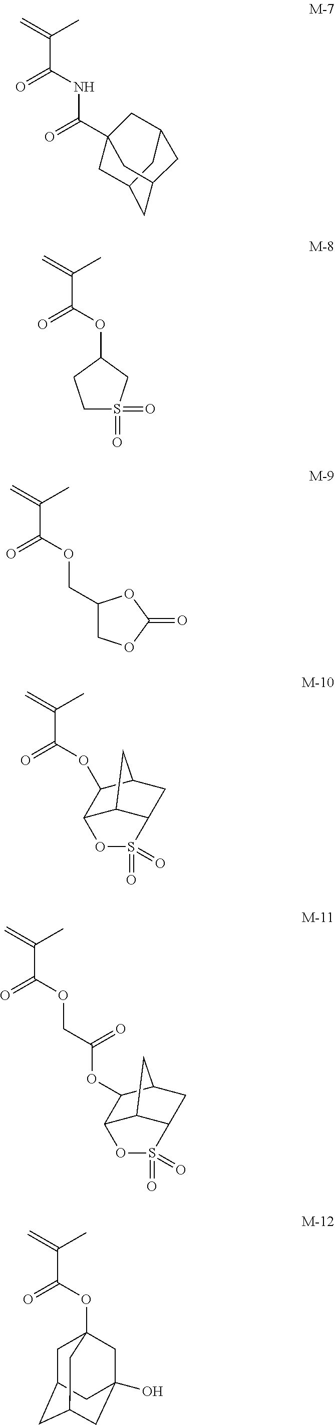

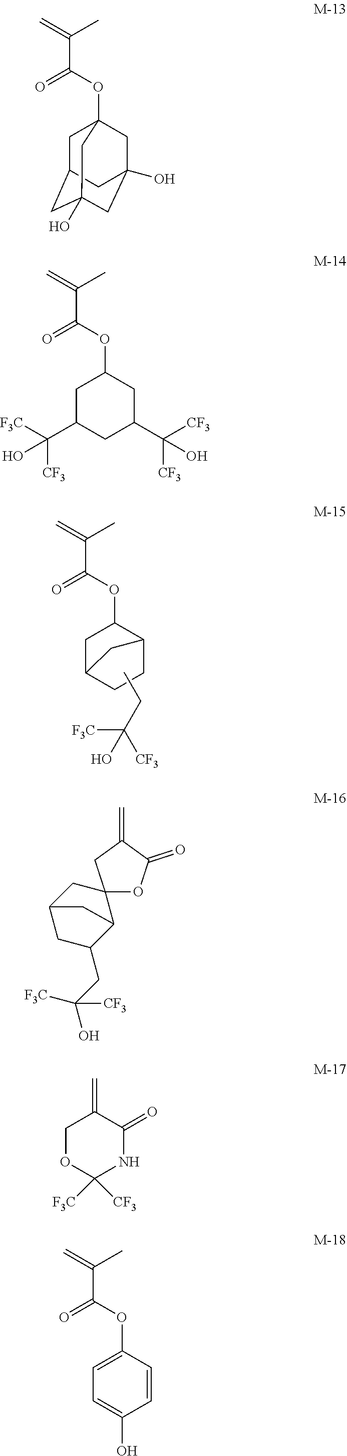

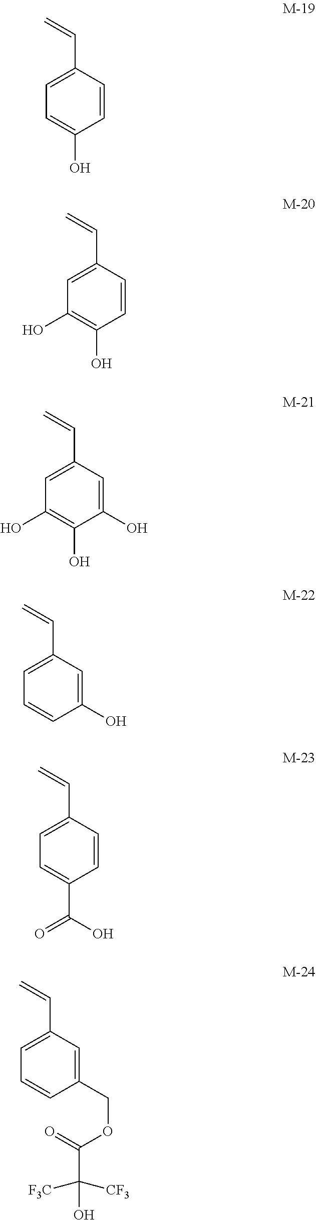

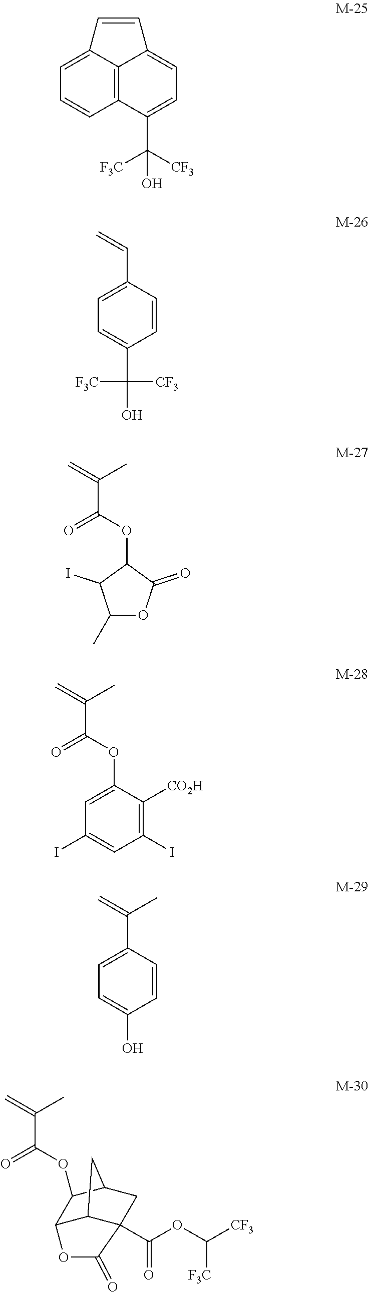

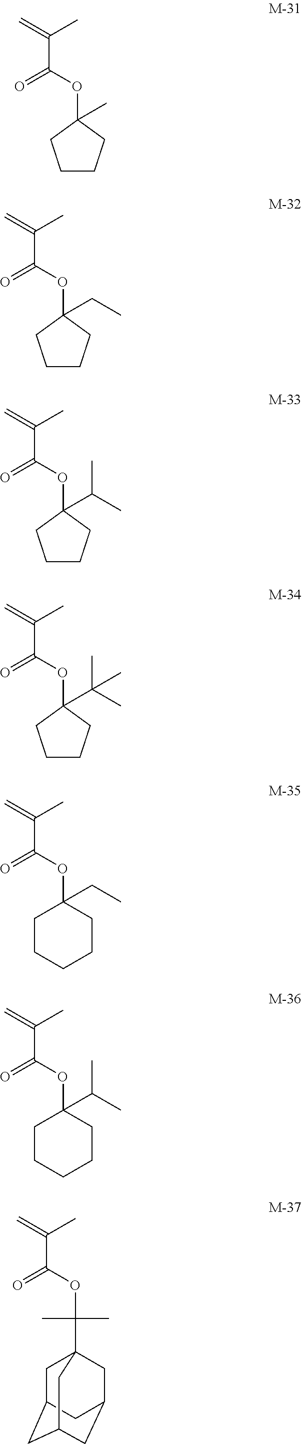

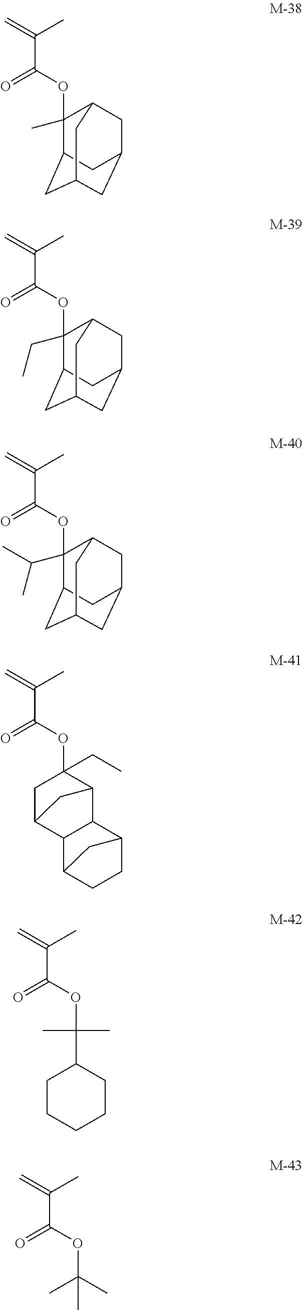

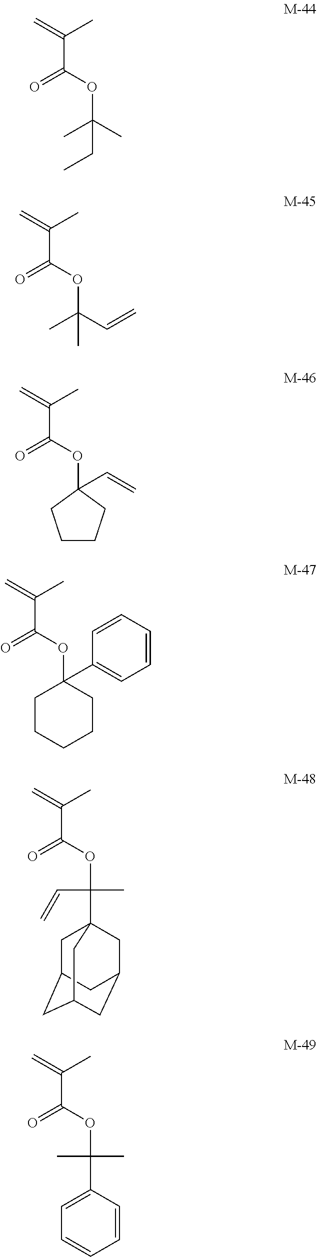

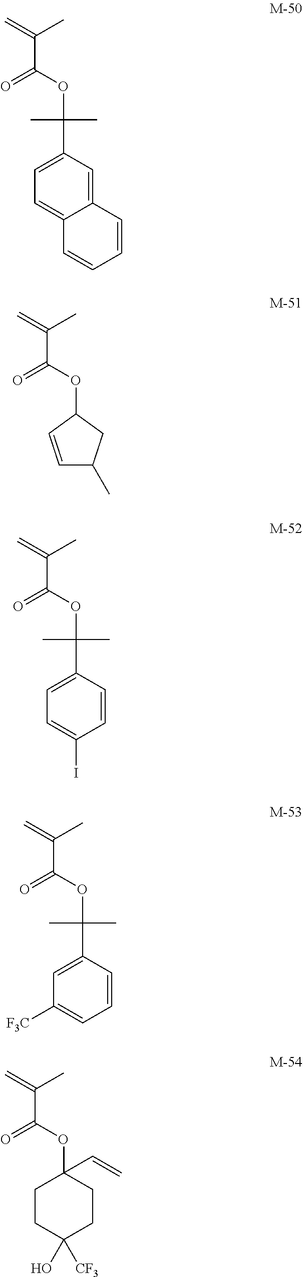

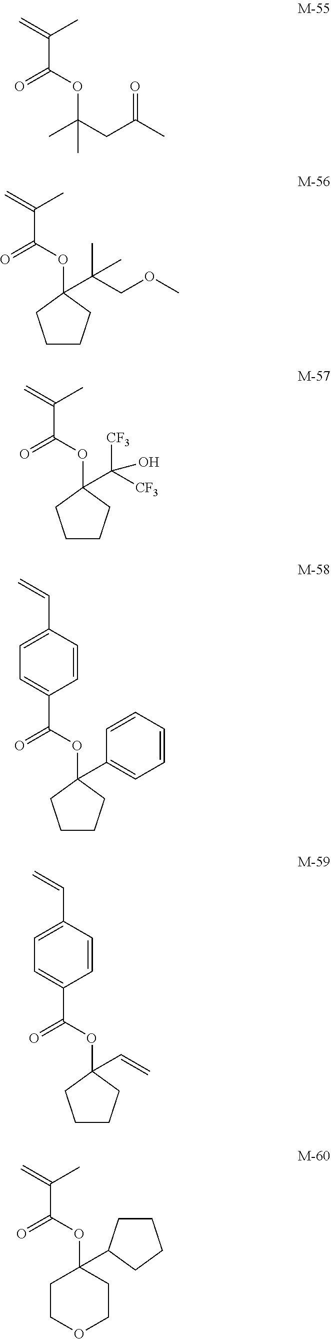

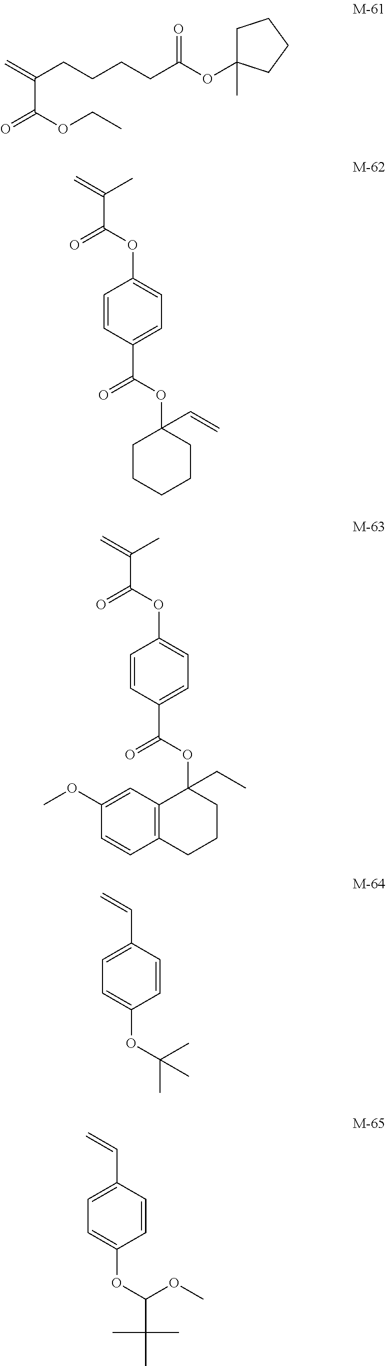

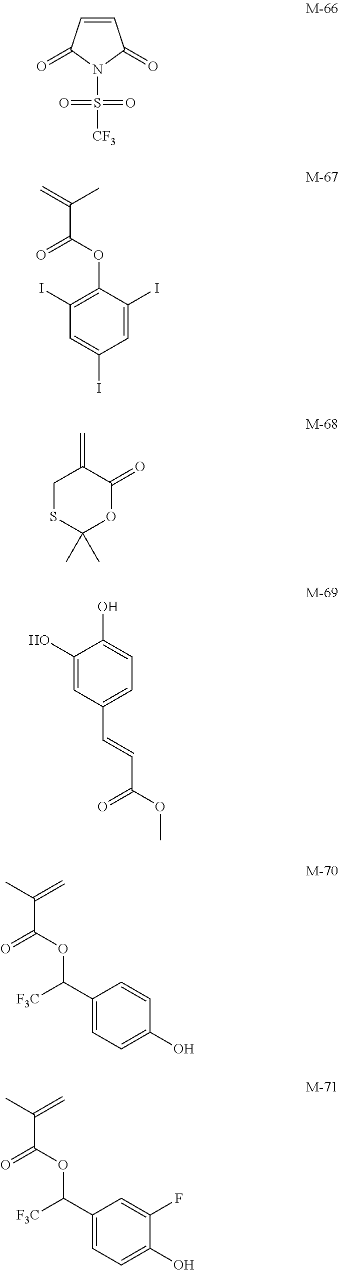

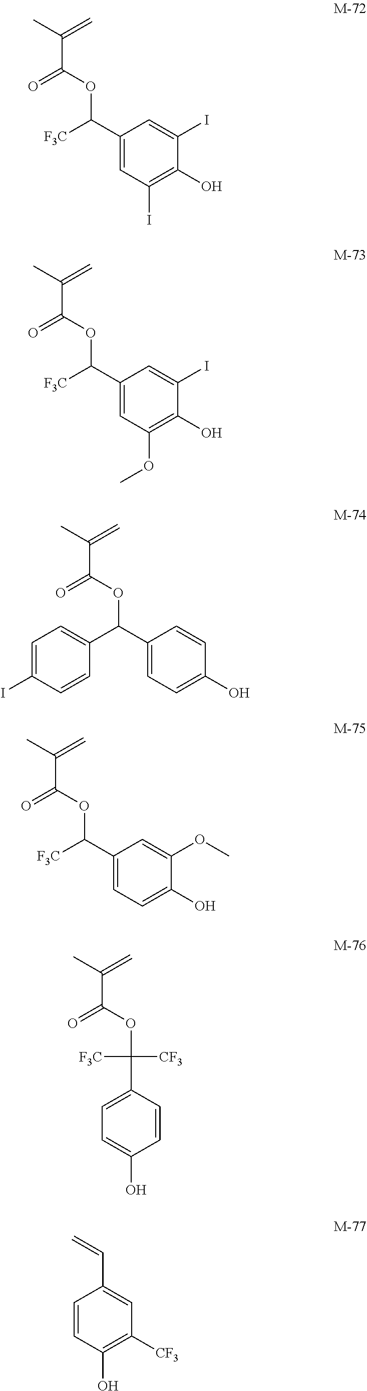

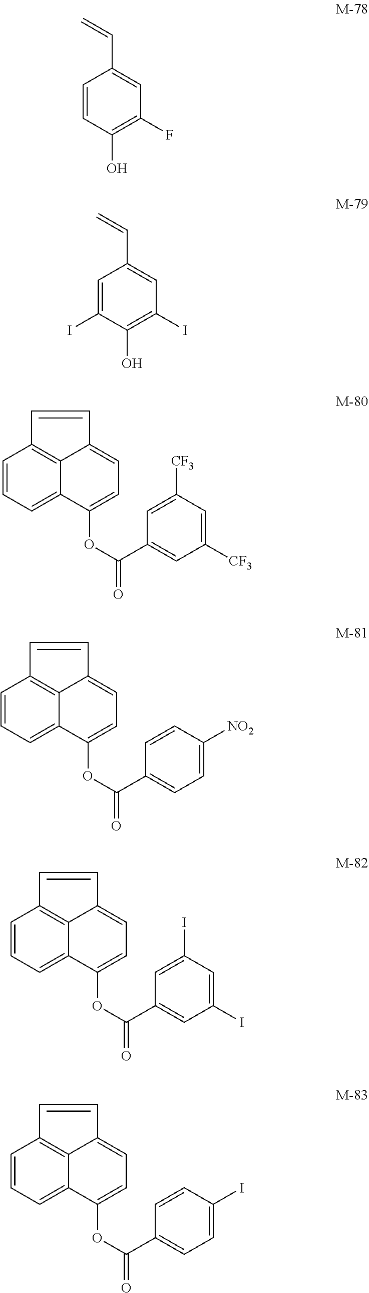

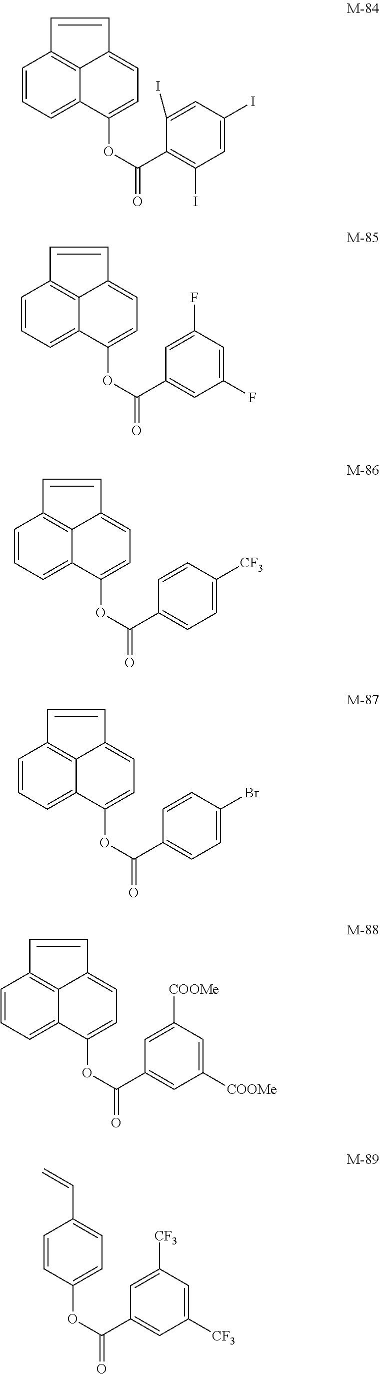

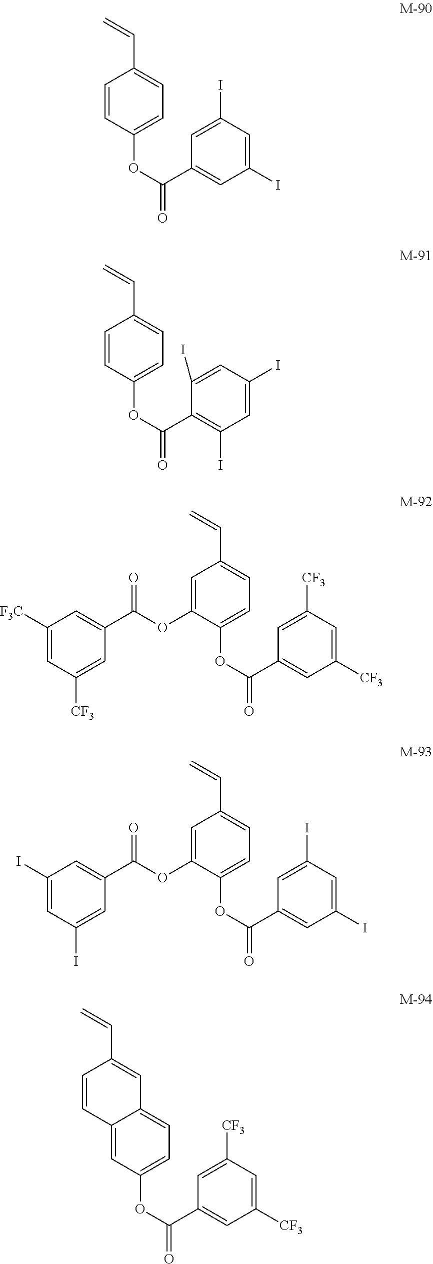

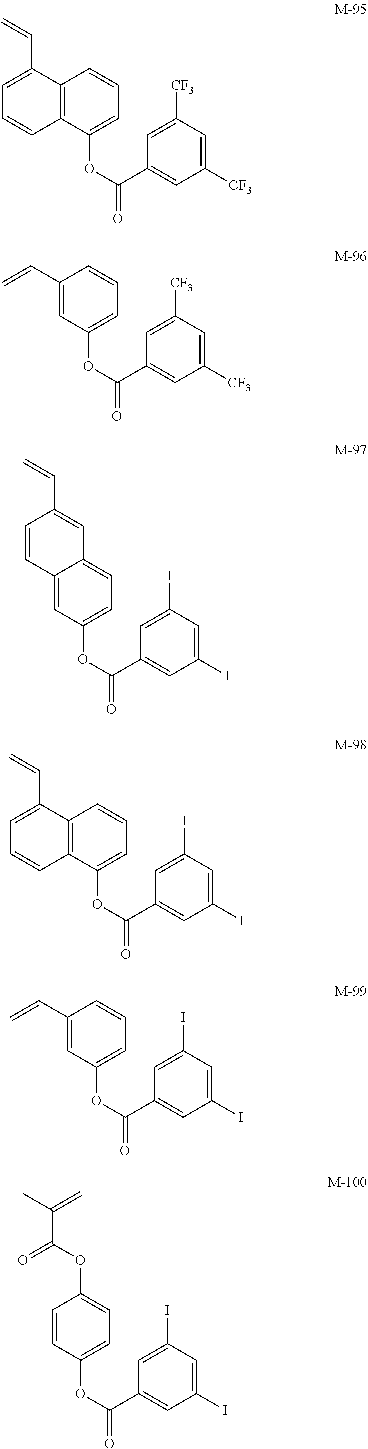

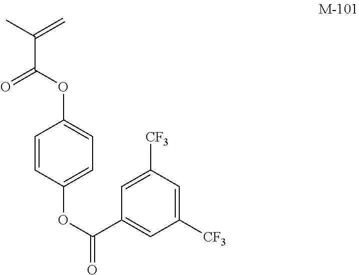

### Photoacid Generator (B)

The structures of the photoacid generator (B) (compounds B-1 to B-39) described in Table 3 are as follows.

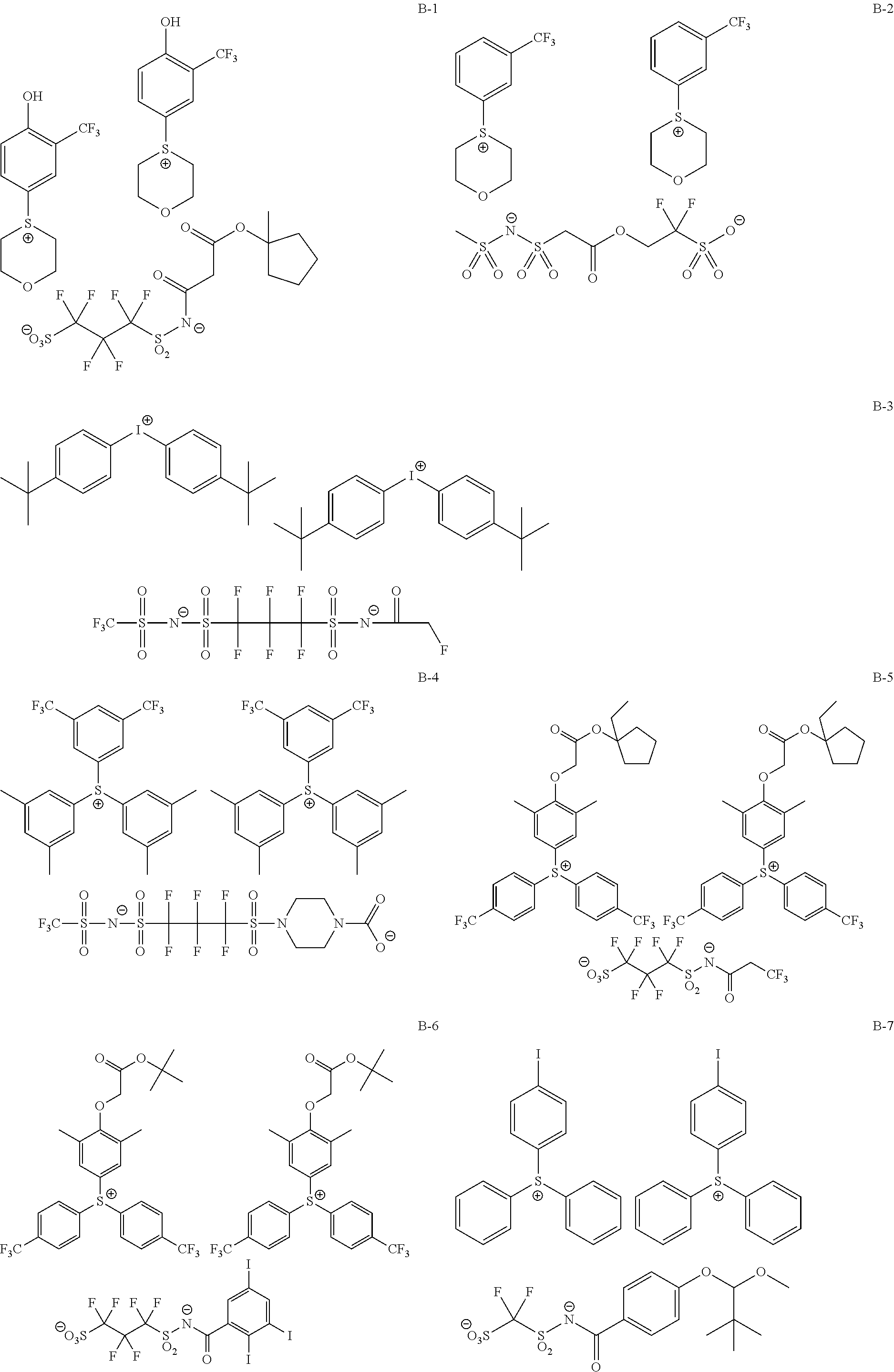

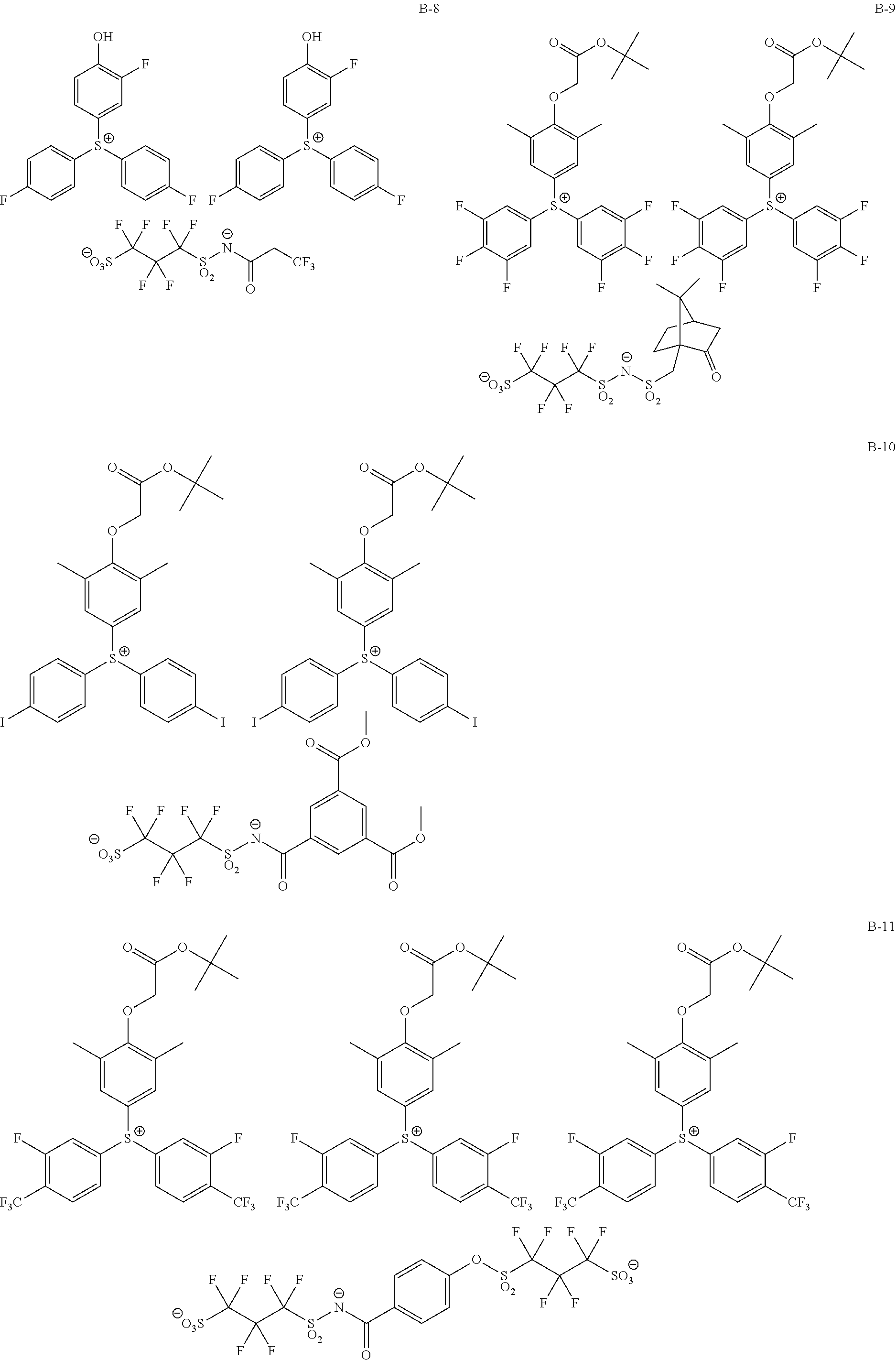

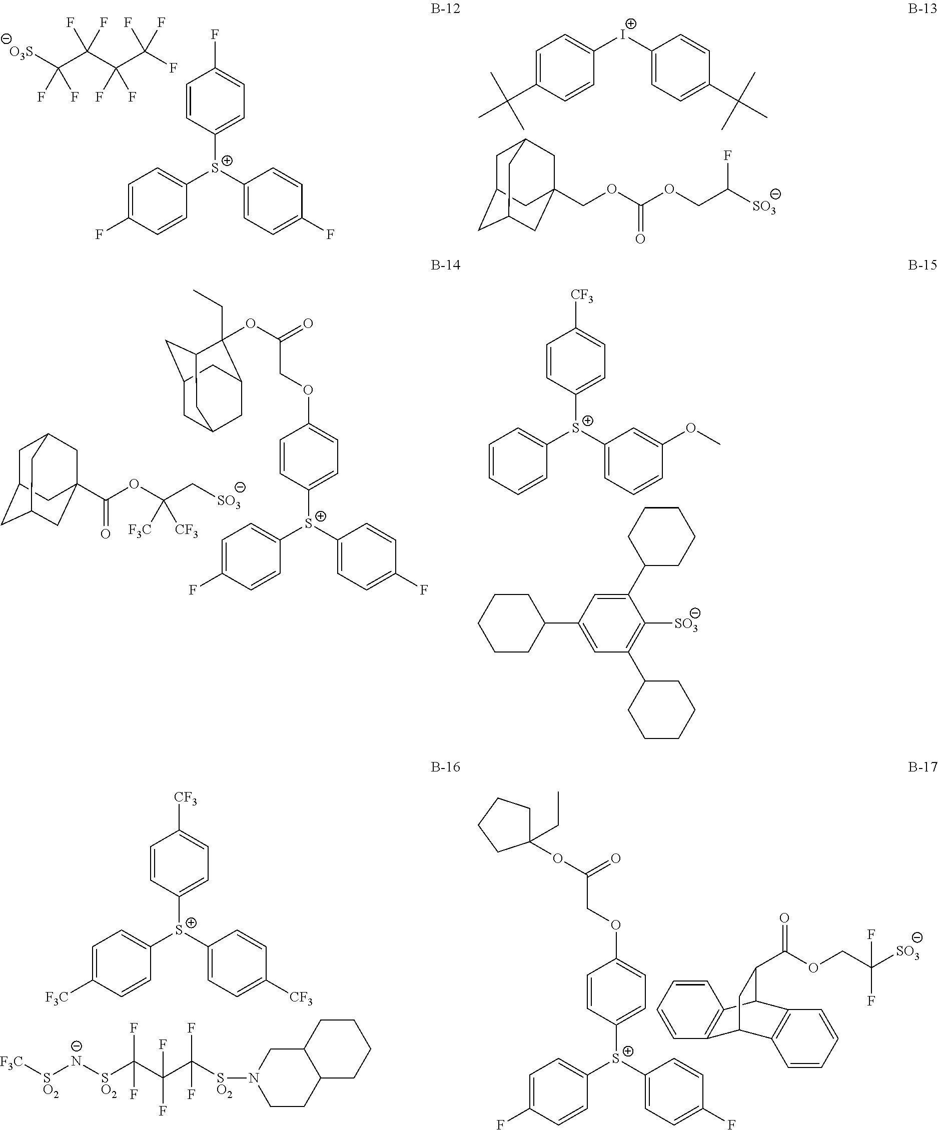

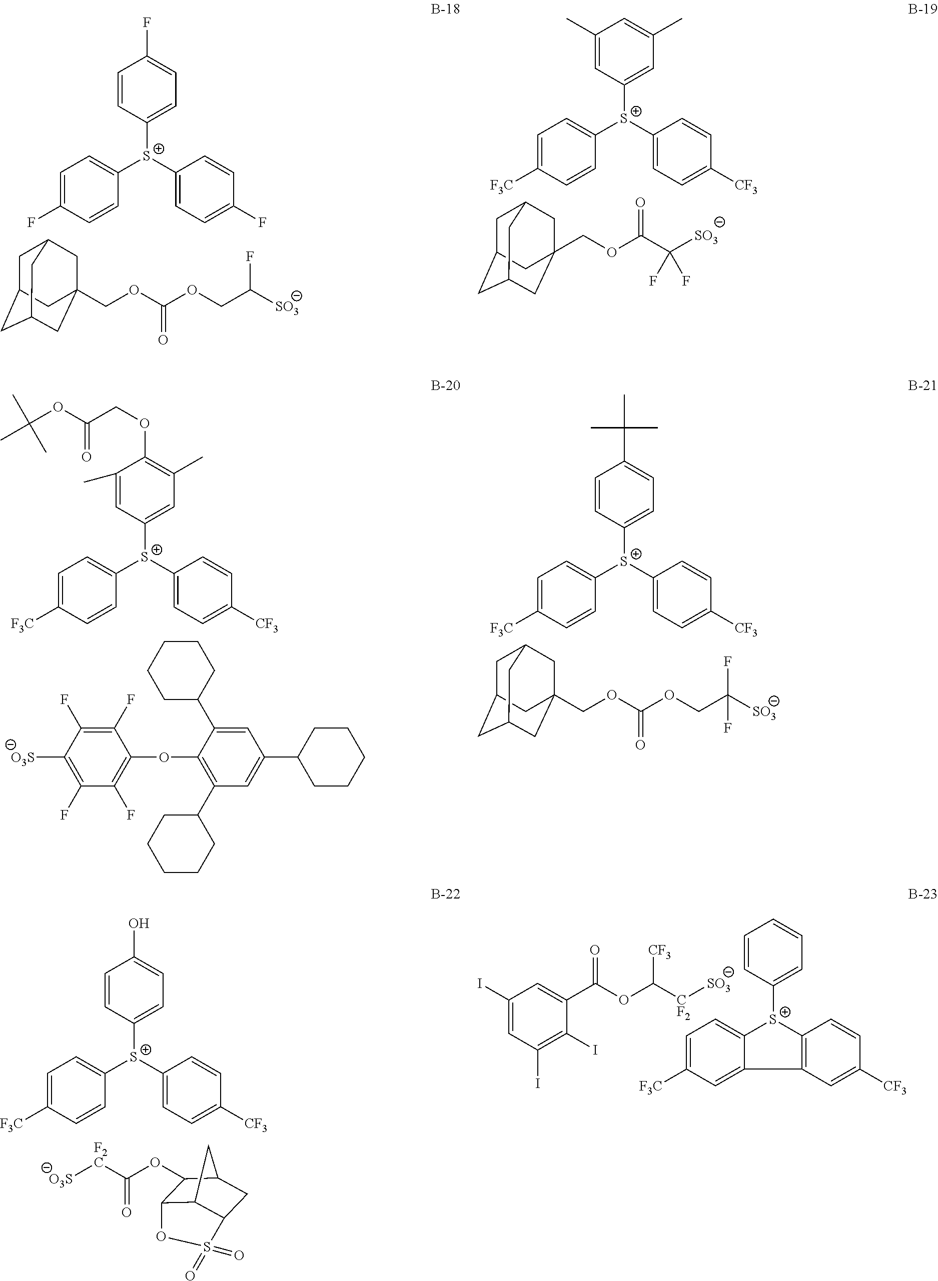

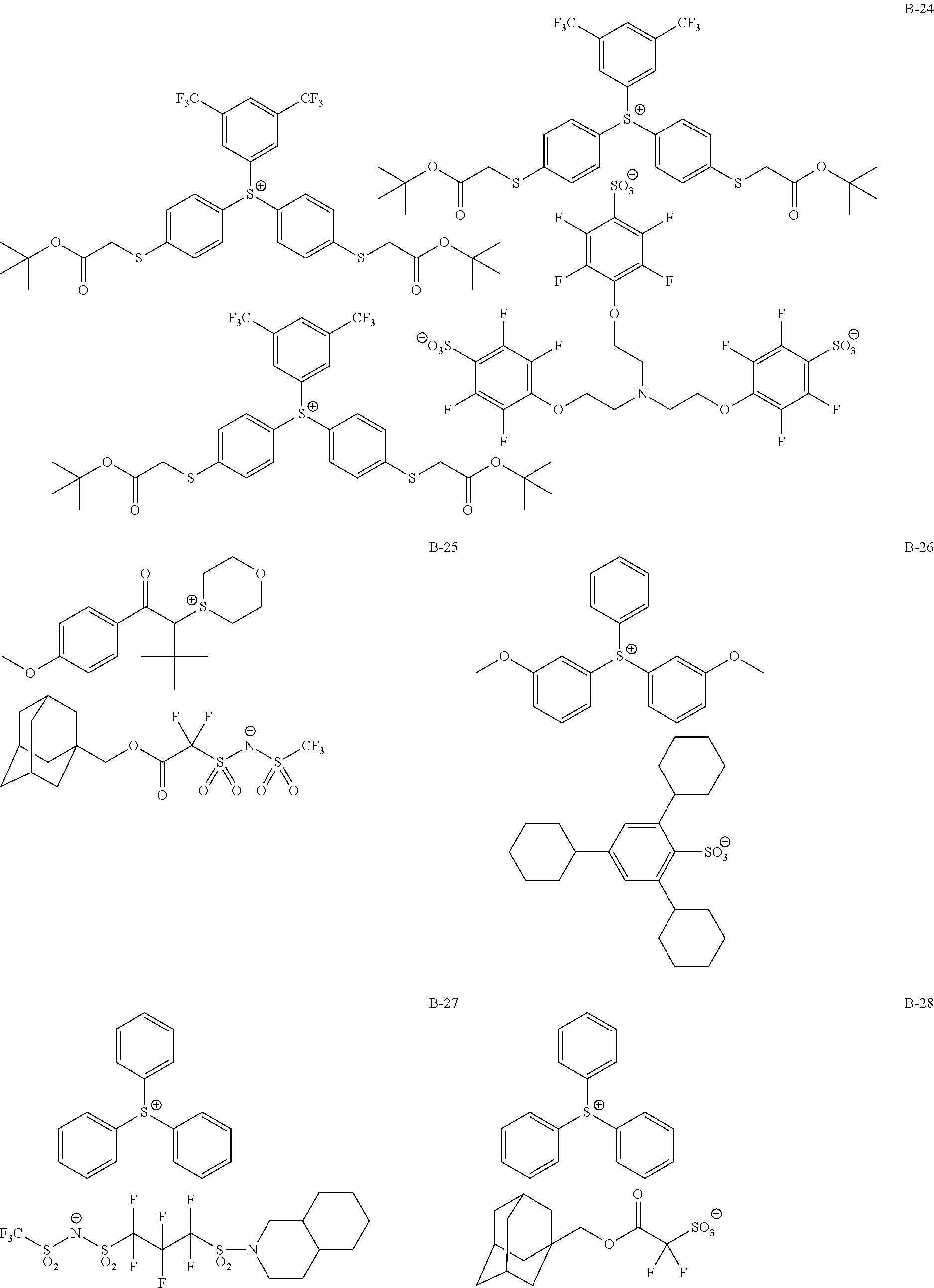

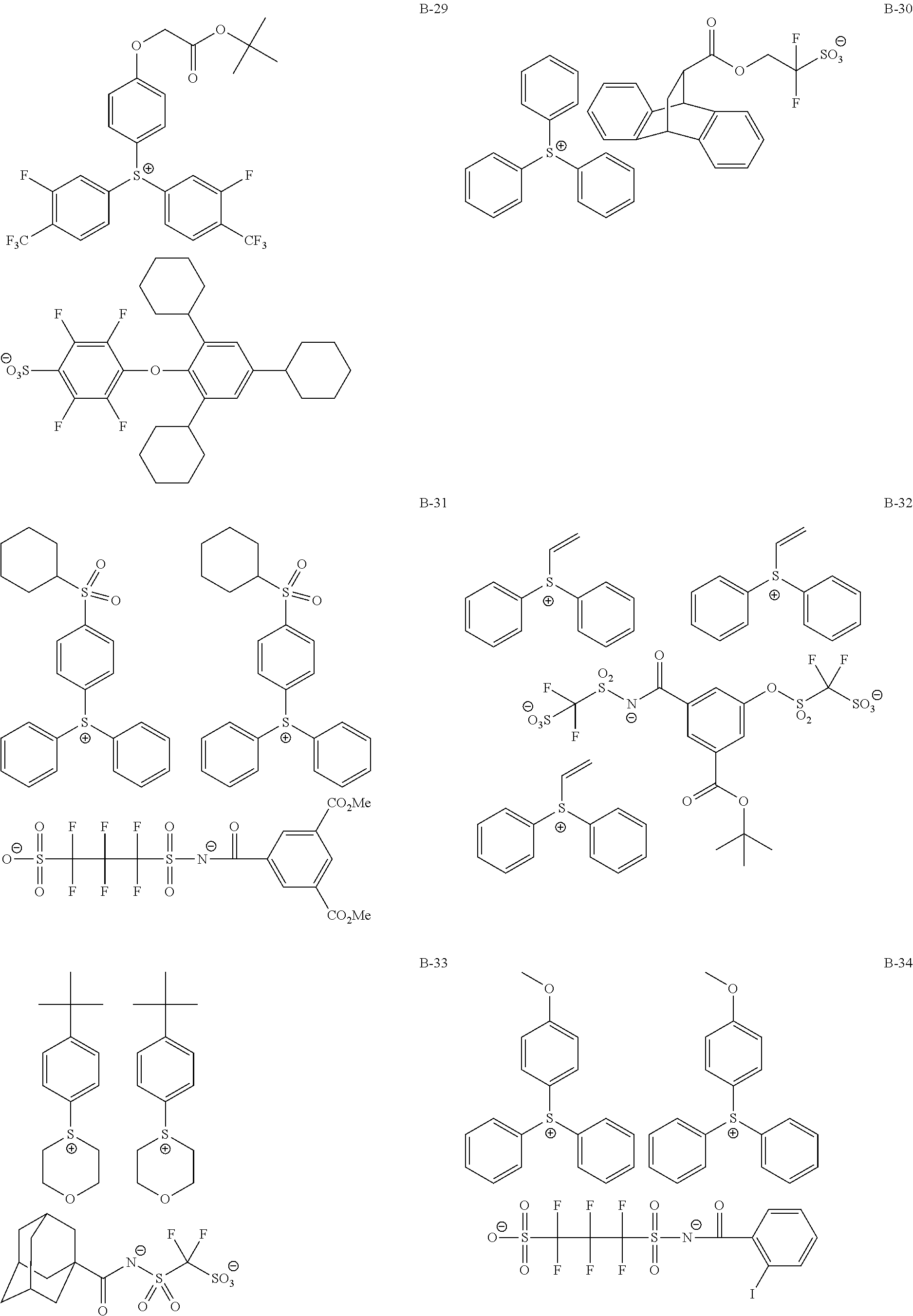

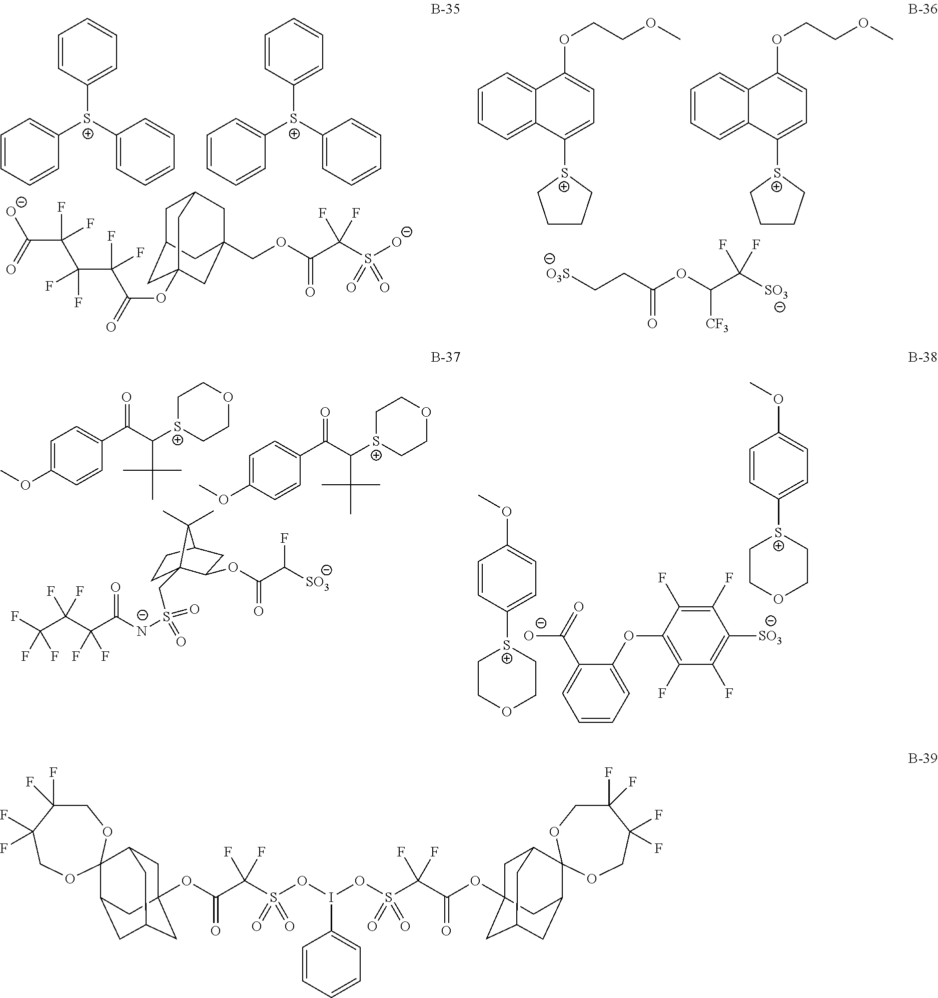

### Acid Diffusion Control Agent

The structures of the acid diffusion control agents (compounds C-1 to C-17 and compounds G-1 to G-5) described in Table 3 are as follows.

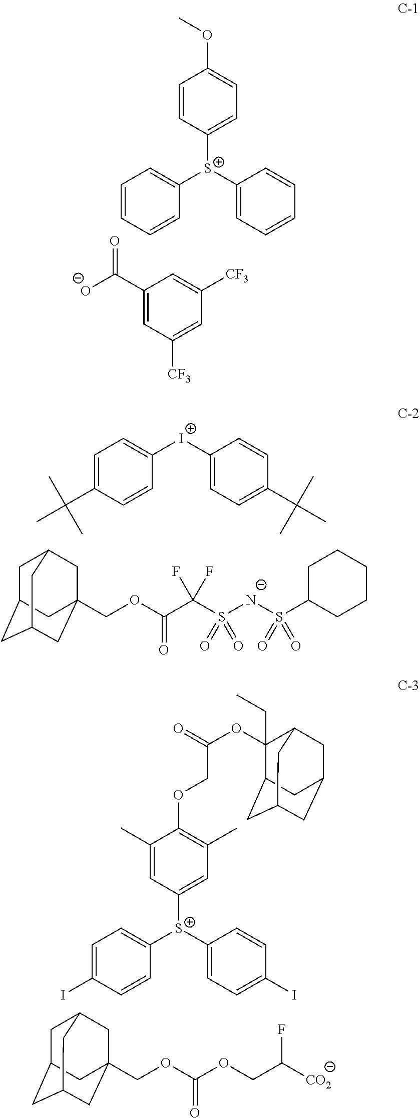

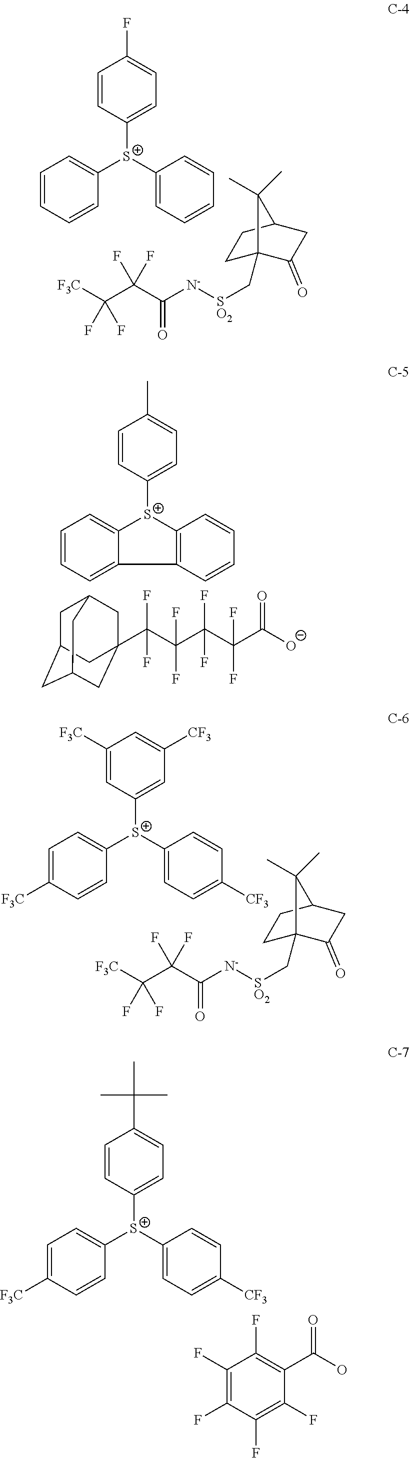

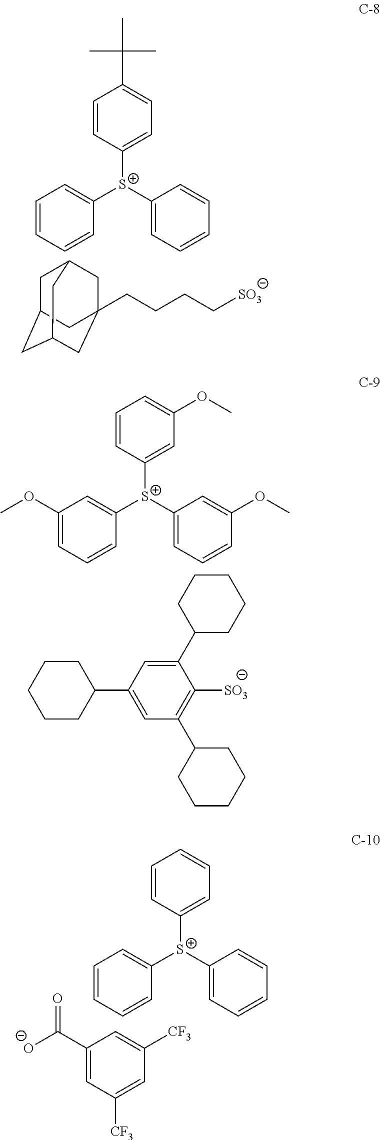

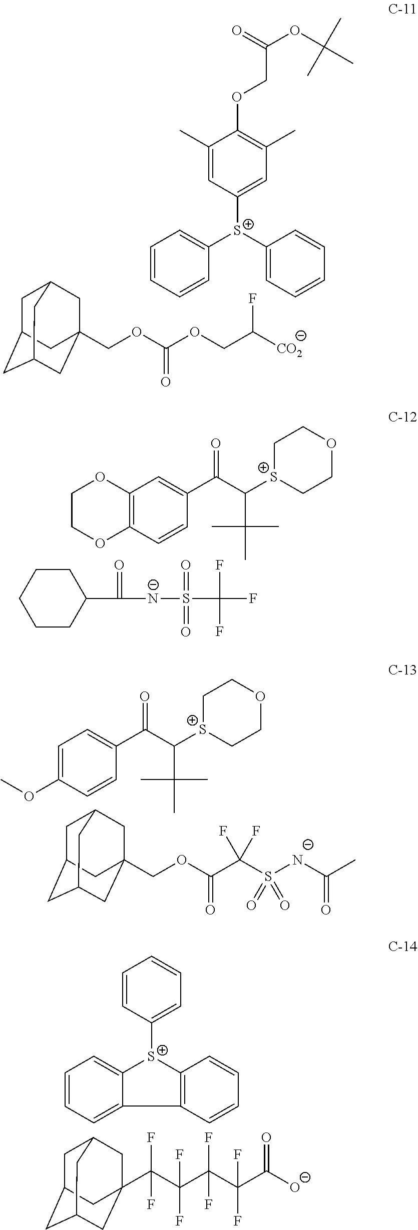

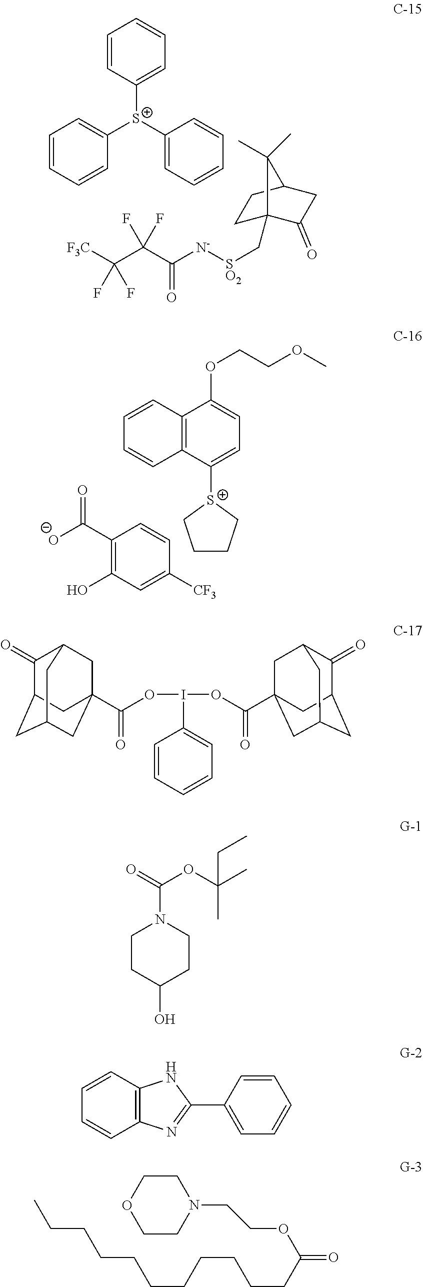

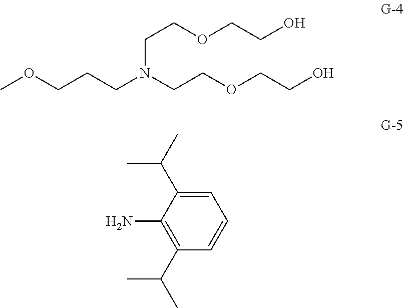

### Resin I

The resin I (resins I-1 to I-8) described in Table 3 will be described below.

The resins I-1 to I-8 used were synthesized in accordance with the above-described method for synthesizing the resin A-1-1-a (Synthesis Example 4). Table 2 describes, for repeating units described later, the compositional ratio (mol % ratio; sequentially described from the left), weight-average molecular weight (Mw), and dispersity (Mw/Mn).

Note that, for the resins I-1 to I-8, the weight-average molecular weight (Mw) and the dispersity (Mw/Mn) were measured by GPC (carrier: tetrahydrofuran (THF)) (polystyrene-equivalent amounts). The compositional ratios (mol % ratios) of the resins were measured by ¹³C-NMR (nuclear magnetic resonance).

TABLE 3

| Table 2 | Molar ratios of repeating units [%] | | | | Mw | Mw/Mn |
|---|---|---|---|---|---|---|
| Resin I-1 | 50 | 45 | 5 | — | 6500 | 1.52 |
| Resin I-2 | 50 | 50 | — | — | 25000 | 1.65 |
| Resin I-3 | 30 | 65 | 5 | — | 22000 | 1.55 |
| Resin I-4 | 40 | 40 | 20 | — | 12000 | 1.68 |
| Resin I-5 | 40 | 50 | 5 | 5 | 5500 | 1.49 |
| Resin I-6 | 90 | 8 | 2 | — | 12000 | 1.63 |
| Resin I-7 | 20 | 30 | 40 | 10 | 13000 | 1.55 |
| Resin I-8 | 50 | 10 | 40 | — | 9000 | 1.51 |

The structural formulas of the resins I-1 to I-8 described in Table 2 are as follows.

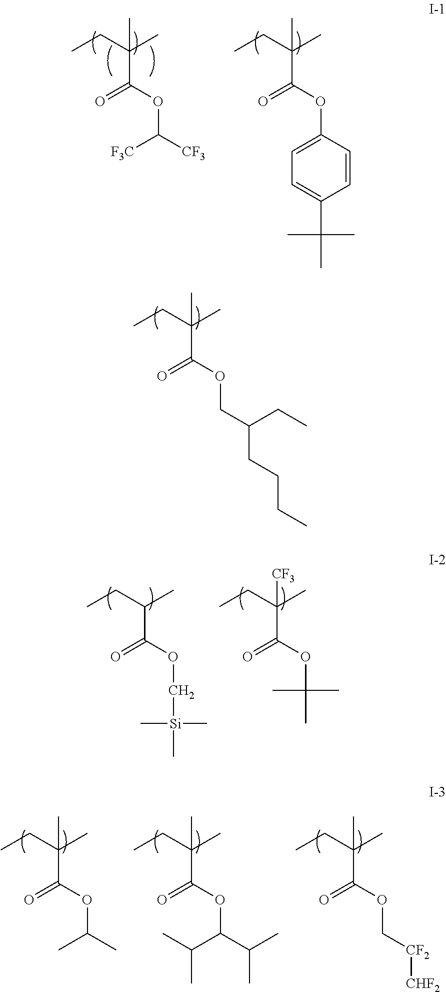

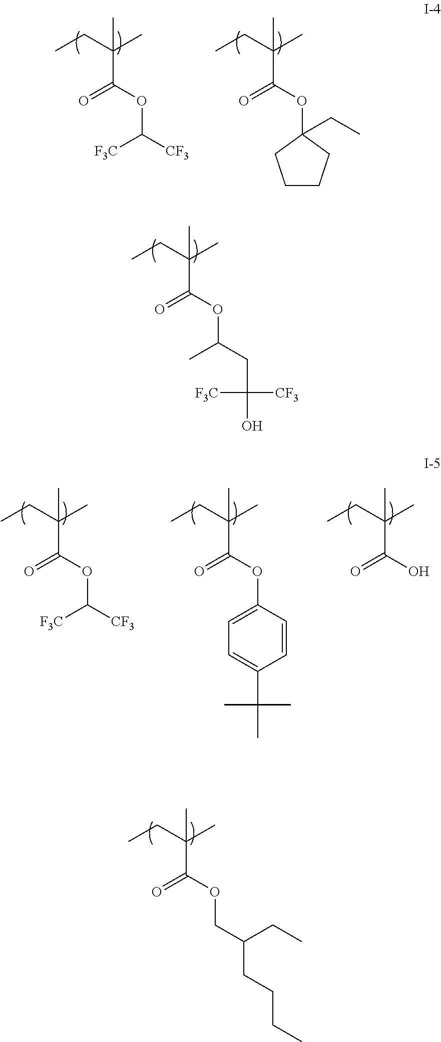

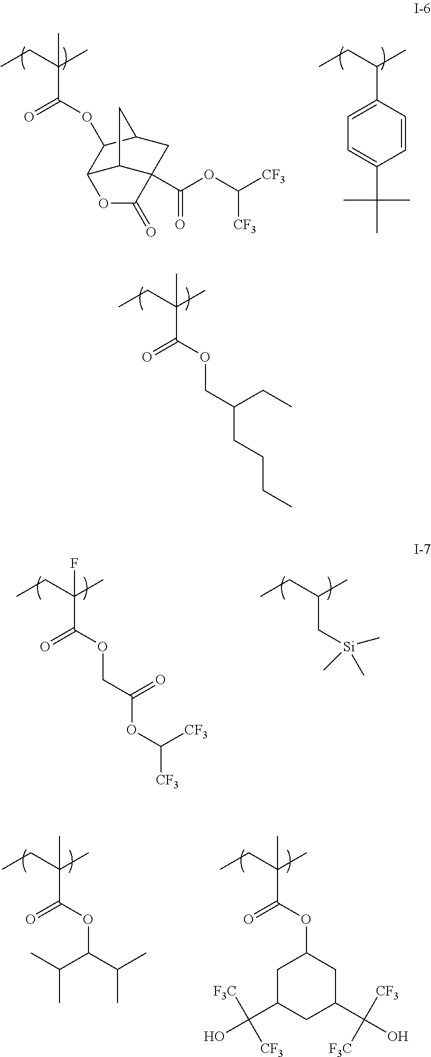

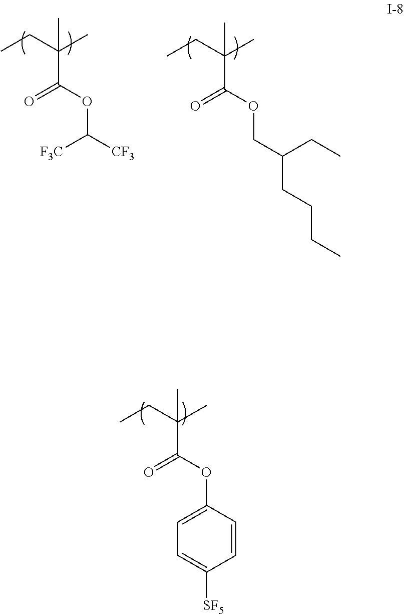

### Surfactant

The surfactants described in Table 3 are as follows.

H-1: MEGAFACE F176 (manufactured by DIC Corporation, fluorine-based surfactant)

H-2: MEGAFACE R₀₈ (manufactured by DIC Corporation, fluorine-based and silicone-based surfactant)

H-3: PF656 (manufactured by OMNOVA Solutions Inc., fluorine-based surfactant)

### Solvent

The solvents described in Table 3 are as follows.
F-1: propylene glycol monomethyl ether acetate (PGMEA)
F-2: propylene glycol monomethyl ether (PGME)
F-3: propylene glycol monoethyl ether (PGEE)
F-4: cyclohexanone
F-5: cyclopentanone
F-6: 2-heptanone
F-7: ethyl lactate
F-8: γ-butyrolactone
F-9: propylene carbonate

### Preparation of Resist Compositions

Components described in Table 3 were mixed together so as to provide a solid content concentration of 2.0 mass %. Subsequently, the obtained mixed solution was filtered first through a polyethylene filter having a pore size of 50 nm, subsequently through a nylon filter having a pore size of 10 nm, and finally through a polyethylene filter having a pore size of 5 nm in this order; in this way, resist compositions (Re-1 to Re-67 and Re-1R to Re-2R) were prepared.

Note that the solid content means all the components other than the solvent. The obtained resist compositions were used in Examples and Comparative Examples.

In Tables, the columns “Amount” describe the content (mass %) of each component relative to the total solid content of the resist composition.

TABLE 4

| | Solid content | | | | | | | | | | | |
|---|---|---|---|---|---|---|---|---|---|---|---|---|
| | | | | | | | | | | | Solvent | |
| | | | Photoacid | | Acid diffusion | | | | | | | Mixing |
| | Resin A | | generator B | | control agent | | Resin I | | Surfactant | | | ratio |
| Table 3 | Type | Amount | Type | Amount | Type | Amount | Type | Amount | Type | Amount | Type | (mass ratio) |
| Re-1 | A-1 | 65.0 | B-28 | 25.0 | C-10 | 10.0 | — | — | — | — | F-1/F-2 | 80/20 |
| Re-2 | A-2 | 60.0 | B-1 | 40.0 | — | — | — | — | — | — | F-1/F-5 | 85/15 |
| Re-3 | A-3 | 56.0 | B-2 | 44.0 | — | — | — | — | — | — | F-1/F-2 | 80/20 |
| Re-4 | A-4 | 55.0 | B-3 | 45.0 | — | — | — | — | — | — | F-1/F-2/F-8 | 40/20/40 |
| Re-5 | A-5 | 60.0 | B-4 | 40.0 | — | — | — | — | — | — | F-1/F-2 | 80/20 |
| Re-6 | A-6 | 65.0 | B-5 | 35.0 | — | — | — | — | — | — | F-1/F-9 | 85/15 |
| Re-7 | A-7 | 54.0 | B-6 | 45.9 | — | — | — | — | H-1 | 0.1 | F-1/F-7 | 90/10 |
| Re-8 | A-8 | 45.0 | B-7 | 55.0 | — | — | — | — | — | — | F-1/F-2 | 80/20 |
| Re-9 | A-9 | 50.0 | B-8 | 35.0 | C-1 | 15.0 | — | — | — | — | F-1/F-2 | 80/20 |
| Re-10 | A-10 | 50.0 | B-9 | 40.0 | C-2 | 10.0 | — | — | — | — | F-1/F-2/F-6 | 70/20/10 |
| Re-11 | A-11 | 55.0 | B-10 | 30.0 | C-3 | 15.0 | — | — | — | — | F-1/F-2 | 80/20 |
| Re-12 | A-12 | 90.0 | B-12 | 8.0 | C-5 | 2.0 | — | — | — | — | F-1/F-4 | 80/20 |
| Re-13 | A-13 | 60.0 | B-11 | 30.0 | C-4 | 8.0 | 1-1 | 2.0 | — | — | F-1/F-2 | 80/20 |
| Re-14 | A-14 | 70.0 | B-13 | 20.0 | C-6 | 7.0 | 1-2 | 2.9 | H-2 | 0.1 | F-4 | 100 |
| Re-15 | A-15 | 65.0 | B-14 | 32.0 | G-1 | 3.0 | — | — | — | — | F-1/F-2 | 85/15 |
| Re-16 | A-16 | 80.0 | B-15 | 15.0 | G-2 | 5.0 | — | — | — | — | F-1/F-5 | 80/20 |
| Re-17 | A-17 | 63.5 | B-16 | 26.0 | C-7 | 6.5 | 1-3 | 4.0 | — | — | F-1/F-2 | 75/25 |
| Re-18 | A-18 | 90.0 | B-17 | 8.0 | G-3 | 2.0 | — | — | — | — | F-1/F-2/F-8 | 34/33/33 |
| Re-19 | A-19 | 65.5 | B-18 | 20.0 | C-8 | 12.5 | 1-4 | 2.0 | — | — | F-1/F-2 | 80/20 |
| Re-20 | A-20 | 88.5 | B-19 | 6.5 | G-4 | 5.0 | — | — | — | — | F-1/F-9 | 80/20 |
| Re-21 | A-21 | 74.0 | B-20 | 22.0 | G-5 | 4.0 | — | — | — | — | F-1/F-7 | 80/20 |
| Re-22 | A-22 | 80.0 | B-21 | 7.0 | C-9 | 4.0 | 1-5 | 8.9 | H-3 | 0.1 | F-1/F-2 | 85/15 |
| Re-23 | A-23 | 80.0 | B-22 | 12.0 | C-10 | 5.0 | 1-6 | 3.0 | — | — | F-1/F-2 | 80/20 |
| Re-24 | A-24 | 85.0 | B-23 | 8.0 | C-11 | 2.0 | 1-7 | 5.0 | — | — | F-1/F-2/F-6 | 80/15/5 |
| Re-25 | A-25 | 70.0 | B-24 | 18.0 | C-12 | 8.0 | 1-8 | 4.0 | — | — | F-1/F-2 | 90/10 |
| Re-26 | A-26 | 65.0 | B-25 | 25.0 | C-13 | 10.0 | — | — | — | — | F-1/F-4 | 80/20 |
| Re-27 | A-27 | 55.0 | B-26 | 30.0 | C-14 | 15.0 | — | — | — | — | F-1/F-2 | 80/20 |
| Re-28 | A-28 | 45.0 | B-27 | 35.0 | C-15 | 19.9 | — | — | H-3 | 0.1 | F-4 | 100 |
| Re-29 | A-29 | 40.0 | B-28 | 45.0 | C-16 | 15.0 | — | — | — | — | F-1/F-3 | 85/15 |
| Re-30 | A-30 | 75.0 | B-29 | 20.0 | C-1 | 5.0 | — | — | — | — | F-1/F-5 | 80/20 |
| Re-31 | A-31 | 75.0 | B-30 | 15.0 | C-2 | 9.9 | — | — | H-1 | 0.1 | F-1/F-2 | 75/25 |
| Re-32 | A-32 | 75.0 | B-31 | 15.0 | C-3 | 10.0 | — | — | — | — | F-1/F-2/F-8 | 40/20/40 |
| Re-33 | A-33 | 70.0 | B-32 | 15.0 | C-4 | 15.0 | — | — | — | — | F-1/F-2 | 80/20 |
| Re-34 | A-34 | 70.0 | B-33 | 20.0 | C-5 | 10.0 | — | — | — | — | F-1/F-9 | 80/20 |
| Re-35 | A-35 | 60.0 | B-34 | 30.0 | C-6 | 10.0 | — | — | — | — | F-1/F-7 | 80/20 |

TABLE 5

| | Solid content | | | | | | | | | | | |
|---|---|---|---|---|---|---|---|---|---|---|---|---|
| | | | | | | | | | | | Solvent | |
| | | | Photoacid | | Acid diffusion | | | | | | | Mixing |
| Table 3 | Resin A | | generator B | | control agent | | Resin I | | Surfactant | | | ratio |
| (continued) | Type | Amount | Type | Amount | Type | Amount | Type | Amount | Type | Amount | Type | (mass ratio) |
| Re-36 | A-36 | 65.0 | B-35 | 35.0 | — | — | — | — | — | — | F-1/F-2 | 85/15 |
| Re-37 | A-37 | 70.0 | B-36 | 30.0 | — | — | — | — | — | — | F-1/F-2 | 90/10 |
| Re-38 | A-38 | 55.0 | B-37 | 45.0 | — | — | — | — | — | — | F-1/F-2/F-6 | 60/20/20 |
| Re-39 | A-39 | 55.0 | B-38 | 45.0 | — | — | — | — | — | — | F-1/F-2 | 90/10 |
| Re-40 | A-40 | 55.0 | B-1/B-12 | 30.0/15.0 | — | — | — | — | — | — | F-1/F-4 | 80/20 |
| Re-41 | A-41 | 60.0 | B-39 | 30.0 | C-17 | 10.0 | — | — | — | — | F-1/F-2 | 80/20 |
| Re-42 | A-42 | 65.0 | B-3 | 35.0 | — | — | — | — | — | — | F-4 | 100 |
| Re-43 | A-43 | 60.0 | B-4 | 40.0 | — | — | — | — | — | — | F-1/F-2/F-6 | 34/33/33 |
| Re-44 | A-44 | 70.0 | B-5/B-7 | 20.0/10.0 | — | — | — | — | — | — | F-1/F-5 | 80/20 |
| Re-45 | A-45 | 65.0 | B-6 | 35.0 | — | — | — | — | — | — | F-1/F-2 | 85/15 |
| Re-46 | A-46 | 65.0 | B-8 | 35.0 | — | — | — | — | — | — | F-1/F-2/F-8 | 50/40/10 |
| Re-47 | A-47 | 60.0 | B-9/B-30 | 20.0/20.0 | — | — | — | — | — | — | F-1/F-2 | 80/20 |
| Re-48 | A-48 | 55.0 | B-11/B-29 | 30.0/15.0 | — | — | — | — | — | — | F-1/F-9 | 80/20 |
| Re-49 | A-49 | 45.0 | B-10 | 55.0 | — | — | — | — | — | — | F-1/F-7 | 60/40 |
| Re-50 | A-50 | 50.0 | B-11 | 50.0 | — | — | — | — | — | — | F-1/F-2 | 90/10 |
| Re-51 | A-51 | 55.0 | B-12 | 35.0 | C-9 | 10.0 | — | — | — | — | F-1/F-2 | 80/20 |
| Re-52 | A-52 | 70.0 | B-13 | 25.0 | C-10 | 5.0 | — | — | — | — | F-1/F-2/F-6 | 50/30/20 |
| Re-53 | A-53 | 80.0 | B-14 | 10.0 | C-11 | 10.0 | — | — | — | — | F-1/F-2 | 80/20 |
| Re-54 | A-54 | 55.0 | B-15 | 35.0 | C-12 | 10.0 | — | — | — | — | F-1/F-4 | 80/20 |
| Re-55 | A-55 | 60.0 | B-16 | 30.0 | C-13 | 10.0 | — | — | — | — | F-1/F-2 | 60/40 |
| Re-56 | A-56 | 75.0 | B-17 | 20.0 | C-14 | 5.0 | — | — | — | — | F-4 | 100 |
| Re-57 | A-57 | 75.0 | B-18 | 15.0 | C-15 | 10.0 | — | — | — | — | F-1/F-2 | 80/20 |
| Re-58 | A-58 | 65.0 | B-19 | 30.0 | C-16 | 5.0 | — | — | — | — | F-1/F-5 | 80/20 |
| Re-59 | A-59 | 80.0 | B-20 | 15.0 | C-7 | 5.0 | — | — | — | — | F-1/F-2 | 80/20 |
| Re-60 | A-60 | 65.0 | B-21 | 25.0 | C-8 | 10.0 | — | — | — | — | F-1/F-2/F-8 | 34/33/33 |
| Re-61 | A-61 | 45.0 | B-22 | 45.0 | C-1 | 10.0 | — | — | — | — | F-1/F-2 | 80/20 |
| Re-62 | A-62 | 65.0 | B-23 | 30.0 | C-2 | 5.0 | — | — | — | — | F-1/F-2 | 85/15 |
| Re-63 | A-63 | 25.0 | B-24 | 70.0 | C-3 | 5.0 | — | — | — | — | F-1/F-7 | 90/10 |
| Re-64 | A-64 | 55.0 | B-25 | 40.0 | C-4 | 5.0 | — | — | — | — | F-1/F-2 | 80/20 |
| Re-65 | A-65 | 65.0 | B-26 | 30.0 | C-5 | 5.0 | — | — | — | — | F-1/F-2 | 80/20 |
| Re-66 | A-66 | 55.0 | B-27 | 30.0 | C-6 | 15.0 | — | — | — | — | F-1/F-7 | 90/10 |
| Re-67 | A-67 | 70.0 | B-28 | 20.0 | C-7 | 10.0 | — | — | — | — | F-1/F-2 | 80/20 |
| Re-1R | A-1R | 65.0 | B-28 | 25.0 | C-4 | 10.0 | — | — | — | — | F-1/F-2 | 80/20 |
| Re-2R | A-2R | 65.0 | B-28 | 25.0 | C-4 | 10.0 | — | — | — | — | F-1/F-2 | 80/20 |

### Examples 1-1 to 1-67 and Comparative Examples 1-1 to 1-2

### Pattern Formation

### EUV Exposure, Organic Solvent Development

An underlayer film-forming composition AL412 (manufactured by Brewer Science, Inc.) was applied onto a silicon wafer having a diameter of 12 inches and baked at 205° C. for 60 seconds to form an underlying film having a film thickness of 20 nm. A resist composition described in Table 3 was applied thereonto and baked at 100° C. for 60 seconds to form a resist film having a film thickness of 30 nm.

An EUV exposure apparatus (manufactured by Exitech Ltd., Micro Exposure Tool, NA: 0.3, Quadrupol, outer sigma: 0.68, inner sigma: 0.36) was used to subject the obtained silicon wafer having the resist film to pattern irradiation such that the resultant pattern would have an average line width of 20 nm. Note that, as the reticle, a mask having a line size=20 nm and a line: space=1:1 was used.

The exposed resist film was baked at 90° C. for 60 seconds, and subsequently developed with n-butyl acetate for 30 seconds; and this was spin-dried to obtain a negative pattern.

### Evaluation

### Defect Evaluation (Defect Suppression Property)

For the patterns obtained by the above-described method, UVision5 (manufactured by AMAT Inc.) and SEMVisionG4 (manufactured by AMAT Inc.) were used to count the number of defects per silicon wafer and evaluation was performed in accordance with the following evaluation grades. The smaller the number of defects, the better the defect suppression property.

Grades “A” to “E” are acceptable for practical use.
“A”: The number of defects is 50 or less.
“B”: The number of defects is more than 50 and 100 or less.
“C”: The number of defects is more than 100 and 200 or less.
“D”: The number of defects is more than 200 and 300 or less.
“E”: The number of defects is more than 300 and 400 or less.
“F”: The number of defects is more than 400.

The evaluation results will be described in Table 4 below.

TABLE 6

| | Resist | Defect suppression |
|---|---|---|
| Table 4 | composition | property |
| Example 1-1 | Re-1 | C |
| Example 1-2 | Re-2 | D |
| Example 1-3 | Re-3 | C |
| Example 1-4 | Re-4 | C |
| Example 1-5 | Re-5 | C |
| Example 1-6 | Re-6 | B |
| Example 1-7 | Re-7 | C |
| Example 1-8 | Re-8 | D |
| Example 1-9 | Re-9 | D |
| Example 1-10 | Re-10 | D |
| Example 1-11 | Re-11 | D |
| Example 1-12 | Re-12 | C |
| Example 1-13 | Re-13 | C |
| Example 1-14 | Re-14 | C |
| Example 1-15 | Re-15 | B |
| Example 1-16 | Re-16 | C |
| Example 1-17 | Re-17 | C |
| Example 1-18 | Re-18 | C |
| Example 1-19 | Re-19 | C |
| Example 1-20 | Re-20 | D |
| Example 1-21 | Re-21 | D |
| Example 1-22 | Re-22 | D |
| Example 1-23 | Re-23 | D |
| Example 1-24 | Re-24 | E |
| Example 1-25 | Re-25 | D |
| Example 1-26 | Re-26 | D |
| Example 1-27 | Re-27 | B |
| Example 1-28 | Re-28 | D |
| Example 1-29 | Re-29 | C |
| Example 1-30 | Re-30 | D |
| Example 1-31 | Re-31 | D |
| Example 1-32 | Re-32 | C |
| Example 1-33 | Re-33 | C |
| Example 1-34 | Re-34 | D |
| Example 1-35 | Re-35 | D |

TABLE 7

| Table 4 | Resist | Defect suppression |
|---|---|---|
| (continued) | composition | property |
| Example 1-36 | Re-36 | D |
| Example 1-37 | Re-37 | D |
| Example 1-38 | Re-38 | C |
| Example 1-39 | Re-39 | D |
| Example 1-40 | Re-40 | C |
| Example 1-41 | Re-41 | C |
| Example 1-42 | Re-42 | C |
| Example 1-43 | Re-43 | C |
| Example 1-44 | Re-44 | C |
| Example 1-45 | Re-45 | C |
| Example 1-46 | Re-46 | C |
| Example 1-47 | Re-47 | B |
| Example 1-48 | Re-48 | B |
| Example 1-49 | Re-49 | C |
| Example 1-50 | Re-50 | D |
| Example 1-51 | Re-51 | B |
| Example 1-52 | Re-52 | C |
| Example 1-53 | Re-53 | D |
| Example 1-54 | Re-54 | C |
| Example 1-55 | Re-55 | C |
| Example 1-56 | Re-56 | C |
| Example 1-57 | Re-57 | D |
| Example 1-58 | Re-58 | D |
| Example 1-59 | Re-59 | C |
| Example 1-60 | Re-60 | C |
| Example 1-61 | Re-61 | C |
| Example 1-62 | Re-62 | B |
| Example 1-63 | Re-63 | C |
| Example 1-64 | Re-64 | C |
| Example 1-65 | Re-65 | C |
| Example 1-66 | Re-66 | C |
| Example 1-67 | Re-67 | C |
| Comparative Example 1-1 | Re-1R | F |
| Comparative Example 1-2 | Re-2R | F |

Table 4 above has demonstrated that resist compositions of the present invention provide, in the case of forming a pattern by organic solvent development, high defect performance (defect suppression property).

### Examples 2-1 to 2-67 and Comparative Examples 2-1 to 2-2

### EUV Exposure, Alkaline Aqueous Solution Development

An underlayer film-forming composition AL412 (manufactured by Brewer Science, Inc.) was applied onto a silicon wafer having a diameter of 12 inches and baked at 205° C. for 60 seconds to form an underlying film having a film thickness of 20 nm. A resist composition described in Table 3 was applied thereonto and baked at 100° C. for 60 seconds to form a resist film having a film thickness of 30 nm.

An EUV exposure apparatus (manufactured by Exitech Ltd., Micro Exposure Tool, NA: 0.3, Quadrupol, outer sigma: 0.68, inner sigma: 0.36) was used to subject the obtained silicon wafer having the resist film to pattern irradiation such that the resultant pattern would have an average line width of 20 nm. Note that, as the reticle, a mask having a line size=20 nm and a line: space=1:1 was used.

The exposed resist film was baked at 90° C. for 60 seconds, subsequently developed with an aqueous tetramethylammonium hydroxide solution (2.38 mass %) for 30 seconds, and subsequently rinsed with pure water for 30 seconds. Subsequently, this was spin-dried to obtain a positive pattern.

Such obtained positive patterns were subjected to, as in the above-described manner, evaluation of the defect suppression property.

The evaluation results will be described in Table 5 below.

TABLE 8

| | Resist | Defect suppression |
|---|---|---|
| Table 5 | composition | property |
| Example 2-1 | Re-1 | B |
| Example 2-2 | Re-2 | C |
| Example 2-3 | Re-3 | B |
| Example 2-4 | Re-4 | B |
| Example 2-5 | Re-5 | B |
| Example 2-6 | Re-6 | A |
| Example 2-7 | Re-7 | B |
| Example 2-8 | Re-8 | C |
| Example 2-9 | Re-9 | C |
| Example 2-10 | Re-10 | C |
| Example 2-11 | Re-11 | C |
| Example 2-12 | Re-12 | B |
| Example 2-13 | Re-13 | B |
| Example 2-14 | Re-14 | B |
| Example 2-15 | Re-15 | A |
| Example 2-16 | Re-16 | B |
| Example 2-17 | Re-17 | B |
| Example 2-18 | Re-18 | B |
| Example 2-19 | Re-19 | B |
| Example 2-20 | Re-20 | C |
| Example 2-21 | Re-21 | C |
| Example 2-22 | Re-22 | C |
| Example 2-23 | Re-23 | C |
| Example 2-24 | Re-24 | D |
| Example 2-25 | Re-25 | C |
| Example 2-26 | Re-26 | C |
| Example 2-27 | Re-27 | A |
| Example 2-28 | Re-28 | C |
| Example 2-29 | Re-29 | B |
| Example 2-30 | Re-30 | C |
| Example 2-31 | Re-31 | C |
| Example 2-32 | Re-32 | B |
| Example 2-33 | Re-33 | B |
| Example 2-34 | Re-34 | C |
| Example 2-35 | Re-35 | C |

TABLE 9

| Table 5 | Resist | Defect suppression |
|---|---|---|
| (continued) | composition | property |
| Example 2-36 | Re-36 | C |
| Example 2-37 | Re-37 | C |
| Example 2-38 | Re-38 | B |
| Example 2-39 | Re-39 | C |
| Example 2-40 | Re-40 | B |
| Example 2-41 | Re-41 | B |
| Example 2-42 | Re-42 | B |
| Example 2-43 | Re-43 | B |
| Example 2-44 | Re-44 | B |
| Example 2-45 | Re-45 | B |
| Example 2-46 | Re-46 | B |
| Example 2-47 | Re-47 | A |
| Example 2-48 | Re-48 | A |
| Example 2-49 | Re-49 | B |
| Example 2-50 | Re-50 | C |
| Example 2-51 | Re-51 | A |
| Example 2-52 | Re-52 | B |
| Example 2-53 | Re-53 | C |
| Example 2-54 | Re-54 | B |
| Example 2-55 | Re-55 | B |
| Example 2-56 | Re-56 | B |
| Example 2-57 | Re-57 | C |
| Example 2-58 | Re-58 | C |
| Example 2-59 | Re-59 | B |
| Example 2-60 | Re-60 | B |
| Example 2-61 | Re-61 | B |
| Example 2-62 | Re-62 | A |
| Example 2-63 | Re-63 | B |
| Example 2-64 | Re-64 | B |
| Example 2-65 | Re-65 | B |
| Example 2-66 | Re-66 | B |
| Example 2-67 | Re-67 | B |
| Comparative Example 2-1 | Re-1R | F |
| Comparative Example 2-2 | Re-2R | F |

Table 5 above has demonstrated that resist compositions of the present invention provide, also in the case of forming a pattern by alkali development, high defect performance (defect suppression property).

What is claimed is:

1. An actinic ray-sensitive or radiation-sensitive resin composition comprising a resin (A) including a repeating unit (a1) having a partial structure in which a phenolic hydroxy group is protected with a structure represented by a formula (1) below: 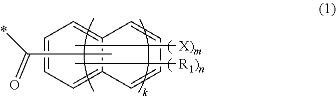
wherein, in the formula (1), X represents a halogen atom or an electron-withdrawing group,
R₁ represents a hydroxy group or an organic group,
k represents an integer of 0 to 3,
n represents an integer of 0 to (4+2k),
m represents an integer of 1 to (5+2k),
wherein a relationship of 1≤(n+m)≤(5+2k) is satisfied,
when n represents an integer of 2 or more, a plurality of R₁'s may be the same or different,
when m represents an integer of 2 or more, a plurality of X's may be the same or different, and
* represents a bonding site to an oxygen atom of the phenolic hydroxy group.

2. The actinic ray-sensitive or radiation-sensitive resin composition according to claim 1, wherein the repeating unit (a1) is a repeating unit derived from a monomer represented by a formula (2) or (3) below: 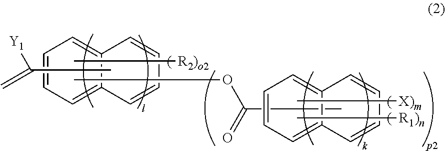
wherein, in the formula (2), Y₁ represents a hydrogen atom, a hydroxy group, a halogen atom, an alkyl group, or a halogenated alkyl group,
X represents a halogen atom or an electron-withdrawing group,
R₁ represents a hydroxy group or an organic group,
R₂ represents a hydroxy group, a halogen atom, or an organic group,
k represents an integer of 0 to 3,
n represents an integer of 0 to (4+2k),
m represents an integer of 1 to (5+2k),
wherein a relationship of 1≤(n+m)≤(5+2k) is satisfied,
when n represents an integer of 2 or more, a plurality of R₁'s may be the same or different,
when m represents an integer of 2 or more, a plurality of X's may be the same or different,
l represents an integer of 0 to 2,
o2 represents an integer of 0 to (4+2l),
p2 represents an integer of 1 to (5+2l),
wherein a relationship of 1≤(o2+p2)≤(5+2l) is satisfied,
when o2 represents an integer of 2 or more, a plurality of R₂'s may be the same or different, and
when p2 represents an integer of 2 or more, a plurality of X's, R₁'s, k's, m's, and n's may be the same or different, and 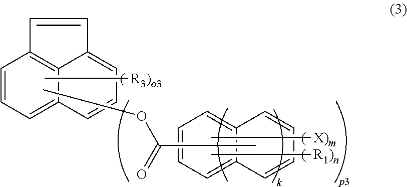
wherein, in the formula (3), X represents a halogen atom or an electron-withdrawing group,
R₁ represents a hydroxy group or an organic group,
R₃ represents a hydroxy group, a halogen atom, or an organic group,
k represents an integer of 0 to 3,
n represents an integer of 0 to (4+2k),
m represents an integer of 1 to (5+2k),
wherein a relationship of 1≤(n+m)≤(5+2k) is satisfied,
when n represents an integer of 2 or more, a plurality of R₁'s may be the same or different,
when m represents an integer of 2 or more, a plurality of X's may be the same or different,
o3 represents an integer of 0 to 5,
p3 represents an integer of 1 to 6,
wherein a relationship of 1≤(o3+p3)≤6 is satisfied,
when o3 represents an integer of 2 or more, a plurality of R₃'s may be the same or different, and
when p3 represents an integer of 2 or more, a plurality of X's, R₁'s, k's, m's, and n's may be the same or different.

3. The actinic ray-sensitive or radiation-sensitive resin composition according to claim 1, wherein X in the formula (1), (2), or (3) represents a halogen atom, a halogenated alkyl group, a nitro group, a cyano group, or a —C(═O) OR group where R represents a hydrocarbon group.

4. The actinic ray-sensitive or radiation-sensitive resin composition according to claim 1, further comprising a photoacid generator and a solvent.

5. The actinic ray-sensitive or radiation-sensitive resin composition according to claim 1, wherein the resin (A) further has a repeating unit (a2) having an acid-decomposable group.

6. The actinic ray-sensitive or radiation-sensitive resin composition according to claim 5, wherein the repeating unit (a2) is a repeating unit derived from a monomer represented by any one of formulas (4) to (6) below: 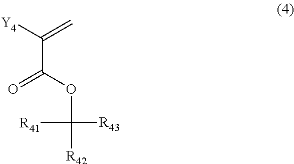
wherein, in the formula (4), Y₄ represents a hydrogen atom, a fluorine atom, or an alkyl group, R₄₁, R₄₂, and R₄₃ each independently represent an organic group, and two among R₄₁, R₄₂, and R₄₃ may be bonded together to form a ring, 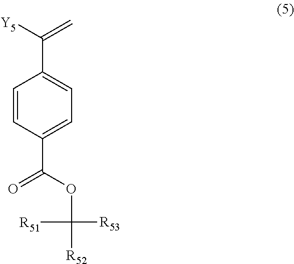
wherein, in the formula (5), Y₅ represents a hydrogen atom, a fluorine atom, or an alkyl group, R₅₁, R₅₂, and R₅₃ each independently represent an organic group, and two among R₅₁, R₅₂, and R₅₃ may be bonded together to form a ring, and 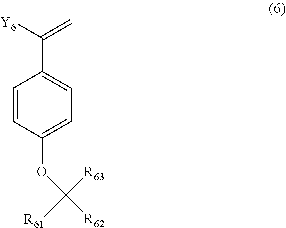
wherein, in the formula (6), Y₆ represents a hydrogen atom, a fluorine atom, or an alkyl group, R₆₁, R₆₂, and R₆₃ each independently represent an organic group, and two among R₆₁, R₆₂, and R₆₃ may be bonded together to form a ring.

7. An actinic ray-sensitive or radiation-sensitive film formed from the actinic ray-sensitive or radiation-sensitive resin composition according to claim 1.

8. A pattern forming method comprising:
using the actinic ray-sensitive or radiation-sensitive resin composition according to claim 1 to form an actinic ray-sensitive or radiation-sensitive film on a substrate;
exposing the actinic ray-sensitive or radiation-sensitive film; and
using a developer to develop the exposed actinic ray-sensitive or radiation-sensitive film to form a pattern.

9. A method for producing an electronic device, the method comprising the pattern forming method according to claim 8.

10. A compound represented by a formula (2) or (3) below: 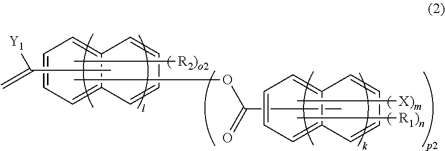
wherein, in the formula (2), Y₁ represents a hydrogen atom, a hydroxy group, a halogen atom, an alkyl group, or a halogenated alkyl group,
X represents a halogen atom or an electron-withdrawing group,
R₁ represents a hydroxy group or an organic group,
R₂ represents a hydroxy group, a halogen atom, or an organic group,
k represents an integer of 0 to 3,
n represents an integer of 0 to (4+2k),
m represents an integer of 1 to (5+2k),
wherein a relationship of 1≤(n+m)≤(5+2k) is satisfied,
when n represents an integer of 2 or more, a plurality of R₁'s may be the same or different,
when m represents an integer of 2 or more, a plurality of X's may be the same or different,
l represents an integer of 0 to 2,
o2 represents an integer of 0 to (4+2l),
p2 represents an integer of 1 to (5+2l),
wherein a relationship of 1≤(o2+p2)≤(5+2l) is satisfied,
when o2 represents an integer of 2 or more, a plurality of R₂'s may be the same or different, and
when p2 represents an integer of 2 or more, a plurality of X's, R₁'s, k's, m's, and n's may be the same or different, and 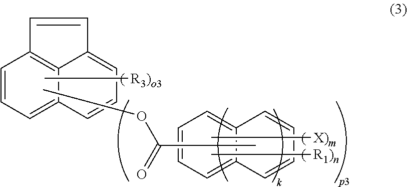
wherein, in the formula (3), X represents a halogen atom or an electron-withdrawing group,
R₁ represents a hydroxy group or an organic group,
R₃ represents a hydroxy group, a halogen atom, or an organic group,
k represents an integer of 0 to 3,
n represents an integer of 0 to (4+2k),
m represents an integer of 1 to (5+2k),
wherein a relationship of 1≤(n+m)≤(5+2k) is satisfied,
when n represents an integer of 2 or more, a plurality of R₁'s may be the same or different,
when m represents an integer of 2 or more, a plurality of X's may be the same or different,
o3 represents an integer of 0 to 5,
p3 represents an integer of 1 to 6,
wherein a relationship of 1≤(o3+p3)≤6 is satisfied,
when o3 represents an integer of 2 or more, a plurality of R₃'s may be the same or different, and
when p3 represents an integer of 2 or more, a plurality of X's, R₁'s, k's, m's, and n's may be the same or different.

11. The compound according to claim 10, wherein, in the formula (2) or (3), X represents a halogen atom, a halogenated alkyl group, a nitro group, a cyano group, or a —C(═O)OR group where R represents a hydrocarbon group.

12. A resin comprising a repeating unit derived from a monomer represented by a formula (2) or (3) below: 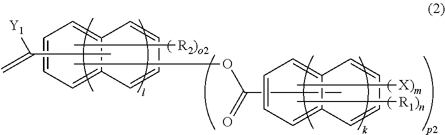
wherein, in the formula (2), Y₁ represents a hydrogen atom, a hydroxy group, a halogen atom, an alkyl group, or a halogenated alkyl group,
X represents a halogen atom or an electron-withdrawing group,
R₁ represents a hydroxy group or an organic group,
R₂ represents a hydroxy group, a halogen atom, or an organic group,
k represents an integer of 0 to 3,
n represents an integer of 0 to (4+2k),
m represents an integer of 1 to (5+2k),
wherein a relationship of 1≤(n+m)≤(5+2k) is satisfied,
when n represents an integer of 2 or more, a plurality of R₁'s may be the same or different,
when m represents an integer of 2 or more, a plurality of X's may be the same or different,
l represents an integer of 0 to 2,
o2 represents an integer of 0 to (4+2l),
p2 represents an integer of 1 to (5+2l),
wherein a relationship of 1≤(o2+p2)≤(5+2l) is satisfied,
when o2 represents an integer of 2 or more, a plurality of R₂'s may be the same or different, and
when p2 represents an integer of 2 or more, a plurality of X's, R₁'s, k's, m's, and n's may be the same or different, and 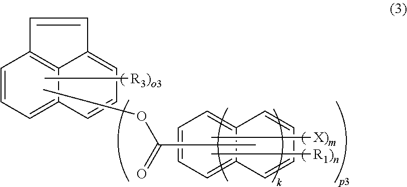
wherein, in the formula (3), X represents a halogen atom or an electron-withdrawing group,
R₁ represents a hydroxy group or an organic group,
R₃ represents a hydroxy group, a halogen atom, or an organic group,
k represents an integer of 0 to 3,
n represents an integer of 0 to (4+2k),
m represents an integer of 1 to (5+2k),
wherein a relationship of 1≤(n+m)≤(5+2k) is satisfied,
when n represents an integer of 2 or more, a plurality of R₁'s may be the same or different,
when m represents an integer of 2 or more, a plurality of X's may be the same or different,
o3 represents an integer of 0 to 5,
p3 represents an integer of 1 to 6,
wherein a relationship of 1≤(o3+p3)≤6 is satisfied,
when o3 represents an integer of 2 or more, a plurality of R₃'s may be the same or different, and
when p3 represents an integer of 2 or more, a plurality of X's, R₁'s, k's, m's, and n's may be the same or different.
